(19) United States
(12) Patent Application Publication
(10) Pub. No.: US 2025/0063893 A1
(43) Pub. Date: Feb. 20, 2025

(54) DISPLAY APPARATUS AND METHOD FOR MANUFACTURING DISPLAY APPARATUS

(71) Applicant: Semiconductor Energy Laboratory Co., Ltd., Atsugi-shi, Kanagawa-ken (JP)

(72) Inventors: Ryota HODO, Atsugi (JP); Kenichi OKAZAKI, Atsugi (JP); Shunpei YAMAZAKI, Setagaya (JP)

(21) Appl. No.: 18/723,543

(22) PCT Filed: Dec. 15, 2022
(86) PCT No.: PCT/IB2022/062264

§ 371 Date: Jun. 24, 2024

(30) Foreign Application Priority Data
Dec. 29, 2021 (JP) 2021-215378

(51) Int. Cl. H10K 59/122; H10K 59/00; H10K 59/12

(52) U.S. Cl. CPC H10K 59/122; H10K 59/1201; H10K 59/771

(57) ABSTRACT

A display apparatus with high display quality is provided. The display apparatus includes a first light-emitting device, a second light-emitting device, and a layer. The first light-emitting device includes a first pixel electrode, a first light-emitting layer over the first pixel electrode, a first common electrode over the first light-emitting layer, and a second common electrode over the first common electrode. The second light-emitting device includes a second pixel electrode, a second light-emitting layer over the second pixel electrode, the first common electrode over the second light-emitting layer, and the second common electrode over the first common electrode. The layer is provided between the first light-emitting device and the second light-emitting device. The second common electrode is provided over the layer.

### TECHNICAL FIELD

One embodiment of the present invention relates to a display apparatus, a display module, and an electronic device. One embodiment of the present invention relates to a method for manufacturing a display apparatus.

Note that one embodiment of the present invention is not limited to the above technical field. Examples of the technical field of one embodiment of the present invention include a semiconductor device, a display apparatus, a light-emitting apparatus, a power storage device, a memory device, an electronic device, a lighting device, an input device (e.g., a touch sensor), an input/output device (e.g., a touch panel), a method for driving any of them, and a method for manufacturing any of them.

### BACKGROUND ART

Display apparatuses have been expected to be applied to a variety of uses. Usage examples of large-sized display apparatuses include a television device for home use (also referred to as TV or television receiver), digital signage, and a PID (Public Information Display). In addition, a smartphone and a tablet terminal each including a touch panel, and the like, are being developed as portable information terminals.

Furthermore, higher-resolution display apparatuses have been required in recent years. As devices requiring high-resolution display apparatuses, for example, devices for virtual reality (VR), augmented reality (AR), substitutional reality (SR), or mixed reality (MR) have been actively developed.

Light-emitting apparatuses including light-emitting devices (also referred to as light-emitting elements) have been developed as display apparatuses, for example. Light-emitting devices utilizing an electroluminescence (hereinafter referred to as EL) phenomenon (also referred to as EL devices or EL elements) have features such as ease of reduction in thickness and weight, high-speed response to input signals, and driving with a constant DC voltage power source, and have been used in display apparatuses.

Patent Document 1 discloses a display apparatus using an organic EL device (also referred to as organic EL element) for VR.

### REFERENCE

### Patent Document

[Patent Document 1] PCT International Publication No. 2018/087625

### SUMMARY OF THE INVENTION

### Problems to be Solved by the Invention

An object of one embodiment of the present invention is to provide a display apparatus with high display quality. An object of one embodiment of the present invention is to provide a high-resolution display apparatus. An object of one embodiment of the present invention is to provide a high-definition display apparatus. An object of one embodiment of the present invention is to provide a highly reliable display apparatus.

An object of one embodiment of the present invention is to provide a method for manufacturing a high-resolution display apparatus. An object of one embodiment of the present invention is to provide a method for manufacturing a high-definition display apparatus. An object of one embodiment of the present invention is to provide a method for manufacturing a highly reliable display apparatus. An object of one embodiment of the present invention is to provide a method for manufacturing a display apparatus with high yield.

Note that the description of these objects does not preclude the existence of other objects. One embodiment of the present invention does not need to achieve all of these objects. Other objects can be derived from the description of the specification, the drawings, and the claims.

### Means for Solving the Problems

One embodiment of the present invention is a display apparatus including a first light-emitting device, a second light-emitting device, and a layer. The first light-emitting device includes a first pixel electrode, a first light-emitting layer over the first pixel electrode, a first common electrode over the first light-emitting layer, and a second common electrode over the first common electrode. The second light-emitting device includes a second pixel electrode, a second light-emitting layer over the second pixel electrode, the first common electrode over the second light-emitting layer, and the second common electrode over the first common electrode. The layer is provided between the first light-emitting device and the second light-emitting device. The second common electrode is provided over the layer.

In the above-described display apparatus, the layer is preferably an insulating layer.

In the above-described display apparatus, the layer is preferably a conductive layer.

The above-described display apparatus preferably includes a first insulating layer and a second insulating layer. The first pixel electrode, the second pixel electrode, and the second insulating layer are preferably provided over the first insulating layer. In a cross-sectional view, a level of a top surface of the second insulating layer is preferably higher than a level of a top surface of the first common electrode.

The above-described display apparatus preferably includes a third insulating layer. The third insulating layer is preferably provided over the second insulating layer. In a cross-sectional view, a level of a top surface of the third insulating layer is preferably higher than a level of a top surface of the second common electrode in a region in contact with the first common electrode.

In the above-described display apparatus, the layer is preferably an insulating layer. The third insulating layer preferably includes the same material as the layer.

In the above-described display apparatus, an end portion of the first light-emitting layer is preferably positioned outward from an end portion of the first pixel electrode. An end portion of the second light-emitting layer is preferably positioned outward from an end portion of the second pixel electrode.

In the above-described display apparatus, the first light-emitting layer preferably includes a region overlapping with the second light-emitting layer.

The above-described display apparatus preferably includes a first common layer. The first common layer is preferably sandwiched between the first pixel electrode and the first light-emitting layer. The first common layer is preferably sandwiched between the second pixel electrode and the second light-emitting layer.

In the above-described display apparatus, the first common layer preferably includes a carrier-injection layer.

The above-described display apparatus preferably includes a second common layer. The second common layer is preferably sandwiched between the first light-emitting layer and the first common electrode. The second common layer is preferably sandwiched between the second light-emitting layer and the first common electrode.

In the above-described display apparatus, the second common layer preferably includes a carrier-injection layer.

One embodiment of the present invention is a method for manufacturing a display apparatus, including forming a first pixel electrode and a second pixel electrode; forming a first light-emitting layer using a first mask over the first pixel electrode; forming a second light-emitting layer using a second mask over the second pixel electrode; forming a first common electrode using a third mask over the first light-emitting layer and the second light-emitting layer; forming a layer over part of the first common electrode; and forming a second common electrode using a fourth mask in a region overlapping with the first common electrode. The layer is provided between the first pixel electrode and the second pixel electrode. The second common electrode is provided over the layer.

One embodiment of the present invention is a method for manufacturing a display apparatus, including forming a first pixel electrode and a second pixel electrode over a first insulating layer; forming a second insulating layer over the first insulating layer; forming a first light-emitting layer using a first mask over the first pixel electrode; forming a second light-emitting layer using a second mask over the second pixel electrode; forming a first common electrode using a third mask over the first light-emitting layer and the second light-emitting layer; forming a third insulating layer over part of the first common electrode and forming a fourth insulating layer over the second insulating layer; and forming a second common electrode using a fourth mask in a region overlapping with the first common electrode. The third insulating layer is provided between the first pixel electrode and the second pixel electrode. The second common electrode is provided over the first common electrode and the third insulating layer.

In the above-described method for manufacturing a display apparatus, in a cross-sectional view, a level of a top surface of the second insulating layer is preferably higher than a level of a top surface of the first common electrode. In forming the first light-emitting layer, the first mask is preferably in contact with the top surface of the second insulating layer. In forming the second light-emitting layer, the second mask is preferably in contact with the top surface of the second insulating layer. In forming the first common electrode, the third mask is preferably in contact with the top surface of the second insulating layer.

In the above-described method for manufacturing a display apparatus, in a cross-sectional view, a level of a top surface of the fourth insulating layer is preferably higher than a level of a top surface of the second common electrode in a region in contact with the first common electrode. In forming the second common electrode, the fourth mask is preferably in contact with the top surface of the fourth insulating layer.

### Effect of the Invention

One embodiment of the present invention can provide a display apparatus with high display quality. One embodiment of the present invention can provide a high-resolution display apparatus. One embodiment of the present invention can provide a high-definition display apparatus. One embodiment of the present invention can provide a highly reliable display apparatus.

One embodiment of the present invention can provide a method for manufacturing a high-resolution display apparatus. One embodiment of the present invention can provide a method for manufacturing a high-definition display apparatus. One embodiment of the present invention can provide a method for manufacturing a highly reliable display apparatus. One embodiment of the present invention can provide a method for manufacturing a display apparatus with high yield.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

FIG. 1A is a top view illustrating an example of a display apparatus. FIG. 1B is a cross-sectional view illustrating an example of the display apparatus.

FIG. 2A and FIG. 2B are cross-sectional views illustrating examples of a display apparatus.

FIG. 3A and FIG. 3B are cross-sectional views illustrating examples of a display apparatus.

FIG. 4A and FIG. 4B are cross-sectional views illustrating examples of a display apparatus.

FIG. 5A and FIG. 5B are cross-sectional views illustrating an example of a display apparatus.

FIG. 6A and FIG. 6B are cross-sectional views illustrating an example of a display apparatus.

FIG. 7A and FIG. 7B are cross-sectional views illustrating examples of a display apparatus.

FIG. 8A is a top view illustrating an example of a display apparatus. FIG. 8B is a cross-sectional view illustrating an example of the display apparatus.

FIG. 9 is a top view illustrating an example of a display apparatus.

FIG. 10A and FIG. 10B are cross-sectional views illustrating an example of a display apparatus.

FIG. 11 is a top view illustrating an example of a display apparatus.

FIG. 12 is a top view illustrating an example of a display apparatus.

FIG. 13A to FIG. 13C are cross-sectional views illustrating an example of a method for manufacturing a display apparatus.

FIG. 14A to FIG. 14C are cross-sectional views illustrating an example of a method for manufacturing a display apparatus.

FIG. 15A to FIG. 15C are cross-sectional views illustrating an example of a method for manufacturing a display apparatus.

FIG. 16A and FIG. 16B are cross-sectional views illustrating an example of a method for manufacturing a display apparatus.

FIG. 17A and FIG. 17B are cross-sectional views illustrating an example of a method for manufacturing a display apparatus.

FIG. 18A and FIG. 18B are cross-sectional views illustrating an example of a method for manufacturing a display apparatus.

FIG. 19A to FIG. 19F are diagrams illustrating examples of pixels.

FIG. 20A to FIG. 20K are diagrams illustrating examples of a pixel.

FIG. 21A and FIG. 21B are perspective views illustrating an example of a display apparatus.

FIG. 22A to FIG. 22C are cross-sectional views illustrating examples of a display apparatus.

FIG. 23 is a cross-sectional view illustrating an example of a display apparatus.

FIG. 24 is a cross-sectional view illustrating an example of a display apparatus.

FIG. 25 is a cross-sectional view illustrating an example of a display apparatus.

FIG. 26 is a cross-sectional view illustrating an example of a display apparatus.

FIG. 27 is a cross-sectional view illustrating an example of a display apparatus.

FIG. 28A to FIG. 28F are diagrams illustrating structure examples of a light-emitting device.

FIG. 29A and FIG. 29B are diagrams illustrating structure examples of a light-receiving device.

FIG. 29C to FIG. 29E are diagrams illustrating structure examples of a display apparatus.

FIG. 30A to FIG. 30D are diagrams illustrating examples of electronic devices.

FIG. 31A to FIG. 31F are diagrams illustrating examples of electronic devices.

FIG. 32A to FIG. 32G are diagrams illustrating examples of electronic devices.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

Note that in structures of the invention described below, the same portions or portions having similar functions are denoted by the same reference numerals in different drawings, and the description thereof is not repeated. The same hatch pattern is used for portions having similar functions, and the portions are not especially denoted by reference numerals in some cases.

The position, size, range, or the like of each component illustrated in drawings does not represent the actual position, size, range, or the like in some cases for easy understanding. Therefore, the disclosed invention is not necessarily limited to the position, size, range, or the like disclosed in the drawings.

Note that the term “film” and the term “layer” can be used interchangeably depending on the case or the circumstances. For example, the term “conductive layer” can be replaced with the term “conductive film”. As another example, the term “insulating film” can be replaced with the term “insulating layer”.

In this specification and the like, a hole or an electron is sometimes referred to as a “carrier”. Specifically, a hole-injection layer or an electron-injection layer may be referred to as a “carrier-injection layer”, a hole-transport layer or an electron-transport layer may be referred to as a “carrier-transport layer”, and a hole-blocking layer or an electron-blocking layer may be referred to as a “carrier-blocking layer”. Note that the above-described carrier-injection layer, carrier-transport layer, and carrier-blocking layer cannot be clearly distinguished from each other on the basis of the cross-sectional shape, properties, or the like in some cases. One layer may have two or three functions of the carrier-injection layer, the carrier-transport layer, and the carrier-blocking layer in some cases.

In this specification and the like, a light-emitting device (also referred to as a light-emitting element) includes an EL layer between a pair of electrodes. The EL layer includes at least a light-emitting layer. Examples of layers (also referred to as functional layers) included in the EL layer include a light-emitting layer, carrier-injection layers (a hole-injection layer and an electron-injection layer), carrier-transport layers (a hole-transport layer and an electron-transport layer), and carrier-blocking layers (a hole-blocking layer and an electron-blocking layer). In this specification and the like, a light-receiving device (also referred to as a light-receiving element) includes at least an active layer functioning as a photoelectric conversion layer between a pair of electrodes. In this specification and the like, one of the pair of electrodes may be referred to as a pixel electrode and the other may be referred to as a common electrode.

In this specification and the like, a tapered shape refers to a shape such that at least part of the side surface of a component is inclined with respect to a substrate surface or a formation surface. For example, a tapered shape preferably includes a region where the angle between the inclined side surface and the substrate surface or the formation surface (such an angle is also referred to as a taper angle) is less than 90°. Note that the side surface, the substrate surface, and the formation surface of the component are not necessarily completely flat, and may have a substantially planar shape with a slight curvature or a substantially planar shape with slight unevenness.

### Embodiment 1

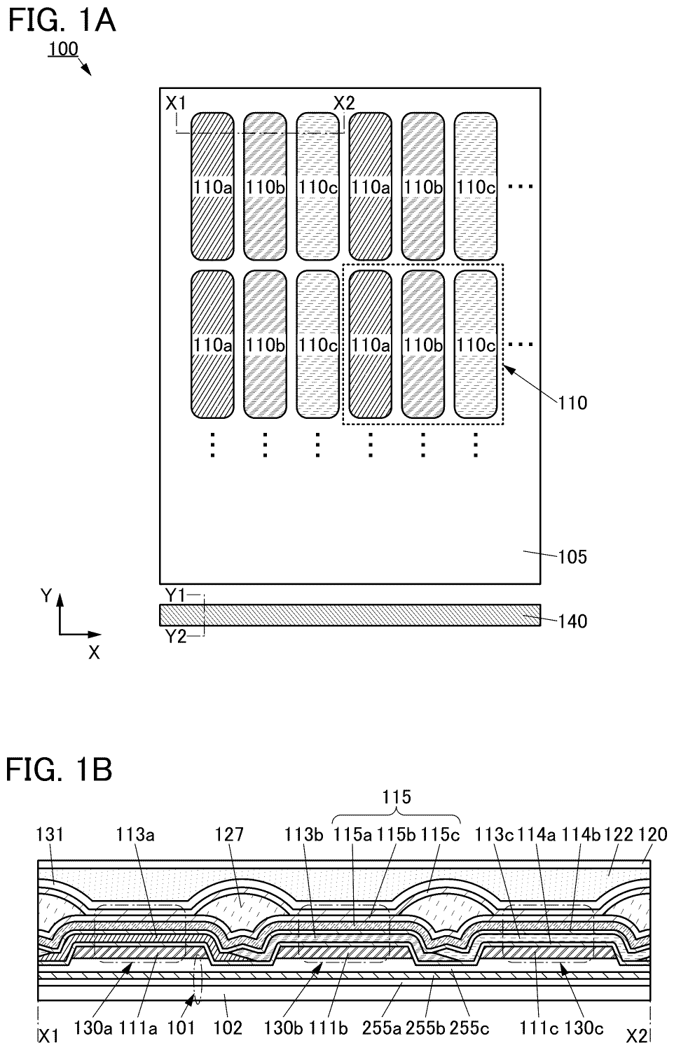

In this embodiment, a display apparatus of one embodiment of the present invention is described with reference to FIG. 1 to FIG. 12.

One embodiment of the present invention is a display apparatus including a first light-emitting device, a second light-emitting device, and a layer. The first light-emitting device includes a first pixel electrode, a first light-emitting layer over the first pixel electrode, and a common electrode over the first light-emitting layer. The second light-emitting device includes a second pixel electrode, a second light-emitting layer over the second pixel electrode, and the common electrode over the second light-emitting layer. The common electrode has a stacked-layer structure of a first common electrode and a second common electrode over the first common electrode. The layer is provided between the first light-emitting device and the second light-emitting device. The second common electrode is provided over the layer.

The first common electrode has a depressed portion due to a region where a pixel electrode is not provided between the first light-emitting device and the second light-emitting device. The above-described layer is provided over the first common electrode to fill the depressed portion. The second common electrode is provided to cover the layer. Providing the layer can reduce unevenness of the formation surface of the second common electrode, so that coverage with the second common electrode can be improved. Consequently, a connection defect due to step disconnection of the common electrode and an increase in electric resistance can be inhibited.

An end portion of the first light-emitting layer is positioned outward from an end portion of the first pixel electrode. An end portion of the second light-emitting layer is positioned outward from an end portion of the second pixel electrode. That is, the first light-emitting layer covers the top surface and a side surface of the first pixel electrode. In a similar manner, the second light-emitting layer covers the top surface and a side surface of the second pixel electrode. Thus, the entire top surface of the first pixel electrode and the entire top surface of the second pixel electrode can be light-emitting regions and the aperture ratio can be increased. The first pixel electrode and the second pixel electrode are not in contact with the common electrode, so that a short circuit can be inhibited.

The first common electrode is provided over the first light-emitting layer and the second light-emitting layer. In the step of forming the layer over the first common electrode, the first light-emitting layer and the second light-emitting layer are not exposed, whereby the first light-emitting layer and the second light-emitting layer can be inhibited from being damaged.

A structure in which light-emitting layers in light-emitting devices of different colors (for example, blue (B), green (G), and red (R)) are separately formed or separately patterned is sometimes referred to as an SBS (Side By Side) structure. The SBS structure can optimize materials and structures for emission colors and thus can extend freedom of choice of materials and structures, whereby the luminance and the reliability can be easily improved.

In the case of manufacturing a display apparatus including a plurality of light-emitting devices emitting light of different colors, light-emitting layers different in emission color each need to be formed in an island shape.

Note that in this specification and the like, the term “island shape” refers to a state where two or more layers formed using the same material in the same step are physically separated from each other.

FIG. 1A is a top view illustrating a display apparatus 100 of one embodiment of the present invention. The display apparatus 100 includes a pixel portion 105 in which a plurality of pixels 110 are arranged in a matrix, and a connection portion 140 outside the pixel portion 105. The pixels 110 each include a plurality of subpixels. FIG. 1A illustrates the pixels in two rows and two columns; as the structure where the pixels 110 each include three subpixels (a subpixel 110a, a subpixel 110b, and a subpixel 110c), the subpixels in two rows and six columns are illustrated. The connection portion 140 can also be referred to as a cathode contact portion.

Each subpixel includes a display device (also referred to as a display element). Examples of the display device include a light-emitting device (also referred to as a light-emitting element). As the light-emitting device, an OLED (Organic Light-Emitting Diode) or a QLED (Quantum-dot Light-Emitting Diode) is preferably used, for example. Examples of a light-emitting substance contained in the light-emitting device include a substance that emits fluorescent light (a fluorescent material), a substance that emits phosphorescent light (a phosphorescent material), and a substance that exhibits thermally activated delayed fluorescence (a thermally activated delayed fluorescence (TADF) material). As a light-emitting substance contained in an EL element, not only organic compounds but also inorganic compounds (e.g., quantum dot materials) can be used.

The emission color of the light-emitting device can be infrared, red, green, blue, cyan, magenta, yellow, white, or the like. When the light-emitting device has a microcavity structure, the color purity can be increased.

A display apparatus of one embodiment of the present invention includes light-emitting devices separately formed for respective emission colors and can perform full-color display.

Top surface shapes of the subpixels illustrated in FIG. 1A correspond to those of the light-emitting regions of the light-emitting devices. Examples of the top surface shape of the subpixel include polygons such as a triangle, a tetragon (including a rectangle, a rhombus, and a square), and a pentagon; polygons with rounded corners; an ellipse; and a circle.

Each subpixel includes a pixel circuit controlling the light-emitting device. The pixel circuits are not necessarily placed in the ranges of the subpixels illustrated in FIG. 1A and may be placed outside the subpixels. For example, transistors included in a pixel circuit of the subpixel 110a may be positioned within the range of the subpixel 110b illustrated in FIG. 1A, or some or all of the transistors may be positioned outside the range of the subpixel 110a.

Although FIG. 1A illustrates the subpixel 110a, the subpixel 110b, and the subpixel 110c having the same or substantially the same aperture ratio (also referred to as the same or substantially the same size of light-emitting regions), one embodiment of the present invention is not limited thereto. The aperture ratio of each of the subpixel 110a, the subpixel 110b, and the subpixel 110c can be determined as appropriate. The subpixel 110a, the subpixel 110b, and the subpixel 110c may have different aperture ratios, or two or more of them may have the same or substantially the same aperture ratio.

The pixel 110 illustrated in FIG. 1A employs stripe arrangement. The pixel 110 illustrated in FIG. 1A is composed of three subpixels: the subpixel 110a, the subpixel 110b, and the subpixel 110c. The subpixel 110a, the subpixel 110b, and the subpixel 110c include light-emitting devices emitting light of different colors. The subpixel 110a, the subpixel 110b, and the subpixel 110c are subpixels of three colors of red (R), green (G), and blue (B) or subpixels of three colors of yellow (Y), cyan (C), and magenta (M), for example. The number of types of subpixels is not limited to three and may be four or more. As the four subpixels, subpixels of four colors of R, G, B, and white (W), subpixels of four colors of R, G, B, and Y, and subpixels of four colors of R, G, B, and infrared light (IR) can be given.

In this specification and the like, the row direction is referred to as X direction and the column direction is referred to as Y direction, in some cases. The X direction and the Y direction intersect with each other and are, for example, orthogonal to each other (see FIG. 1A). FIG. 1A illustrates an example in which subpixels of different colors are arranged in the X direction and subpixels of the same color are arranged in the Y direction.

Although the top view in FIG. 1A illustrates an example in which the connection portion 140 is positioned in the lower side of the pixel portion 105, the position of the connection portion 140 is not particularly limited. The connection portion 140 is provided in at least one of the upper side, the right side, the left side, and the lower side of the pixel portion 105 in the top view, and may be provided so as to surround the four sides of the pixel portion 105. The top surface shape of the connection portion 140 can be a belt-like shape, an L shape, a U shape, a frame-like shape, or the like. The number of the connection portions 140 can be one or more.

### Structure Example 1

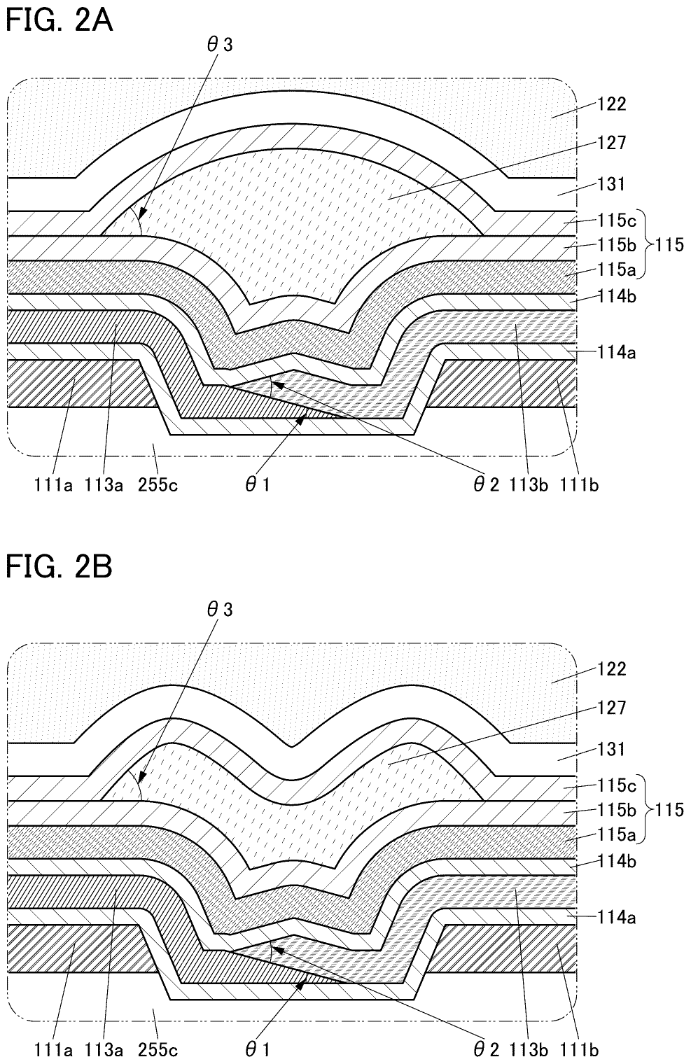

FIG. 1B is a cross-sectional view taken along a dashed-dotted line X1-X2 in FIG. 1A. FIG. 2A is an enlarged view of part of the cross-sectional view illustrated in FIG. 1B.

As illustrated in FIG. 1B, in the display apparatus 100, a light-emitting device 130a, a light-emitting device 130b, and a light-emitting device 130c are provided over a layer 101, and a substrate 120 is bonded onto the light-emitting device 130a, the light-emitting device 130b, and the light-emitting device 130c with a resin layer 122. A protective layer 131 is provided to cover the light-emitting device 130a, the light-emitting device 130b, and the light-emitting device 130c, and the substrate 120 may be bonded onto the protective layer 131 with the resin layer 122. A layer 127 is provided in a region between adjacent light-emitting devices.

Although FIG. 1B illustrates a plurality of cross sections of the layer 127, the layer 127 are each one continuous layer when the display apparatus 100 is seen from above. In other words, the display apparatus 100 can have a structure including one layer 127. Note that the display apparatus 100 may include a plurality of layers 127 that are separated from each other.

The display apparatus of one embodiment of the present invention can have any of a top-emission structure in which light is emitted in a direction opposite to the substrate where the light-emitting device is formed, a bottom-emission structure in which light is emitted toward the substrate where the light-emitting device is formed, and a dual-emission structure in which light is emitted toward both surfaces.

The light-emitting device 130a, the light-emitting device 130b, and the light-emitting device 130c emit light of different colors. The combination of colors emitted from the light-emitting device 130a, the light-emitting device 130b, and the light-emitting device 130c can be red (R), green (G), and blue (B), for example.

Each of the light-emitting device 130a, the light-emitting device 130b, and the light-emitting device 130c includes a pair of electrodes and a layer sandwiched between the pair of electrodes. The layer includes at least a light-emitting layer. One of the pair of electrodes included in the light-emitting device functions as an anode, and the other electrode functions as a cathode. The case where the pixel electrode functions as an anode and the common electrode functions as a cathode is described below as an example in some cases.

The light-emitting device 130a includes a pixel electrode 111a over an insulating layer 255c, a common layer 114a over the pixel electrode 111a, an island-shaped first layer 113a over the common layer 114a, a common layer 114b over the first layer 113a, and a common electrode 115 over the common layer 114b. In the light-emitting device 130a, the common layer 114a, the first layer 113a, and the common layer 114b can be collectively referred to as an EL layer.

The light-emitting device 130b includes a pixel electrode 111b over the insulating layer 255c, the common layer 114a over the pixel electrode 111b, an island-shaped second layer 113b over the common layer 114a, the common layer 114b over the second layer 113b, and the common electrode 115 over the common layer 114b. In the light-emitting device 130b, the common layer 114a, the second layer 113b, and the common layer 114b can be collectively referred to as an EL layer.

The light-emitting device 130c includes a pixel electrode 111c over the insulating layer 255c, the common layer 114a over the pixel electrode 111c, an island-shaped third layer 113c over the common layer 114a, the common layer 114b over the third layer 113c, and the common electrode 115 over the common layer 114b. In the light-emitting device 130c, the common layer 114a, the third layer 113c, and the common layer 114b can be collectively referred to as an EL layer.

In this specification and the like, in the EL layers included in the light-emitting devices, the island-shaped layer provided in each light-emitting device is referred to as the first layer 113a, the second layer 113b, or the third layer 113c, and the layer shared by the plurality of light-emitting devices is referred to as the common layer 114a or the common layer 114b. Note that in this specification and the like, the first layer 113a, the second layer 113b, and the third layer 113c are sometimes referred to as island-shaped EL layers, EL layers formed in an island shape, or the like, in which case the common layer 114a and the common layer 114b are not included.

Note that in the case of describing matters common to the light-emitting device 130a, the light-emitting device 130b, and the light-emitting device 130b, these light-emitting devices are sometimes referred to as a light-emitting device 130 by omitting the alphabets that distinguish them from each other. Similarly, in the description of matters common to other components that are distinguished from each other using alphabets, such as the pixel electrode 111a, the pixel electrode 111b, and the pixel electrode 111c, reference numerals without alphabets are sometimes used.

The first layer 113a, the second layer 113b, and the third layer 113c each include at least a light-emitting layer. For example, a structure is preferable in which the first layer 113a includes a light-emitting layer emitting red light, the second layer 113b includes a light-emitting layer emitting green light, and the third layer 113c includes a light-emitting layer emitting blue light.

The first layer 113a, the second layer 113b, and the third layer 113c are each provided to have an island shape. The first layer 113a, the second layer 113b, and the third layer 113c can each be formed using a fine metal mask (an FMM, a high-resolution metal mask), for example.

Although FIG. 1B illustrates a structure in which the first layer 113a to the third layer 113c have the same thickness, one embodiment of the present invention is not limited thereto. The first layer 113a to the third layer 113c may have different thicknesses. For example, the thickness is preferably set to match an optical path length that intensifies light emitted from the first layer 113a to the third layer 113c. A microcavity structure can be achieved in this manner, and the color purity of each light-emitting device can be increased.

The light-emitting device of this embodiment may have either a single structure (a structure including only one light-emitting unit) or a tandem structure (a structure including a plurality of light-emitting units). The light-emitting unit includes at least one light-emitting layer.

In the case where a light-emitting device having a tandem structure is used, a charge-generation layer is preferably provided between the light-emitting units. Each of the first layer 113a, the second layer 113b, and the third layer 113c can have a structure that includes a first light-emitting unit, a charge-generation layer, and a second light-emitting unit, for example.

In the case of using a light-emitting device having a tandem structure, the first layer 113a preferably includes a plurality of light-emitting units emitting red light, the second layer 113b preferably includes a plurality of light-emitting units emitting green light, and the third layer 113c preferably includes a plurality of light-emitting units emitting blue light.

The common layer 114a and the common layer 114b are each a continuous film provided to be shared by a plurality of light-emitting devices. The common layer 114a and the common layer 114b each preferably include any one or more of a hole-injection layer, a hole-transport layer, a hole-blocking layer, an electron-blocking layer, an electron-transport layer, and an electron-injection layer. For example, the common layer 114a includes a hole-injection layer and the common layer 114b includes an electron-injection layer. For example, the common layer 114a may include a stack of a hole-transport layer and a hole-injection layer, and the common layer 114b may include a stack of an electron-transport layer and an electron-injection layer. Note that the common layer 114a is not necessarily provided. Furthermore, the common layer 114b is not necessarily provided.

The first layer 113a, the second layer 113b, and the third layer 113c may each include one or more of a hole-injection layer, a hole-transport layer, a hole-blocking layer, a charge-generation layer, an electron-blocking layer, an electron-transport layer, and an electron-injection layer.

For example, the first layer 113a, the second layer 113b, and the third layer 113c may each include a hole-injection layer, a hole-transport layer, a light-emitting layer, and an electron-transport layer in this order. In addition, an electron-blocking layer may be provided between the hole-transport layer and the light-emitting layer. In addition, a hole-blocking layer may be provided between the electron-transport layer and the light-emitting layer. Furthermore, an electron-injection layer may be provided over the electron-transport layer.

For example, the first layer 113a, the second layer 113b, and the third layer 113c may each include an electron-injection layer, an electron-transport layer, a light-emitting layer, and a hole-transport layer in this order. In addition, a hole-blocking layer may be provided between the electron-transport layer and the light-emitting layer. In addition, an electron-blocking layer may be provided between the hole-transport layer and the light-emitting layer. Furthermore, a hole-injection layer may be provided over the hole-transport layer.

Here, when a temperature higher than the upper temperature limit of the EL layer is applied after the formation of the EL layer, deterioration of the EL layer proceeds, which might result in a decrease in the emission efficiency and reliability of the light-emitting device. Thus, in one embodiment of the present invention, the upper temperature limit of a compound contained in the light-emitting device is preferably higher than or equal to 100° C. and lower than or equal to 180° C., further preferably higher than or equal to 120° C. and lower than or equal to 180° C., still further preferably higher than or equal to 140° C. and lower than or equal to 180° C.

Examples of indicators of the upper temperature limit include the glass transition point (Tg), the softening point, the melting point, the thermal decomposition temperature, and the 5% weight loss temperature. For example, as an indicator of the upper temperature limit of a layer included in the EL layer, a glass transition point of a material contained in the layer can be used. In the case where the layer is a mixed layer formed of a plurality of materials, a glass transition point of a material contained in the highest proportion can be used, for example. Alternatively, the lowest temperature among the glass transition points of the materials may be used.

In particular, the upper temperature limit of the light-emitting layer is preferably high. In this case, the light-emitting layer can be inhibited from being damaged by heating and being decreased in emission efficiency and lifetime. The light-emitting layer contains a light-emitting substance (also referred to as a light-emitting organic compound, a guest material, or the like) and a host material. Since the light-emitting layer contains more host material than light-emitting substance, Tg of the host material can be used as an indicator of the upper temperature limit of the light-emitting layer.

The upper temperature limits of the compounds contained in the first layer 113a, the second layer 113b, and the third layer 113c are each preferably higher than or equal to 100° C. and lower than or equal to 180° C. or higher than or equal to 120° C. and lower than or equal to 180° C., further preferably higher than or equal to 140° C. and lower than or equal to 180° C. For example, the glass transition point (Tg) of these compounds is preferably higher than or equal to 100° C. and lower than or equal to 180° C. or higher than or equal to 120° C. and lower than or equal to 180° C., further preferably higher than or equal to 140° C. and lower than or equal to 180° C.

In particular, the upper temperature limits of a functional layer provided over the light-emitting layer and a functional layer provided under the light-emitting layer are preferably high. When the functional layer has high heat resistance, the light-emitting layer can be effectively protected and damage to the light-emitting layer can be reduced.

The upper temperature limits of the compounds contained in the common layer 114a and the common layer 114b are each preferably higher than or equal to 100° C. and lower than or equal to 180° C. or higher than or equal to 120° C. and lower than or equal to 180° C., further preferably higher than or equal to 140° C. and lower than or equal to 180° C. For example, the glass transition point (Tg) of these compounds is preferably higher than or equal to 100° C. and lower than or equal to 180° C. or higher than or equal to 120° C. and lower than or equal to 180° C., further preferably higher than or equal to 140° C. and lower than or equal to 180° C.

Increasing the upper temperature limit of the light-emitting device can improve the reliability of the light-emitting device. Furthermore, the allowable temperature range in the manufacturing process of the display apparatus can be widened, thereby improving the manufacturing yield and the reliability.

Of the pixel electrode 111 and the common electrode 115, an electrode using a conductive film that transmits visible light (also referred to as a transparent electrode) is used for the side through which light is extracted. For the side through which light is not extracted, an electrode using a conductive film that reflects visible light (also referred to as a reflective electrode) is preferably used. In the case where the display apparatus includes a light-emitting device emitting infrared light, it is preferable that an electrode using a conductive film that transmits visible light and infrared light (a transparent electrode) be used for the side through which light is extracted and an electrode using a conductive film that reflects visible light and infrared light (a reflective electrode) be used for the side through which light is not extracted.

A conductive film transmitting visible light may be used as the electrode through which light is not extracted. In that case, a conductive film that transmits visible light is preferably provided between a conductive film that reflects visible light (also referred to as a reflective layer) and the EL layer. In other words, light emitted by the EL layer may be reflected by the reflective layer to be extracted from the display apparatus.

As a material that forms the pair of electrodes of the light-emitting device, a metal, an alloy, an electrically conductive compound, a mixture thereof, or the like can be used as appropriate. Specific examples of the material include metals such as aluminum, magnesium, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing any of these metals in appropriate combination. Other examples of the material include indium tin oxide (also referred to as In—Sn oxide or ITO), In—Si—Sn oxide (also referred to as ITSO), indium zinc oxide (In—Zn oxide), and In—W—Zn oxide. Other examples of the material include an alloy containing aluminum (aluminum alloy) such as an alloy of aluminum, nickel, and lanthanum (Al—Ni—La), and an alloy containing silver such as an alloy of silver and magnesium and an alloy of silver, palladium, and copper (Ag—Pd—Cu, also referred to as APC). Other examples of the material include an element belonging to Group 1 or Group 2 of the periodic table that is not given above as an example (e.g., lithium, cesium, calcium, or strontium), a rare earth metal such as europium or ytterbium, an alloy containing an appropriate combination of any of these elements, and graphene.

The light-emitting devices preferably employ a microcavity structure. Therefore, one of the pair of electrodes of the light-emitting device is preferably an electrode having properties of transmitting and reflecting visible light (transflective electrode), and the other is preferably an electrode having a property of reflecting visible light (reflective electrode). When the light-emitting device has a microcavity structure, light obtained from the light-emitting layer can be resonated between the electrodes, whereby light emitted from the light-emitting device can be intensified.

The light transmittance of the transparent electrode is higher than or equal to 40%. For example, an electrode having a visible light (light with wavelengths greater than or equal to 400 nm and less than 750 nm) transmittance higher than or equal to 40% is preferably used as the transparent electrode of the light-emitting device. The transflective electrode has a visible light reflectance higher than or equal to 10% and lower than or equal to 95%, preferably higher than or equal to 30% and lower than or equal to 80%. The reflective electrode has a visible light reflectance higher than or equal to 40% and lower than or equal to 100%, preferably higher than or equal to 70% and lower than or equal to 100%. These electrodes preferably have a resistivity less than or equal to 1×10⁻² Ωcm.

The common electrode 115 is a continuous film shared by a plurality of light-emitting devices. Any of the above-described materials can be used for the common electrode 115.

The common electrode 115 preferably has a stacked-layer structure. FIG. 1B illustrates an example in which the common electrode 115 has a stacked-layer structure of a conductive layer 115a, a conductive layer 115b over the conductive layer 115a, and a conductive layer 115c over the conductive layer 115b. The conductive layer 115a can also be referred to as the first common electrode, the conductive layer 115b can also be referred to as the second common electrode, and the conductive layer 115c can also be referred to as a third common electrode. The conductive layer 115a is provided to cover the EL layer (here, the common layer 114b) and the conductive layer 115b is provided to cover the conductive layer 115a. The layer 127 is provided over the conductive layer 115b to fill a depressed portion between adjacent light-emitting devices. The conductive layer 115c is provided over the conductive layer 115b and the layer 127. The conductive layer 115c is in contact with the conductive layer 115b in a region overlapping with the pixel electrode 111a, a region overlapping with the pixel electrode 111b, and a region overlapping with the pixel electrode 111c. Any of the above-described materials can be used for the conductive layer 115a, the conductive layer 115b, and the conductive layer 115c.

In the case where the common electrode 115 is a transflective electrode, a conductive layer having properties of transmitting and reflecting visible light is used as any one or more of the conductive layer 115a, the conductive layer 115b, and the conductive layer 115c, and a conductive layer having a property of transmitting visible light is used as the other conductive layers. In particular, a conductive layer having properties of transmitting and reflecting visible light is preferably used as the conductive layer 115a provided in contact with the EL layer. A conductive layer having a property of transmitting visible light can be used as each of the conductive layer 115b and the conductive layer 115c. For the conductive layer 115a, an alloy of silver and magnesium can be suitably used, for example. For each of the conductive layer 115b and the conductive layer 115c, an In—Sn oxide (ITO) or an In—Si—Sn oxide (ITSO) can be suitably used, for example. Note that the same material or different materials may be used for the conductive layer 115b and the conductive layer 115c.

In the case where the common electrode 115 is a transparent electrode, a conductive layer having a property of reflecting visible light is used as each of the conductive layer 115a, the conductive layer 115b, and the conductive layer 115c. The same material or different materials may be used for the conductive layer 115a, the conductive layer 115b, and the conductive layer 115c.

In the case where the common electrode 115 is a reflective electrode, a conductive layer having a property of reflecting visible light is used as any one or more of the conductive layer 115a, the conductive layer 115b, and the conductive layer 115c. In particular, a conductive layer having a property of reflecting visible light is preferably used as the conductive layer 115a provided in contact with the EL layer. For the conductive layer 115a, aluminum or an alloy containing aluminum can be suitably used, for example. For each of the conductive layer 115b and the conductive layer 115c, a conductive layer having a property of transmitting visible light may be used or a conductive layer having a property of reflecting visible light may be used. The same material or different materials may be used for the conductive layer 115b and the conductive layer 115c.

For the conductive layer 115b, a material that is less likely to be oxidized than the material for the conductive layer 115a is preferably used. In particular, in the case where a material that is easily oxidized is used for the conductive layer 115a, the conductive layer 115b is preferably provided to cover the conductive layer 115a. In the case where the conductive layer 115b is not provided, the conductive layer 115a might be oxidized in the step of forming the layer 127, for example. Furthermore, a metal component contained in the conductive layer 115a might be precipitated. When the conductive layer 115a is covered with the conductive layer 115b, oxidation of the conductive layer 115a can be inhibited. Furthermore, precipitation of a metal component contained in the conductive layer 115a can be inhibited. For the conductive layer 115b, an oxide is preferably used. For the conductive layer 115b, an In—Sn oxide (ITO) or an In—Si—Sn oxide (ITSO) can be suitably used, for example. It can be said that the conductive layer 115b has a function of protecting the conductive layer 115a.

The conductive layer 115b has a depressed portion due to a region where the pixel electrode 111 is not provided. The layer 127 is embedded in the depressed portion.

The layer 127 is provided over the conductive layer 115b to fill a depressed portion formed in the conductive layer 115b. The layer 127 can overlap with a side surface and part of the top surface of each of the first layer 113a, the second layer 113b, and the third layer 113c, with the common layer 114b, the conductive layer 115a, and the conductive layer 115b therebetween. The layer 127 preferably covers at least part of the top surface of the conductive layer 115b.

The layer 127 can fill a space between adjacent light-emitting devices, whereby the formation surface of the conductive layer 115c can have higher flatness with small unevenness. Consequently, coverage with the conductive layer 115c can be improved.

The conductive layer 115c is provided over the conductive layer 115b and the layer 127. Before the layer 127 is provided, a step is generated due to a region where the pixel electrode is provided and a region where the pixel electrode is not provided (a region between the light-emitting devices). Specifically, a depressed portion is generated in a region where the pixel electrode is not provided between adjacent pixel electrodes. In the display apparatus of one embodiment of the present invention, the layer 127 is provided over the conductive layer 115b to fill the depressed portion, whereby the step between adjacent light-emitting devices can be reduced and coverage with the conductive layer 115c can be improved. In addition, an increase in electric resistance, which is caused by local thinning of the conductive layer 115c due to the step, can be inhibited. Consequently, a connection defect due to step disconnection of the common electrode 115 and an increase in electric resistance can be inhibited.

Note that in this specification and the like, step disconnection refers to a phenomenon in which a layer, a film, or an electrode is disconnected because of the shape of the formation surface (e.g., a level difference).

Since the conductive layer 115a and the conductive layer 115b have larger unevenness on the formation surface than the conductive layer 115c, step disconnection or local thinning of the conductive layer 115a and the conductive layer 115b occurs in some cases. However, in the display apparatus of one embodiment of the present invention, the conductive layer 115c can be formed with good coverage; thus, even when step disconnection or local thinning of the conductive layer 115a and the conductive layer 115b occurs, a connection defect of the common electrode 115 and an increase in electric resistance can be inhibited.

Although FIG. 1B illustrates a structure in which the layer 127 is provided in contact with the conductive layer 115b, one embodiment of the present invention is not limited thereto. The layer 127 may include a region in contact with the conductive layer 115a. For example, in the case where step disconnection occurs in the conductive layer 115b in a depressed portion between light-emitting devices, the layer 127 may be in contact with the conductive layer 115a in a region of step disconnection. Note that the EL layer is preferably covered with one or both of the conductive layer 115a and the conductive layer 115b. When the EL layer is covered with one or both of the conductive layer 115a and the conductive layer 115b, the EL layer can be inhibited from being damaged in forming the layer 127.

The top surface of the layer 127 preferably has a shape with higher flatness, but may include a projection portion, a convex surface, a concave surface, or a depressed portion. For example, the top surface of the layer 127 preferably has a smooth convex shape with high flatness.

There is no particular limitation on the conductivity of the layer 127, and the layer 127 may be an insulating layer or a conductive layer. Note that when the layer 127 is a conductive layer, the layer 127 can function as part of the common electrode.

One or both of an organic material and an inorganic material can be used for the layer 127. An organic material can be suitably used for the layer 127. As the organic material, a photosensitive organic resin is preferably used, and for example, a photosensitive resin composite containing an acrylic resin is preferably used. Note that in this specification and the like, an acrylic resin refers to not only a polymethacrylic acid ester or a methacrylic resin, but also all the acrylic polymer in a broad sense in some cases.

Alternatively, for the layer 127, it is possible to use an acrylic resin, a polyimide resin, an epoxy resin, an imide resin, a polyamide resin, a polyimide-amide resin, a silicone resin, a siloxane resin, a benzocyclobutene-based resin, a phenol resin, precursors of these resins, or the like. Alternatively, for the layer 127, it is possible to use an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin. A photoresist may be used for the photosensitive resin. As the photosensitive organic resin, either a positive material or a negative material may be used.

For the layer 127, a material absorbing visible light may be used. When the layer 127 absorbs light from the light-emitting device, leakage of light (stray light) from the light-emitting device to the adjacent light-emitting device through the layer 127 can be inhibited. Thus, the display quality of the display apparatus can be improved. Since no polarizing plate is required to improve the display quality, the weight and thickness of the display apparatus can be reduced.

Examples of the material absorbing visible light include materials containing pigment of black or the like, materials containing dye, light-absorbing resin materials (e.g., polyimide), and resin materials that can be used for color filters (color filter materials). Using a resin material obtained by mixing color filter materials of two or three or more colors is particularly preferable to enhance the effect of blocking visible light. In particular, mixing color filter materials of three or more colors enables the formation of a black or nearly black resin layer. A stack of layers using these materials may be used as the layer 127.

The conductive layer 115c is provided to cover the layer 127 and the conductive layer 115b. For the conductive layer 115c, a material having high adhesion to the formation surface of the conductive layer 115c (here, the layer 127 and the conductive layer 115b) is preferably used. Thus, film separation of the conductive layer 115c can be inhibited.

In a cross-sectional view of the display apparatus, side surfaces of the pixel electrode 111a, the pixel electrode 111b, and the pixel electrode 111c each preferably have a tapered shape. Specifically, the angle formed by each of the side surfaces of the pixel electrode 111a, the pixel electrode 111b, and the pixel electrode 111c and the formation surface (here, the top surface of the insulating layer 255c) is preferably less than 90°. When the side surfaces of the pixel electrodes have a tapered shape, coverage with the EL layers provided along the side surfaces of the pixel electrodes can be improved.

An insulating layer covering an end portion of the top surface of the pixel electrode is not provided between the pixel electrode and the EL layer in the display apparatus of one embodiment of the present invention. Specifically, in FIG. 1B, an insulating layer covering an end portion of the top surface of the pixel electrode 111a is not provided between the pixel electrode 111a and the common layer 114a. An insulating layer covering an end portion of the top surface of the pixel electrode 111b is not provided between the pixel electrode 111b and the common layer 114a. Thus, the distance between adjacent light-emitting devices can be extremely shortened. Accordingly, the display apparatus can have a high resolution or a high definition.

Furthermore, light emitted from the EL layer can be extracted efficiently with a structure in which an insulating layer covering the end portion of the pixel electrode is not provided between the pixel electrode and the EL layer, i.e., a structure in which an insulating layer is not provided between the pixel electrode and the EL layer. Therefore, the display apparatus of one embodiment of the present invention can significantly reduce the viewing angle dependence. A reduction in the viewing angle dependence leads to an increase in visibility of an image on the display apparatus.

As illustrated in FIG. 1B, the first layer 113a preferably covers an end portion of the pixel electrode 111a. An end portion of the first layer 113a is positioned outward from the end portion of the pixel electrode 111a. That is, the end portion of the first layer 113a is positioned in a region not overlapping with the pixel electrode 111a. Such a structure enables the entire top surface of the pixel electrode to be a light-emitting region, and the aperture ratio can be easily increased as compared with the structure where the end portion of the first layer 113a is positioned inward from the end portion of the pixel electrode 111a. Note that a region of the first layer 113a that does not overlap with the pixel electrode 111a can be regarded as a region that does not contribute or has a small contribution to light emission. Note that although description is made using the pixel electrode 111a and the first layer 113a as an example here, the same applies to the pixel electrode 111b and the second layer 113b, and the pixel electrode 111c and the third layer 113c.

Increasing the aperture ratio of the display apparatus can improve the reliability of the display apparatus. Specifically, with reference to the lifetime of a display apparatus including an organic EL device and having an aperture ratio of 10%, a display apparatus having an aperture ratio of 20% (that is, having an aperture ratio two times higher than the reference) has a lifetime 3.25 times longer than the reference, and a display apparatus having an aperture ratio of 40% (that is, having an aperture ratio four times higher than the reference) has a lifetime 10.6 times longer than the reference. Thus, the density of a current flowing through the organic EL device can be reduced with an increasing aperture ratio, and accordingly the lifetime of the display apparatus can be increased. The display apparatus of one embodiment of the present invention can have a higher aperture ratio and thus the display apparatus can have higher display quality. Furthermore, the display apparatus has excellent effect that the reliability (especially the lifetime) can be significantly improved with an increasing aperture ratio.

Covering the side surface of the pixel electrode with the EL layer inhibits contact between the pixel electrode and the common electrode 115, thereby inhibiting a short circuit of the light-emitting device. Furthermore, the distance between light-emitting regions of the light-emitting devices (i.e., regions where the first layer 113a, the second layer 113b, and the third layer 113c overlap with the pixel electrodes) and the end portions of the first layer 113a, the second layer 113b, and the third layer 113c can be increased. The thicknesses of the end portions of the first layer 113a, the second layer 113b, and the third layer 113c and the vicinity thereof are sometimes smaller than those of the inner regions. Thus, using regions that are away from the end portions of the first layer 113a, the second layer 113b, and the third layer 113c as the light-emitting regions can reduce variation in characteristics of the light-emitting devices.

FIG. 1B illustrates an example in which a stacked-layer structure of the common layer 114a, the first layer 113a, the common layer 114b, the conductive layer 115a, the conductive layer 115b, the layer 127, and the conductive layer 115c is positioned over the end portion of the pixel electrode 111a. In a similar manner, a stacked-layer structure of the common layer 114a, the second layer 113b, the common layer 114b, the conductive layer 115a, the conductive layer 115b, the layer 127, and the conductive layer 115c is positioned over an end portion of the pixel electrode 111b. A stacked-layer structure of the common layer 114a, the third layer 113c, the common layer 114b, the conductive layer 115a, the conductive layer 115b, the layer 127, and the conductive layer 115c is positioned over an end portion of the pixel electrode 111c.

Next, a structure of the layer 127 and the vicinity thereof will be described with reference to FIG. 2A. FIG. 2A is an enlarged cross-sectional view of a region including the layer 127 between the light-emitting device 130a and the light-emitting device 130b, and the vicinity of the layer 127. Although the layer 127 between the light-emitting device 130a and the light-emitting device 130b is described below as an example, the same applies to the layer 127 between the light-emitting device 130b and the light-emitting device 130c, the layer 127 between the light-emitting device 130c and the light-emitting device 130a, and the like.

As illustrated in FIG. 2A, the common layer 114a is provided to cover the pixel electrode 111a and the pixel electrode 111b. The first layer 113a and the second layer 113b are provided to cover the common layer 114a. The common layer 114b is provided to cover the first layer 113a and the second layer 113b.

Here, the first layer 113a may include a region in contact with the adjacent second layer 113b. FIG. 2A illustrates an example in which the second layer 113b is provided to cover the end portion of the first layer 113a and the vicinity thereof. For example, after the first layer 113a is formed, the second layer 113b can be formed to cover the end portion of the first layer 113a and the vicinity thereof. Note that the formation order of the first layer 113a, the second layer 113b, and the third layer 113c is not particularly limited. The first layer 113a may be formed to cover the end portion of the second layer 113b and the vicinity thereof after the second layer 113b is formed. The first layer 113a may be formed after the formation of the third layer 113c, or the first layer 113a may be formed before the formation of the third layer 113c.

The first layer 113a, the second layer 113b, and the third layer 113c may each include a region in contact with the adjacent first layer 113a, the adjacent second layer 113b, or the adjacent third layer 113c. It can be said that the first layer 113a, the second layer 113b, and the third layer 113c each include a region overlapping with the adjacent first layer 113a, the adjacent second layer 113b, or the adjacent third layer 113c. Whether regions where the first layer 113a, the second layer 113b, and the third layer 113c adjacent to each other overlap with each other are included can be confirmed by, for example, a photoluminescence (PL) method.

In a cross-sectional view of the display apparatus, the side surfaces of the first layer 113a, the second layer 113b, and the third layer 113c each preferably have a tapered shape. Specifically, the angle formed by each of the side surfaces of the first layer 113a, the second layer 113b, and the third layer 113c and the formation surface is preferably less than 90°. When the side surfaces of the first layer 113a, the second layer 113b, and the third layer 113c have tapered shapes, coverage with the common layer 114b provided over the first layer 113a, the second layer 113b, and the third layer 113c can be improved.

FIG. 2A illustrates an angle θ1 formed by the side surface of the first layer 113a and the top surface of the common layer 114a, which is the formation surface of the first layer 113a. Furthermore, an angle 62 formed by the side surface of the second layer 113b and the top surface and the side surface of the first layer 113a, which is the formation surface of the second layer 113b, is illustrated. The angle θ1 is preferably less than 90°, further preferably less than or equal to 60°, still further preferably less than or equal to 45°, yet still further preferably less than or equal to 20°. When the side surface of the first layer 113a has such a tapered shape, coverage with the second layer 113b and the common layer 114b provided over the first layer 113a can be improved. The angle θ2 is preferably less than 90°, further preferably less than or equal to 60°, still further preferably less than or equal to 45°, yet still further preferably less than or equal to 20°. When the side surface of the second layer 113b has such a tapered shape, coverage with the common layer 114b provided over the second layer 113b can be improved.

The first layer 113a, the second layer 113b, and the third layer 113c can each be formed using a fine metal mask, for example. Each of the first layer 113a, the second layer 113b, and the third layer 113c formed using a fine metal mask is thinner in a portion closer to the end portion, and the angle formed by the side surface and the formation surface (e.g., the angle θ1 and the angle θ2) is extremely small in some cases. Thus, in each of the first layer 113a, the second layer 113b, and the third layer 113c, the side surface of the layer formed first and the top surface of the layer formed later are continuously connected, and it is difficult to clearly distinguish the side surface of the layer formed first from the top surface of the layer formed later in some cases.

The layer 127 is provided in contact with part of the top surface of the conductive layer 115b. The conductive layer 115c is provided to cover the conductive layer 115b and the layer 127.

In a cross-sectional view of the display apparatus, a side surface of the layer 127 preferably has a tapered shape. Specifically, the angle formed by the side surface of the layer 127 and the formation surface is preferably less than 90°. When the side surface of the layer 127 has a tapered shape, coverage with the conductive layer 115c provided over the layer 127 can be improved.

FIG. 2A illustrates an angle θ3 formed by the side surface of the layer 127 and the top surface of the conductive layer 115b, which is the formation surface of the layer 127. The angle θ3 is preferably less than 90°, further preferably less than or equal to 60°, still further preferably less than or equal to 45°, yet still further preferably less than or equal to 20°. When the side surface of the layer 127 has such a tapered shape, coverage with the conductive layer 115c provided over the layer 127 can be improved.

As illustrated in FIG. 2A, in a cross-sectional view of the display apparatus, the top surface of the layer 127 preferably has a convex shape. The convex shape of the top surface of the layer 127 is preferably a shape gently bulged toward the center. It is also preferable that the convex portion in the center portion of the top surface of the layer 127 have a shape connected continuously to a tapered portion in the end portion. When the layer 127 has such a shape, the conductive layer 115c can be formed with good coverage over the whole layer 127.

As illustrated in FIG. 2B, the top surface of the layer 127 may have a concave shape in a cross-sectional view of the display apparatus. In FIG. 2B, the top surface of the layer 127 has a shape that is gently bulged toward the center, i.e., includes a convex surface, and has a shape that is recessed in the center and its vicinity, i.e., includes a concave surface. In FIG. 2B, the convex portion of the top surface of the layer 127 has a shape connected continuously to the tapered portion in the end portion. Even when the layer 127 has such a shape, the conductive layer 115c can be formed with good coverage over the whole layer 127.

A structure in which the layer 127 includes a concave surface in its center portion as illustrated in FIG. 2B can relieve stress generated in the layer 127 in some cases. Specifically, the structure in which the layer 127 includes a concave surface in its center portion can relieve local stress generated at the end portion of the layer 127 and inhibit separation of the layer 127 from the conductive layer 115b.

To form a structure in which the layer 127 includes a concave surface in its center portion as illustrated in FIG. 2B, a light exposure method using a multi-tone mask (typically, a half-tone mask or a gray-tone mask) can be employed. A multi-tone mask is a mask capable of light exposure of three light-exposure levels to provide an exposed portion, a half-exposed portion, and an unexposed portion, and is a light-exposure mask through which light is transmitted to have a plurality of intensities. The layer 127 including regions with a plurality of (typically two kinds of) thicknesses can be formed with one photomask (one light exposure and development process).

In order to form the structure in which the layer 127 includes a concave surface in its center portion, it is also possible to employ a method in which the line width of a mask at a position where the concave surface is formed is made smaller than the line width of an exposed portion. Accordingly, the layer 127 including a plurality of regions with different thicknesses can be formed.

Note that a method for forming a concave surface in the center portion of the layer 127 is not limited to the above method. For example, an exposed portion and a half-exposed portion may be formed separately with the use of two photomasks. Alternatively, the viscosity of the resin material used for the layer 127 may be adjusted; specifically, the viscosity of the material used for the layer 127 may be less than or equal to 10 cP, preferably greater than or equal to 1 cP and less than or equal to 5 cP.

Note that the concave surface in the center portion of the layer 127 is not necessarily continuous, and may be disconnected between adjacent light-emitting devices. In this case, part of the layer 127 in the center portion of the layer 127 illustrated in FIG. 2B is eliminated, so that the surface of the conductive layer 115b is exposed. In the case of such a structure, the conductive layer 115c is formed to have a shape covering the conductive layer 115b.

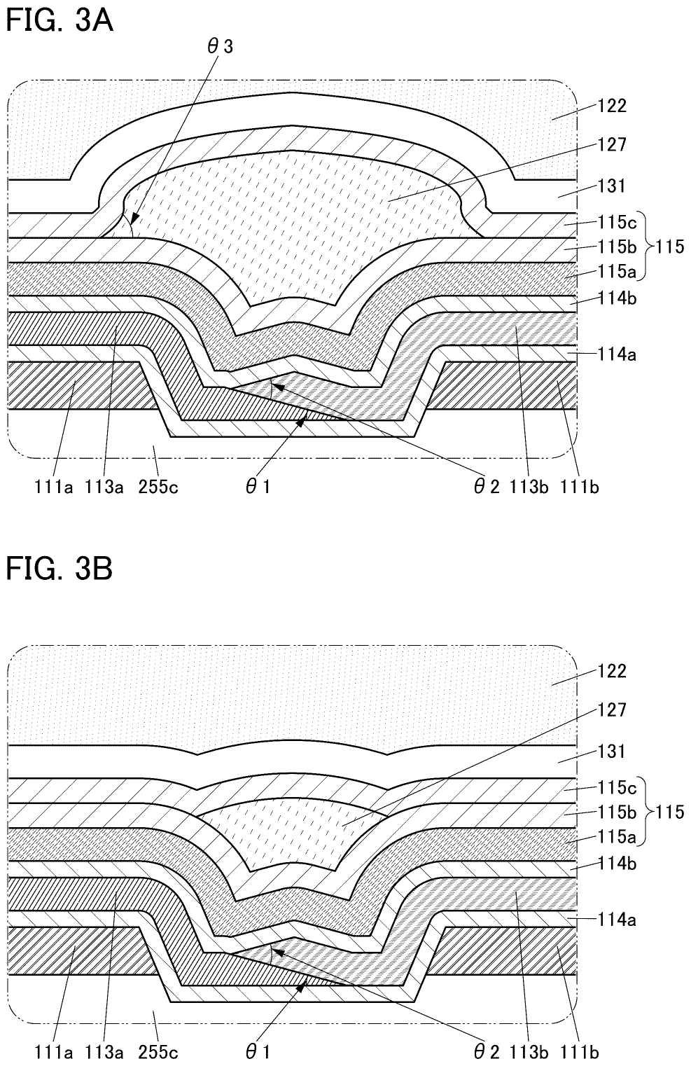

FIG. 3A illustrates an example in which the side surface of the layer 127 has a concave shape (also referred to as a narrowed portion, a depressed portion, a dent, a hollow, or the like) in a cross-sectional view of the display apparatus. Depending on the materials and the formation conditions (e.g., heating temperature, heating time, and heating atmosphere) of the layer 127, the side surface of the layer 127 has a concave shape in some cases.

As illustrated in FIG. 2A, FIG. 2B, and FIG. 3A, one end portion of the layer 127 preferably overlaps with the top surface of the pixel electrode 111a and the other end portion of the layer 127 preferably overlaps with the top surface of the pixel electrode 111b. Such a structure enables the end portion of the layer 127 to be formed over a substantially flat region of the conductive layer 115b. Thus, the layer 127 having a taper-shaped side surface is easily formed. Meanwhile, the area of a portion where the top surface of the pixel electrode and the layer 127 overlap with each other is preferably smaller because the light-emitting region of the light-emitting device can be wider and the aperture ratio can be increased.

Note that the layer 127 does not necessarily overlap with the top surface of the pixel electrode. As illustrated in FIG. 3B, the layer 127 does not necessarily overlap with the pixel electrode, and may be provided in a region sandwiched between the pixel electrode 111a and the pixel electrode 111b. When the layer 127 is provided in a region not overlapping with the top surface of the pixel electrode, the light-emitting region of the light-emitting device can be widened and the aperture ratio can be increased. Note that even with such a structure, unevenness of the surface where the conductive layer 115c is formed can be reduced and coverage with the conductive layer 115c can be improved, as compared with the structure in which the layer 127 is not provided.

Providing the layer 127 can improve coverage with the conductive layer 115c, thereby preventing formation of a disconnected portion and a locally thinned portion in the common electrode 115. Accordingly, in the common electrode 115, a connection defect due to the disconnected portion and an increase in electric resistance due to the locally thinned portion can be inhibited. Thus, the display quality of the display apparatus of one embodiment of the present invention can be improved.

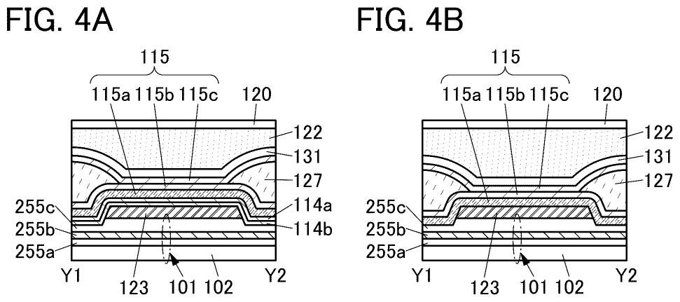

FIG. 4A and FIG. 4B are cross-sectional views taken along a dashed-dotted line Y1-Y2 in FIG. 1A. The common electrode 115 is electrically connected to a conductive layer 123 provided in the connection portion 140. The conductive layer 123 is preferably formed using a conductive layer formed using the same material as the pixel electrode 111a, the pixel electrode 111b, and the pixel electrode 111c. For example, the conductive layer 123 can be formed in the same step as the pixel electrode 111a, the pixel electrode 111b, and the pixel electrode 111c.

Note that FIG. 4A illustrates an example in which the common layer 114a is provided over the conductive layer 123, the common layer 114b is provided over the common layer 114a, and the common electrode 115 (the conductive layer 115a, the conductive layer 115b, and the conductive layer 115c) is provided over the common layer 114b. In FIG. 4A, the conductive layer 123 is electrically connected to the common electrode 115 through the common layer 114a and the common layer 114b. Note that one or both of the common layer 114a and the common layer 114b are not necessarily provided in the connection portion 140. In FIG. 4B, the common layer 114a and the common layer 114b are not provided, and the conductive layer 123 is directly connected to the common electrode 115. For example, by using a mask for specifying a film formation area (also referred to as an area mask, a rough metal mask, or the like to be distinguished from a fine metal mask), regions where the common layer 114a, the common layer 114b, and the common electrode 115 are formed can be different from one another.

The layer 101 preferably includes a pixel circuit having a function of controlling the light-emitting device 130a, the light-emitting device 130b, and the light-emitting device 130c. The pixel circuit can include a transistor, a capacitor, and a wiring, for example. Note that the layer 101 may include one or both of a gate line driver circuit (a gate driver) and a source line driver circuit (a source driver) in addition to the pixel circuit. The layer 101 may include one or both of an arithmetic circuit and a memory circuit.

The layer 101 can have a structure where a pixel circuit is provided over a semiconductor substrate or an insulating substrate. As the semiconductor substrate, a single crystal semiconductor substrate or a polycrystalline semiconductor substrate using silicon or silicon carbide as a material, a compound semiconductor substrate of silicon germanium or the like, or an SOI substrate can be used. As the insulating substrate, a glass substrate, a quartz substrate, a sapphire substrate, a ceramic substrate, or an organic resin substrate can be used. Note that the shape of the semiconductor substrate and the insulating substrate may be circular or square. As the semiconductor substrate and the insulating substrate, a substrate having at least heat resistance high enough to withstand heat treatment performed later can be used.

As illustrated in FIG. 1B, the layer 101 can employ a stacked-layer structure of a substrate 102 in which a plurality of transistors are provided and an insulating layer provided to cover these transistors, for example. The insulating layer over the transistors may have a single-layer structure or a stacked-layer structure. In FIG. 1B, an insulating layer 255a, an insulating layer 255b over the insulating layer 255a, and the insulating layer 255c over the insulating layer 255b are illustrated as insulating layers over the transistors. These insulating layers may have a depressed portion between adjacent light-emitting devices. In the example illustrated in FIG. 1B and the like, the insulating layer 255c is provided with a depressed portion. Note that the insulating layer 255c does not necessarily include a depressed portion between adjacent light-emitting devices.

In a cross-sectional view, an end portion of the insulating layer 255c preferably has a tapered shape with a taper angle less than 90°. This can improve coverage with a layer provided over the insulating layer 255c. FIG. 1B and the like illustrate an example structure in which part of the shape of the depressed portion provided in the insulating layer 255c has a taper angle substantially equal to that of the tapered shape of the pixel electrode 111a, the pixel electrode 111b, and the pixel electrode 111c; however, one embodiment of the present invention is not limited thereto. For example, the tapered shape of the pixel electrode 111a, the pixel electrode 111b, and the pixel electrode 111c may be different from the tapered shape of the depressed portion formed in the insulating layer 255c.

As each of the insulating layer 255a, the insulating layer 255b, and the insulating layer 255c, any of a variety of inorganic insulating films such as an oxide insulating film, a nitride insulating film, an oxynitride insulating film, and a nitride oxide insulating film can be suitably used. As each of the insulating layer 255a and the insulating layer 255c, an oxide insulating film or an oxynitride insulating film, such as a silicon oxide film, a silicon oxynitride film, or an aluminum oxide film, is preferably used. As the insulating layer 255b, a nitride insulating film or a nitride oxide insulating film, such as a silicon nitride film or a silicon nitride oxide film, is preferably used. Specifically, it is preferable that a silicon oxide film be used as each of the insulating layer 255a and the insulating layer 255c and that a silicon nitride film be used as the insulating layer 255b. The insulating layer 255b preferably has a function of an etching protective film.

Note that in this specification and the like, oxynitride refers to a material that contains more oxygen than nitrogen in its composition, and nitride oxide refers to a material that contains more nitrogen than oxygen in its composition. For example, silicon oxynitride refers to a material that contains more oxygen than nitrogen in its composition, and silicon nitride oxide refers to a material that contains more nitrogen than oxygen in its composition.

Structure examples of the layer 101 will be described later in Embodiment 4.

The protective layer 131 is preferably provided over the light-emitting device 130a, the light-emitting device 130b, and the light-emitting device 130c. Providing the protective layer 131 can improve the reliability of the light-emitting devices. The protective layer 131 may have a single-layer structure or a stacked-layer structure, and may have a stacked-layer structure including two or more layers.

There is no limitation on the conductivity of the protective layer 131. As the protective layer 131, at least one type of insulating films, semiconductor films, and conductive films can be used.

The protective layer 131 including an inorganic film can inhibit deterioration of the light-emitting devices by preventing oxidation of the common electrode 115 and inhibiting entry of impurities (e.g., moisture and oxygen) into the light-emitting devices, for example; thus, the reliability of the display apparatus can be improved.

As the protective layer 131, an inorganic insulating film such as an oxide insulating film, a nitride insulating film, an oxynitride insulating film, or a nitride oxide insulating film can be used, for example. Specific examples of these inorganic insulating films are as listed in the description of. In particular, the protective layer 131 preferably includes a nitride insulating film or a nitride oxide insulating film, and further preferably includes a nitride insulating film.

As the protective layer 131, an inorganic film containing In—Sn oxide (also referred to as ITO), In—Zn oxide, Ga—Zn oxide, Al—Zn oxide, indium gallium zinc oxide (In—Ga—Zn oxide, also referred to as IGZO), or the like can also be used. The inorganic film preferably has high resistance, specifically, higher resistance than the common electrode 115. The inorganic film may further contain nitrogen.

When light emitted from the light-emitting device is extracted through the protective layer 131, the protective layer 131 preferably has a high visible-light-transmitting property. For example, ITO, IGZO, and aluminum oxide are preferable because they are inorganic materials having a high visible-light-transmitting property.

The protective layer 131 can employ, for example, a stacked-layer structure of an aluminum oxide film and a silicon nitride film over the aluminum oxide film, or a stacked-layer structure of an aluminum oxide film and an IGZO film over the aluminum oxide film. Such a stacked-layer structure can inhibit entry of impurities (e.g., water and oxygen) into the EL layer.

Furthermore, the protective layer 131 may include an organic film. For example, the protective layer 131 may include both an organic film and an inorganic film. Examples of an organic material that can be used for the protective layer 131 include organic insulating materials that can be used for the layer 127.

The protective layer 131 may have a stacked structure of two layers which are formed by different film formation methods. Specifically, the first layer of the protective layer 131 may be formed by an ALD method, and the second layer of the protective layer 131 may be formed by a sputtering method.

A light-blocking layer may be provided on the surface of the substrate 120 on the resin layer 122 side. Moreover, a variety of optical members can be provided on the outer surface of the substrate 120. Examples of optical members include a polarizing plate, a retardation plate, a light diffusion layer (e.g., a diffusion film), an anti-reflective layer, and a light-condensing film. Furthermore, a surface protective layer such as an antistatic film inhibiting the attachment of dust, a water repellent film inhibiting the attachment of stain, a hard coat film inhibiting generation of a scratch caused by the use, or an impact-absorbing layer may be provided on the outer surface of the substrate 120. For example, it is preferable to provide, as the surface protective layer, a glass layer or a silica layer (SiOₓ layer) because the surface contamination and generation of damage can be inhibited. For the surface protective layer, DLC (diamond like carbon), aluminum oxide (AlOₓ), a polyester-based material, a polycarbonate-based material, or the like may be used. For the surface protective layer, a material having a high visible light transmittance is preferably used. For the surface protective layer, a material with high hardness is preferably used.

For the substrate 120, glass, quartz, ceramic, sapphire, a resin, a metal, an alloy, a semiconductor, or the like can be used. For the substrate through which light from the light-emitting device is extracted, a material that transmits the light is used. When a flexible material is used for the substrate 120, the flexibility of the display apparatus can be increased. Furthermore, a polarizing plate may be used as the substrate 120.

For the substrate 120, it is possible to use polyester resins such as polyethylene terephthalate (PET) and polyethylene naphthalate (PEN), a polyacrylonitrile resin, an acrylic resin, a polyimide resin, a polymethyl methacrylate resin, a polycarbonate (PC) resin, a polyethersulfone (PES) resin, polyamide resins (e.g., nylon and aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, cellulose nanofiber, and the like. Glass that is thin enough to have flexibility may be used as the substrate 120.

In the case where a circularly polarizing plate overlaps with the display apparatus, a highly optically isotropic substrate is preferably used as the substrate included in the display apparatus. A highly optically isotropic substrate has a low birefringence (i.e., a small amount of birefringence).

The absolute value of a retardation (phase difference) of a highly optically isotropic substrate is preferably less than or equal to 30 nm, further preferably less than or equal to 20 nm, still further preferably less than or equal to 10 nm.

Examples of a highly optically isotropic film include a triacetyl cellulose (TAC, also referred to as cellulose triacetate) film, a cycloolefin polymer (COP) film, a cycloolefin copolymer (COC) film, and an acrylic film.

In the case where a film is used as the substrate and the film absorbs water, the shape of the display apparatus might be changed, e.g., creases might be caused. Thus, as the substrate, a film with a low water absorption rate is preferably used. For example, a film with a water absorption rate lower than or equal to 1% is preferably used, a film with a water absorption rate lower than or equal to 0.1% is further preferably used, and a film with a water absorption rate lower than or equal to 0.01% is still further preferably used.

For the resin layer 122, a variety of curable adhesives such as a photocurable adhesive like an ultraviolet curable adhesive, a reactive curable adhesive, a thermosetting adhesive, and an anaerobic adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferable. A two-liquid-mixture-type resin may be used. An adhesive sheet or the like may be used.

A structure example different from that of the above-described display apparatus will be described below. Note that description of the same portions as those in the display apparatus described above is omitted in some cases. Furthermore, in drawings that are referred to later, the same hatching pattern is applied to portions having functions similar to those in the display apparatus described above, and the portions are not denoted by reference numerals in some cases.

### Structure Example 2

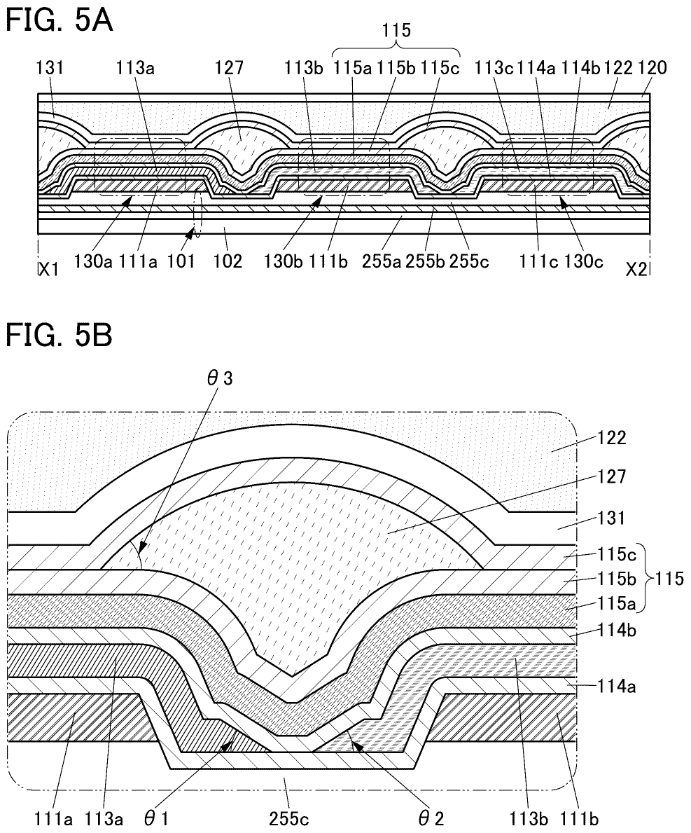

FIG. 5A is a cross-sectional view illustrating the display apparatus 100 of one embodiment of the present invention. FIG. 1A can be referred to for a top view. FIG. 5A is a cross-sectional view taken along the dashed-dotted line X1-X2 in FIG. 1A. FIG. 5B is an enlarged view of part of the cross-sectional view illustrated in FIG. 5A. FIG. 4A or FIG. 4B can be referred to for a cross-sectional view taken along the dashed-dotted line Y1-Y2.

The display apparatus 100 illustrated in FIG. 5A and FIG. 5B is different from the display apparatus described in <Structure example 1> mainly in that the first layer 113a, the second layer 113b, and the third layer 113c adjacent to one another are not in contact with one another.

The top surface and the side surface of the first layer 113a are covered with the common layer 114b. In a similar manner, the top surface and the side surface of the second layer 113b are covered with the common layer 114b. The top surface and the side surface of the third layer 113c are covered with the common layer 114b. The common layer 114b includes a region in contact with the common layer 114a in a region not overlapping with any of the first layer 113a, the second layer 113b, and the third layer 113c.

### Structure Example 3

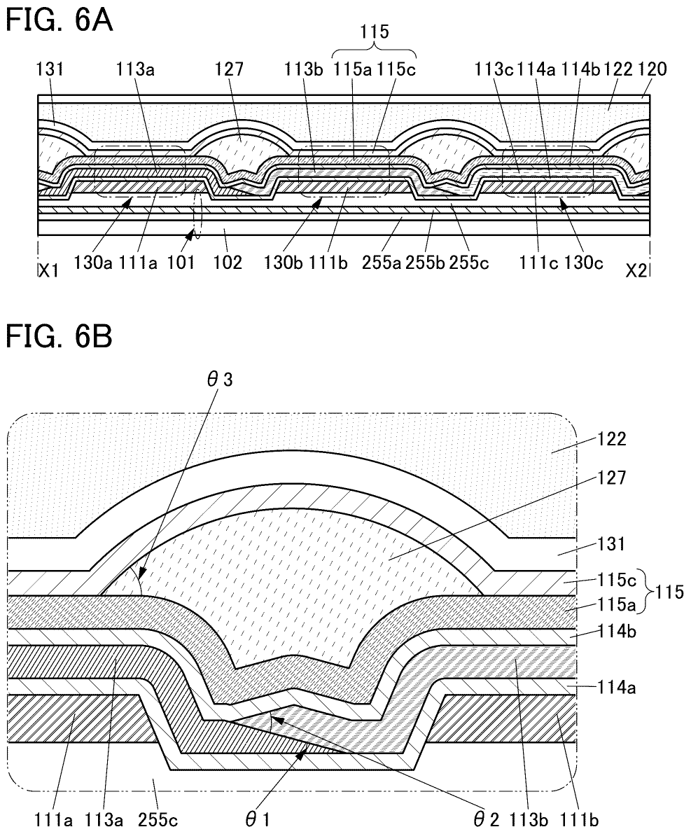

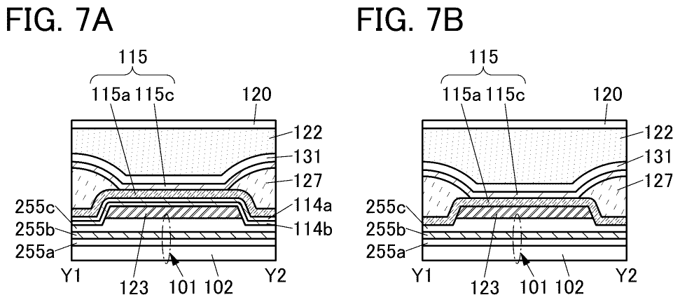

FIG. 6A is a cross-sectional view illustrating the display apparatus 100 of one embodiment of the present invention. FIG. 1A can be referred to for a top view. FIG. 6A is a cross-sectional view taken along the dashed-dotted line X1-X2 in FIG. 1A. FIG. 6B is an enlarged view of part of the cross-sectional view illustrated in FIG. 6A. FIG. 7A and FIG. 7B are cross-sectional views taken along the dashed-dotted line Y1-Y2.

The display apparatus 100 illustrated in FIG. 6A and FIG. 6B is different from the display apparatus described in <Structure example 1> mainly in that the common electrode 115 does not include the conductive layer 115b.

The common electrode 115 has a stacked-layer structure of the conductive layer 115a and the conductive layer 115c over the conductive layer 115a. The conductive layer 115a is provided to cover the EL layer (here, the common layer 114b), and the layer 127 is provided over the conductive layer 115a to fill a depressed portion between adjacent light-emitting devices. The conductive layer 115c is provided over the conductive layer 115a and the layer 127. The conductive layer 115c is in contact with the conductive layer 115a in a region overlapping with the pixel electrode 111a, a region overlapping with the pixel electrode 111b, and a region overlapping with the pixel electrode 111c.

For example, in the case where a material that is less likely to be oxidized is used for the conductive layer 115a, the layer 127 can be formed over the conductive layer 115a. When the conductive layer 115b is not provided, the manufacturing cost of the display apparatus can be reduced.

As illustrated in FIG. 7A, in the connection portion 140, the common layer 114a is provided over the conductive layer 123, the common layer 114b is provided over the common layer 114a, the conductive layer 115a is provided over the common layer 114b, and the conductive layer 115c is provided over the conductive layer 115a. Note that one or both of the common layer 114a and the common layer 114b are not necessarily provided in the connection portion 140. As illustrated in FIG. 7B, the conductive layer 123 may be directly connected to the common electrode 115 (the conductive layer 115a and the conductive layer 115c) without providing the common layer 114a and the common layer 114b.

Note that the structure of the common electrode 115 described in <Structure example 3> can also be applied to other structure examples.

### Structure Example 4

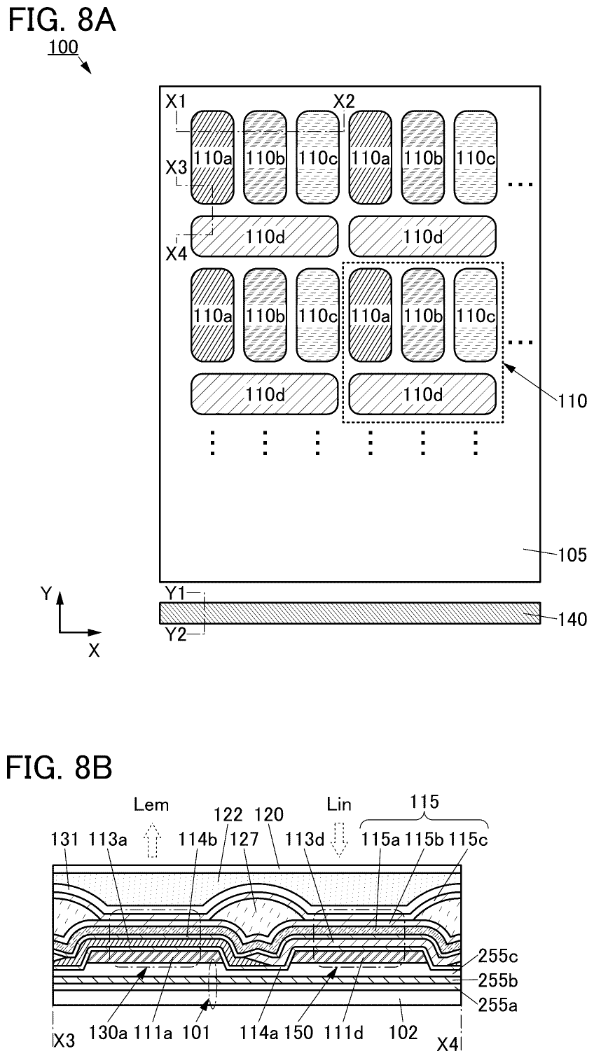

FIG. 8A is a top view illustrating the display apparatus 100 of one embodiment of the present invention.

The pixel 110 illustrated in FIG. 8A is composed of four subpixels: the subpixel 110a, the subpixel 110b, the subpixel 110c, and a subpixel 110d.

The subpixel 110a, the subpixel 110b, the subpixel 110c, and the subpixel 110d can be configured to include light-emitting devices whose emission colors are different. The subpixel 110a, the subpixel 110b, the subpixel 110c, and the subpixel 110d are subpixels of four colors of R, G, B, and W, subpixels of four colors of R, G, B, and Y, or subpixels of four types of R, G, B, and IR, for example.

The display apparatus of one embodiment of the present invention may include a light-receiving device in the pixel.

Three of the four subpixels included in the pixel 110 illustrated in FIG. 8A may each be configured to include a light-emitting device and the other one may be configured to include a light-receiving device.

For example, a pn or pin photodiode can be used as the light-receiving device. The light-receiving device functions as a photoelectric conversion device (also referred to as a photoelectric conversion element) that detects light entering the light-receiving device and generates electric charge. The amount of electric charge generated from the light-receiving device depends on the amount of light entering the light-receiving device.

The light-receiving device can detect one or both of visible light and infrared light. In the case of detecting visible light, for example, one or more of blue light, violet light, bluish violet light, green light, yellowish green light, yellow light, orange light, red light, and the like can be detected. The infrared light is preferably detected because an object can be detected even in a dark environment.

It is particularly preferable to use an organic photodiode including a layer containing an organic compound as the light-receiving device. An organic photodiode, which is easily made thin, lightweight, and large in area and has a high degree of freedom for shape and design, can be used for a variety of display apparatuses.

In one embodiment of the present invention, an organic EL device is used as the light-emitting device, and an organic photodiode is used as the light-receiving device. The organic EL device and the organic photodiode can be formed over the same substrate. Thus, the organic photodiode can be incorporated in the display apparatus including the organic EL device.

The light-receiving device is driven by application of reverse bias between the pixel electrode and the common electrode, whereby light entering the light-receiving device can be detected and electric charge can be generated and extracted as a current.

Embodiment 6 can be referred to for the structure and the materials of the light-receiving device.

FIG. 8B is a cross-sectional view taken along a dashed-dotted line X3-X4 in FIG. 8A. FIG. 1B can be referred to for a cross-sectional view taken along the dashed-dotted line X1-X2 in FIG. 8A, and FIG. 4A or FIG. 4B can be referred to for a cross-sectional view taken along the dashed-dotted line Y1-Y2.

As illustrated in FIG. 8B, in the display apparatus 100, the light-emitting device 130a and a light-receiving device 150 are provided over the layer 101 and the substrate 120 is bonded onto the light-emitting device and the light-receiving device with the resin layer 122. The protective layer 131 may be provided to cover the light-emitting device 130a and the light-receiving device 150, and the substrate 120 may be bonded onto the protective layer 131 with the resin layer 122. In a region between the light-emitting device and the light-receiving device adjacent to each other, the layer 127 is provided. The layer 127 is also preferably provided in a region between adjacent light-receiving devices.

FIG. 8B illustrates an example in which light is emitted from the light-emitting device 130a to the substrate 120 side and light enters the light-receiving device 150 from the substrate 120 side (see light Lem and light Lin).

The structure of the light-emitting device 130a is as described above.

The light-receiving device 150 includes a pixel electrode 111d over the insulating layer 255c, a fourth layer 113d over the pixel electrode 111d, the common layer 114b over the fourth layer 113d, and the common electrode 115 over the common layer 114b. The fourth layer 113d includes at least an active layer.

The fourth layer 113d includes at least an active layer. The fourth layer 113d may further include a functional layer. Examples of the functional layer include carrier-transport layers (a hole-transport layer and an electron-transport layer) and carrier-blocking layers (a hole-blocking layer and an electron-blocking layer). For example, the fourth layer 113d can include an active layer and a carrier-blocking layer (a hole-blocking layer or an electron-blocking layer) or a carrier-transport layer (an electron-transport layer or a hole-transport layer) over the active layer.

The fourth layer 113d is a layer provided in the light-receiving device 150, not in the light-emitting devices. Note that the functional layer other than the active layer included in the fourth layer 113d may include the same material as the functional layer other than the light-emitting layer included in each of the first layer 113a to the third layer 113c. Meanwhile, the common layer 114a and the common layer 114b are each one continuous layer shared by the light-emitting device and the light-receiving device.

Here, the display apparatus of one embodiment of the present invention includes a layer shared by the light-receiving device and the light-emitting device (the layer can be also regarded as a continuous layer shared by the light-receiving device and the light-emitting device) in some cases. The function of such a layer in the light-emitting device is different from its function in the light-receiving device in some cases. In this specification, the name of a component is based on its function in the light-emitting device in some cases. For example, a hole-injection layer functions as a hole-injection layer in the light-emitting device and functions as a hole-transport layer in the light-receiving device. Similarly, an electron-injection layer functions as an electron-injection layer in the light-emitting device and functions as an electron-transport layer in the light-receiving device. A layer shared by the light-receiving device and the light-emitting device may have the same function in both the light-emitting device and the light-receiving device. For example, the hole-transport layer functions as a hole-transport layer in both the light-emitting device and the light-receiving device, and the electron-transport layer functions as an electron-transport layer in both the light-emitting device and the light-receiving device.

Here, the first layer 113a may include a region in contact with the adjacent fourth layer 113d. FIG. 8B illustrates an example in which the fourth layer 113d is provided to cover the end portion of the first layer 113a and the vicinity thereof. For example, after the first layer 113a is formed, the fourth layer 113d can be formed to cover the end portion of the first layer 113a and the vicinity thereof. Note that the formation order of the first layer 113a, the second layer 113b, the third layer 113c, and the fourth layer 113d is not particularly limited. After the fourth layer 113d is formed, the first layer 113a may be formed to cover an end portion of the fourth layer 113d and the vicinity thereof.

Note that a structure in which the first layer 113a, the second layer 113b, the third layer 113c, and the fourth layer 113d adjacent to one another are not in contact with one another may be employed.

In a cross-sectional view of the display apparatus, a side surface of the fourth layer 113d preferably has a tapered shape. Specifically, the angle formed by the side surface of the fourth layer 113d and the formation surface is preferably less than 90°. When the side surface of the fourth layer 113d has a tapered shape, coverage with the common layer 114b provided over the fourth layer 113d can be improved. The angle formed by the side surface of the fourth layer 113d and the formation surface of the fourth layer 113d (here, the top surface and the side surface of the first layer 113a) is preferably less than 90°, further preferably less than or equal to 60°, still further preferably less than or equal to 45°, yet still further preferably less than or equal to 20°. A manufacturing method similar to that of the light-emitting device can be employed to manufacture the light-receiving device.

Note that the structure of the light-receiving device 150 described in <Structure example 4> can also be applied to other structure examples.

Although FIG. 8A illustrates an example in which an aperture ratio (also referred to as size or size of the light-emitting region or the light-receiving region) of the subpixel 110d is higher than those of the subpixel 110a, the subpixel 110b, and the subpixel 110c, one embodiment of the present invention is not limited thereto. The aperture ratio of each of the subpixel 110a, the subpixel 110b, the subpixel 110c, and the subpixel 110d can be determined as appropriate. The subpixel 110a, the subpixel 110b, the subpixel 110c, and the subpixel 110d may have different aperture ratios, or two or more of them may have the same or substantially the same aperture ratio.

The subpixel 110d may have a higher aperture ratio than at least one of the subpixel 110a, the subpixel 110b, and the subpixel 110c. The wide light-receiving area of the subpixel 110d can make it easy to detect an object in some cases. For example, in some cases, the aperture ratio of the subpixel 110d is higher than the aperture ratio of each of the other subpixels depending on the resolution of the display apparatus and the circuit structure or the like of the subpixel. The subpixel 110d may have a lower aperture ratio than at least one of the subpixel 110a, the subpixel 110b, and the subpixel 110c. A small light-receiving area of the subpixel 110d leads to a narrow image-capturing range, inhibits a blur in a capturing result, and improves the definition. Accordingly, high-resolution or high-definition image capturing can be performed, which is preferable.

As described above, the subpixel 110d can have a detection wavelength, a resolution, and an aperture ratio that are suitable for the intended use.

### Structure Example 5

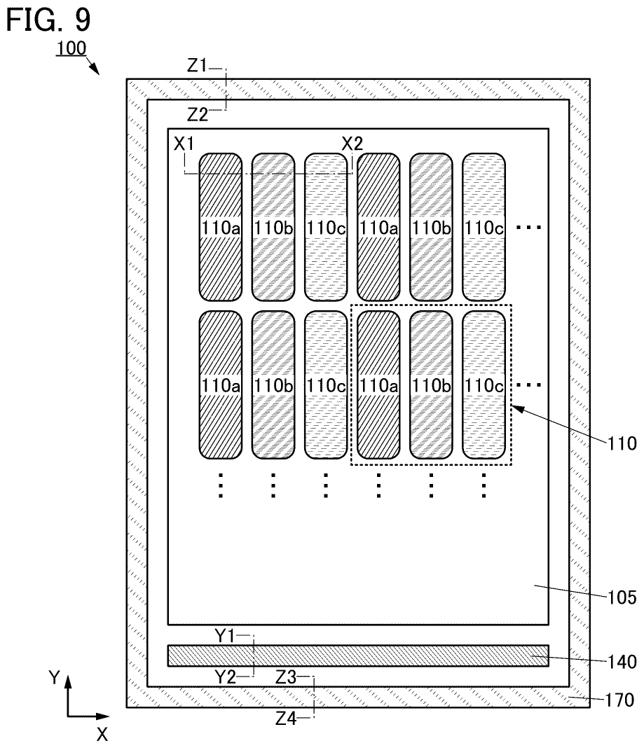

FIG. 9 is a top view illustrating the display apparatus 100 of one embodiment of the present invention.

The display apparatus 100 illustrated in FIG. 9 is different from the display apparatus described in <Structure example 1> mainly in including an insulating layer 170.

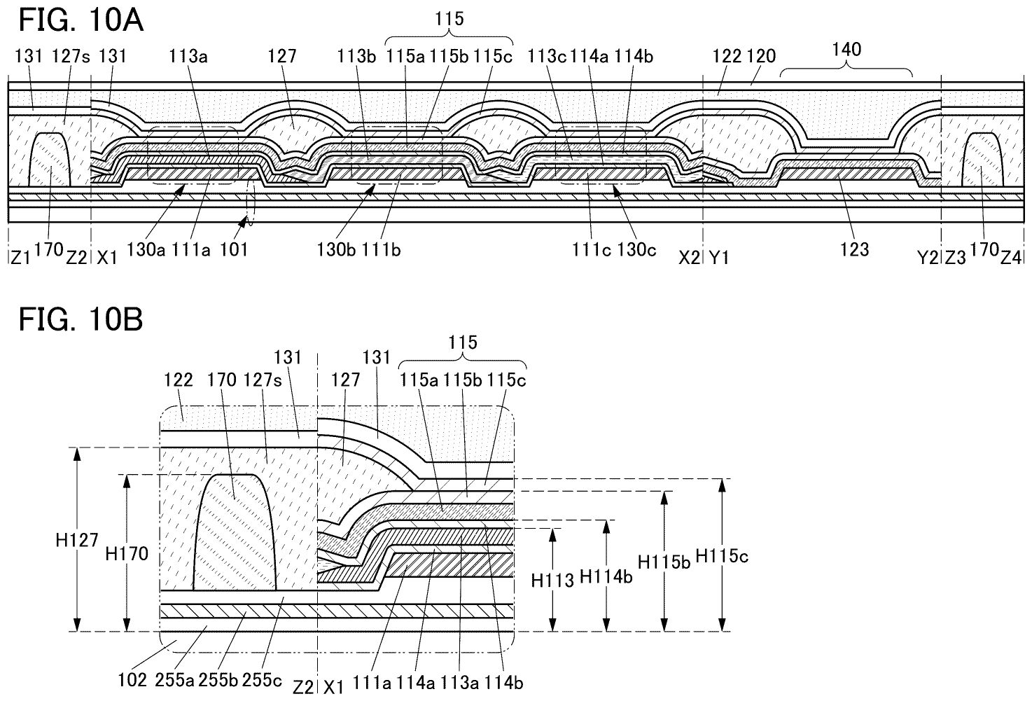

FIG. 10A is a cross-sectional view taken along the dashed-dotted lines X1-X2, Y1-Y2, Z1-Z2, and Z3-Z4 in FIG. 9. FIG. 10B is an enlarged view of part of the cross-sectional view illustrated in FIG. 10A.

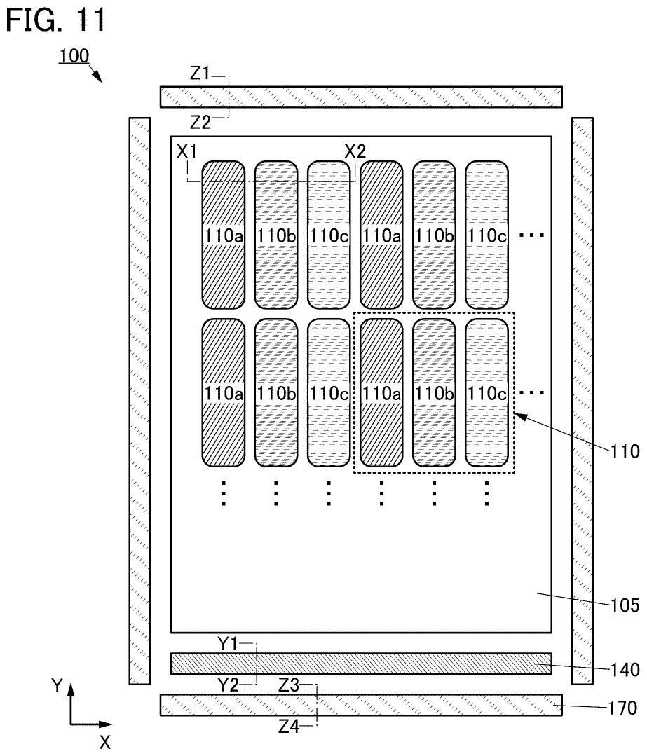

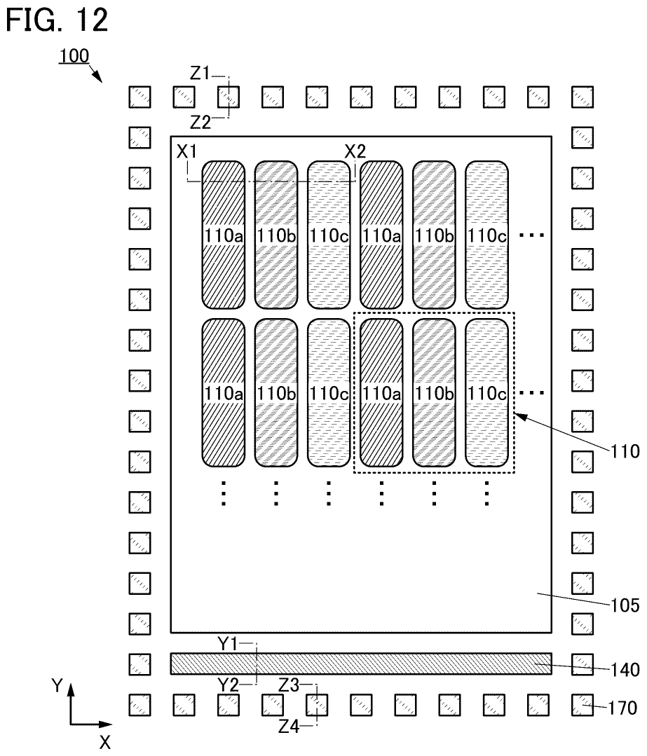

As illustrated in FIG. 9, the insulating layer 170 is preferably provided to surround the outside of the pixel portion 105 and the connection portion 140. The top surface shape of the insulating layer 170 is not particularly limited and can be a belt-like shape, an L shape, a U shape, a frame-like shape, or the like. The top surface shape of the insulating layer 170 may have rounded corners. The top surface shape of the insulating layer 170 may also be an ellipse or a circle. The number of the insulating layer 170 may be one or more. FIG. 9 illustrates an example in which the top surface of the insulating layer 170 has a frame-like shape. FIG. 11 illustrates an example in which four insulating layers 170 with a band-like shape surround the outside of the pixel portion 105 and the connection portion 140. FIG. 12 illustrates an example in which the insulating layers 170 with a rectangular shape with a number larger than four surround the outside of the pixel portion 105 and the connection portion 140.

Although FIG. 9 illustrates an example in which the insulating layer 170 is positioned outside the pixel portion 105 and the connection portion 140 in the top view, the position of the insulating layer 170 is not particularly limited. For example, the insulating layer 170 may be provided inside the pixel portion 105 or between the pixel portion 105 and the connection portion 140.

As illustrated in FIG. 10B, in the cross-sectional view of the display apparatus, the level of the top surface of the insulating layer 170 is preferably at least higher than the levels of the top surfaces of the first layer 113a, the second layer 113b, and the third layer 113c.

Note that in this specification and the like, the level of the top surface of a layer refers to the longest distance from a reference surface to the top surface of the layer.

FIG. 10B illustrates a level H170 of the top surface of the insulating layer 170 and a level H113 of the top surface of the first layer 113a. Note that the level H170 refers to the level of the top surface of the insulating layer 170 at its highest point. The level H113 refers to the level of the top surface of the first layer 113a, the second layer 113b, or the third layer 113c at its highest point. Although FIG. 10B illustrates the level H170 and the level H113 with the top surface of the substrate 102 as a reference surface, there is no particular limitation on the reference surface. For example, the top surface of the insulating layer 255b may be a reference surface.

When the level H170 of the top surface of the insulating layer 170 is made higher than the level H113 of the top surfaces of the first layer 113a, the second layer 113b, and the third layer 113c, in forming the first layer 113a, the second layer 113b, and the third layer 113c using fine metal masks, the insulating layer 170 can function as a support layer supporting the fine metal masks. Specifically, when the fine metal mask is provided in contact with the top surface of the insulating layer 170 to form the first layer 113a, the second layer 113b, or the third layer 113c, the fine metal mask can be inhibited from being in contact with the top surface of the common layer 114a, for example. The insulating layer 170 can also be referred to as a partition wall or a spacer. Furthermore, the fine metal mask can be inhibited from being in contact with the top surface of the first layer 113a, the second layer 113b, or the third layer 113c formed using the fine metal mask.

Here, the case where the first layer 113a, the second layer 113b, and the third layer 113c are formed in this order is described as an example. In the pixel portion 105, the common layer 114a is exposed in forming the first layer 113a, the first layer 113a and the common layer 114a are exposed in forming the second layer 113b, and the first layer 113a, the second layer 113b, and the common layer 114a are exposed in forming the third layer 113c. Accordingly, a fine metal mask used in forming the first layer 113a, a fine metal mask used in forming the second layer 113b, and a fine metal mask used in forming the third layer 113c can each be in contact with any one or more of the first layer 113a, the second layer 113b, the third layer 113c, and the common layer 114a. When the fine metal mask is in contact with any one or more of these layers, a difference in characteristics (e.g., luminance and color tone) of the light-emitting device might be caused between a region in contact with and a surrounding region not in contact with the fine metal mask.

In the display apparatus of one embodiment of the present invention, the insulating layer 170 is provided and the level H170 of the top surface of the insulating layer 170 is made higher than the level H113 of the top surfaces of the first layer 113a, the second layer 113b, and the third layer 113c, whereby the fine metal masks used in forming the first layer 113a, the second layer 113b, and the third layer 113c can each be inhibited from being in contact with any one or more of the first layer 113a, the second layer 113b, the third layer 113c, and the common layer 114a. Thus, a display apparatus having high display quality can be provided.

The level H170 of the top surface of the insulating layer 170 is preferably higher than a level H114b of the top surface of the common layer 114b, further preferably higher than a level H115b of the top surface of the conductive layer 115b. Note that the level H114b refers to the level of the top surface of the common layer 114b at its highest point. Similarly, the level H115b refers to the level of the top surface of the conductive layer 115b at its highest point.

Here, the common layer 114a, the common layer 114b, the conductive layer 115a, the conductive layer 115b, and the conductive layer 115c can be formed using area masks. When the level H170 of the top surface of the insulating layer 170 is made higher than the level H115b of the top surface of the conductive layer 115b, in forming the common layer 114a, the common layer 114b, the conductive layer 115a, and the conductive layer 115b using area masks, the insulating layer 170 can function as a support layer supporting the area masks.

For the insulating layer 170, one or both of an organic material and an inorganic material can be used. An organic material can be suitably used for the insulating layer 170. As the organic material, a photosensitive organic resin is preferably used, and for example, a photosensitive resin composite containing an acrylic resin is preferably used.

Alternatively, for the insulating layer 170, it is possible to use an acrylic resin, a polyimide resin, an epoxy resin, an imide resin, a polyamide resin, a polyimide-amide resin, a silicone resin, a siloxane resin, a benzocyclobutene-based resin, a phenol resin, precursors of these resins, or the like. Alternatively, for the insulating layer 170, it is possible to use an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin. A photoresist may be used for the photosensitive resin. As the photosensitive organic resin, either a positive material or a negative material may be used.

A layer 127s is preferably provided to cover the insulating layer 170. For the layer 127s, a material that can be used for the layer 127 can be used. For example, the layer 127s can be formed through the same steps as the layer 127. Note that the layer 127s and the layer 127 may be joined together. Alternatively, the layer 127s and the layer 127 may be separated from each other. In the case where the layer 127s is provided over the insulating layer 170, the layer 127s is an insulating layer. In the case where the layer 127s is an insulating layer, the layer 127s may be formed using the same material as or different materials from the insulating layer 170.

In the case where the layer 127s is provided over the insulating layer 170, a level H127 of the top surface of the layer 127s is higher than the level H170 of the top surface of the insulating layer 170. With such a structure, when the conductive layer 115c is formed using an area mask, the layer 127s can function as a support layer supporting the area mask. Specifically, the area mask is provided to be in contact with the top surface of the layer 127s to form the conductive layer 115c, whereby the area mask can be inhibited from being in contact with the conductive layer 115b or the conductive layer 115c. Note that the level H127 refers to the level of the top surface the layer 127s at its highest point.

The level H127 of the top surface of the layer 127s is preferably higher than a level H115c of the top surface of the conductive layer 115c. When the level H127 of the top surface of the layer 127s is made higher than the level H115c of the top surface of the conductive layer 115c, in forming the conductive layer 115c using an area mask, the layer 127s can function as a support layer supporting the area mask.

Note that the level H127 of the top surface of the layer 127s may be lower than the level H170 of the top surface of the insulating layer 170. In that case, the level H170 of the top surface of the insulating layer 170 is preferably higher than the level H115c of the top surface of the conductive layer 115c. When the level H170 of the top surface of the insulating layer 170 is made higher than the level H115c of the top surface of the conductive layer 115c, in forming the conductive layer 115c using an area mask, the insulating layer 170 can function as a support layer supporting the area mask. It can be said that a stack of the insulating layer 170 and the layer 127s functions as a support layer supporting the area mask.

The insulating layer 170 can be provided over the insulating layer 255c. The insulating layer 170 is preferably formed before the common layer 114a is formed. For example, the insulating layer 170 can be formed after the pixel electrode 111a, the pixel electrode 111b, the pixel electrode 111c, and the conductive layer 123 are formed, and then the common layer 114a can be formed. Note that the formation order of the pixel electrode 111a, the pixel electrode 111b, the pixel electrode 111c, the conductive layer 123, and the insulating layer 170 is not particularly limited.

After the light-emitting device is formed, the insulating layer 170 may be removed from the display apparatus 100. For example, the insulating layer 170 is provided outside the pixel portion 105 and the connection portion 140; a region where the insulating layer 170 is formed is separated from the pixel portion 105 and the connection portion 140 after the light-emitting device or the like is formed, whereby the region where the insulating layer 170 is formed can be removed from the display apparatus 100. When the region where the insulating layer 170 is formed is removed, the display apparatus 100 can be small in size.

Note that the structure of the insulating layer 170 described in <Structure example 5> can also be applied to other structure examples.

In the display apparatus of one embodiment of the present invention, an insulating layer covering the end portion of the top surface of the pixel electrode 111 is not provided between the pixel electrode 111 and the EL layer. Thus, the distance between adjacent light-emitting devices can be extremely shortened. Accordingly, the display apparatus can have a high resolution or a high definition.

In one embodiment of the present invention, the common electrode 115 has a stacked-layer structure. In addition, between adjacent pixel electrodes 111, the layer 127 is provided over the conductive layer 115b and the conductive layer 115c is provided over the conductive layer 115b and the layer 127. The layer 127 is provided to fill a depressed portion generated between adjacent pixel electrodes 111 and can improve coverage with the conductive layer 115c. Consequently, a connection defect due to step disconnection of the common electrode 115 and an increase in electric resistance can be inhibited.

The top surface and the side surface of the pixel electrode 111 are covered with the EL layer. This can prevent the pixel electrode 111 from being in contact with the common electrode 115, thereby inhibiting a short circuit. Furthermore, the EL layer is covered with the conductive layer 115a and the conductive layer 115b. In the step of forming the layer 127 over the conductive layer 115b, the EL layer is not exposed, so that the EL layer can be inhibited from being damaged. Thus, a display apparatus having high display quality can be provided.

This embodiment can be combined with the other embodiments as appropriate. In this specification, in the case where a plurality of structure examples are described in one embodiment, the structure examples can be combined as appropriate.

### Embodiment 2

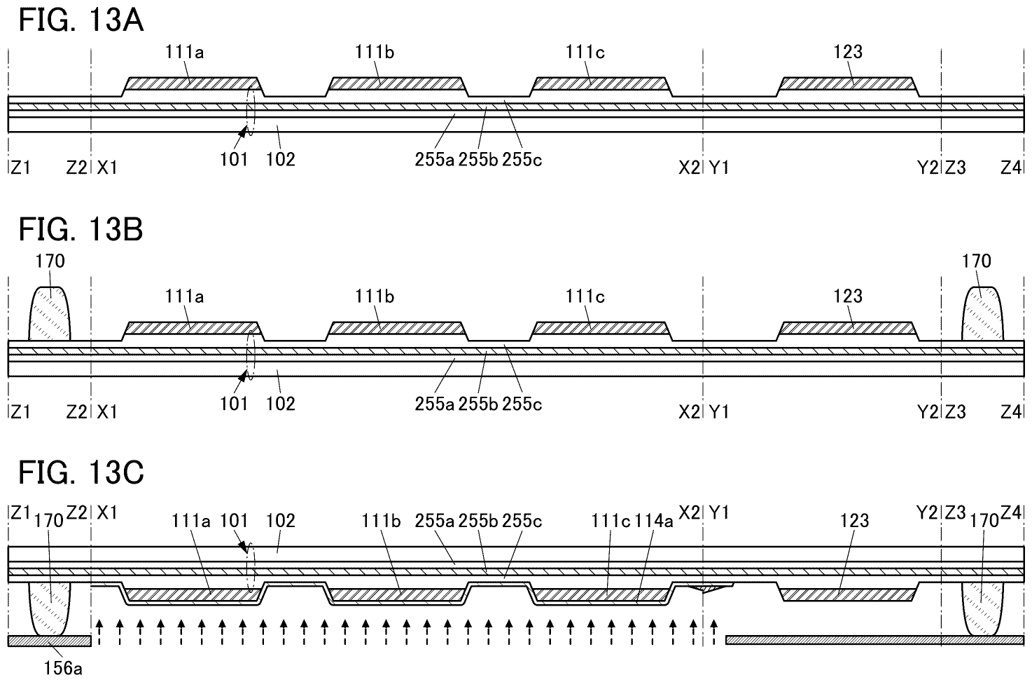

In this embodiment, a method for manufacturing a display apparatus of one embodiment of the present invention will be described with reference to FIG. 13A to FIG. 18B. Note that as for a material and a formation method of each component, portions similar to the portions described in Embodiment 1 are not described in some cases. The structure of the light-emitting device will be described in detail in Embodiment 4.

Thin films included in the display apparatus (e.g., insulating films, semiconductor films, and conductive films) can be formed by any of a sputtering method, a chemical vapor deposition (CVD) method, a vacuum evaporation method, a pulsed laser deposition (PLD) method, an atomic layer deposition (ALD) method, and the like. Examples of a CVD method include a plasma-enhanced CVD (PECVD) method and a thermal CVD method. An example of a thermal CVD method is a metal organic chemical vapor deposition (MOCVD) method.

Alternatively, thin films included in the display apparatus (e.g., insulating films, semiconductor films, and conductive films) can be formed by a wet film formation method such as spin coating, dipping, spray coating, ink-jetting, dispensing, screen printing, offset printing, a doctor knife method, slit coating, roll coating, curtain coating, or knife coating.

Specifically, for manufacture of the light-emitting device, a vacuum process such as an evaporation method and a solution process such as a spin coating method or an inkjet method can be used. Examples of an evaporation method include physical vapor deposition methods (PVD methods) such as a sputtering method, an ion plating method, an ion beam evaporation method, a molecular beam evaporation method, and a vacuum evaporation method, and a chemical vapor deposition method (CVD method). Specifically, functional layers (e.g., a hole-injection layer, a hole-transport layer, a hole-blocking layer, a light-emitting layer, an electron-blocking layer, an electron-transport layer, an electron-injection layer, and a charge-generation layer) included in the EL layer can be formed by a method such as an evaporation method (e.g., a vacuum evaporation method), a coating method (e.g., a dip coating method, a die coating method, a bar coating method, a spin coating method, or a spray coating method), or a printing method (e.g., an inkjet method, a screen printing (stencil) method, an offset printing (planography) method, a flexography (relief printing) method, a gravure printing method, or a micro-contact printing method).

Thin films included in the display apparatus can be processed by a photolithography method or the like. Alternatively, the thin films may be processed by a nanoimprinting method, a sandblasting method, a lift-off method, or the like. Alternatively, island-shaped thin films may be directly formed by a film formation method using a shielding mask such as a metal mask.

There are the following two typical examples of photolithography methods. In one of the methods, a resist mask is formed over a thin film to be processed, the thin film is processed by etching or the like, and then the resist mask is removed. In the other method, after a photosensitive thin film is formed, light exposure and development are performed, so that the thin film is processed into a desired shape.

As light used for light exposure in a photolithography method, it is possible to use light with the i-line (wavelength: 365 nm), light with the g-line (wavelength: 436 nm), light with the h-line (wavelength: 405 nm), or combined light of any of them. Alternatively, ultraviolet rays, KrF laser light, ArF laser light, or the like can be used. Light exposure may be performed by liquid immersion light exposure technique. As the light used for light exposure, extreme ultraviolet (EUV) light or X-rays may also be used. Furthermore, instead of the light used for light exposure, an electron beam can be used. It is preferable to use extreme ultraviolet light, X-rays, or an electron beam because extremely minute processing can be performed. Note that a photomask is not needed when light exposure is performed by scanning with a beam such as an electron beam. For etching of thin films, a dry etching method, a wet etching method, a sandblast method, or the like can be used.

Here, a method for manufacturing the display apparatus illustrated in FIG. 10A is described.

First, the insulating layer 255a, the insulating layer 255b, and the insulating layer 255c are formed in this order over the substrate 102.

Next, the pixel electrode 111a, the pixel electrode 111b, the pixel electrode 111c, and the conductive layer 123 are formed over the insulating layer 255c (FIG. 13A). The pixel electrode can be formed by a sputtering method or a vacuum evaporation method, for example.

Then, the insulating layer 170 is formed over the insulating layer 255c (FIG. 13B). For the insulating layer 170, one or both of an organic material and an inorganic material can be used. A photosensitive organic resin can be suitably used for the insulating layer 170. In the case of using the photosensitive organic resin, the level H170 of the top surface of the insulating layer 170 can be controlled by adjusting the light exposure time.

Then, the pixel electrode is preferably subjected to hydrophobic treatment. The hydrophobic treatment can change the property of the surface of a processing target from hydrophilic to hydrophobic, or can improve the hydrophobic property of the surface of the processing target. The hydrophobic treatment for the pixel electrode can improve adhesion between the pixel electrode and a film to be formed in a later step, thereby inhibiting film separation. Note that the hydrophobic treatment is not necessarily performed.

The hydrophobic treatment can be performed by fluorine modification of the pixel electrode, for example. The fluorine modification can be performed by treatment using a gas containing fluorine, heat treatment, plasma treatment in a gas atmosphere containing fluorine, or the like. A fluorine gas can be used as the gas containing fluorine, and for example, a fluorocarbon gas can be used. As the fluorocarbon gas, a low-molecular-weight carbon fluoride gas such as a carbon tetrafluoride (CF₄) gas, a C₄F₆ gas, a C₂F₆ gas, a C₄F₈ gas, or C₅F₈ can be used, for example. Alternatively, as the gas containing fluorine, an SF₆ gas, an NF₃ gas, a CHF₃ gas, or the like can be used, for example. Moreover, a helium gas, an argon gas, a hydrogen gas, or the like can be added to any of the above gases as appropriate.

After plasma treatment is performed in a gas atmosphere containing a Group 18 element such as argon, treatment using a silylating agent is performed on the surface of the pixel electrode, so that the surface of the pixel electrode can have a hydrophobic property. As the silylating agent, hexamethyldisilazane (HMDS), trimethylsilylimidazole (TMSI), or the like can be used. Alternatively, after plasma treatment is performed in a gas atmosphere containing a Group 18 element such as argon, treatment using a silane coupling agent is performed on the surface of the pixel electrode, so that the surface of the pixel electrode can have a hydrophobic property.

Plasma treatment on the surface of the pixel electrode in a gas atmosphere containing a Group 18 element such as argon can apply damage to the surface of the pixel electrode. Accordingly, a methyl group included in the silylating agent such as HMDS is likely to bond to the surface of the pixel electrode. In addition, silane coupling by the silane coupling agent is likely to occur. As described above, treatment using a silylating agent or a silane coupling agent performed on the surface of the pixel electrode after plasma treatment in a gas atmosphere containing a Group 18 element such as argon enables the surface of the pixel electrode to have a hydrophobic property.

The treatment using a silylating agent, a silane coupling agent, or the like can be performed by application of the silylating agent, the silane coupling agent, or the like by a spin coating method, a dipping method, or the like. Alternatively, the treatment using a silylating agent, a silane coupling agent, or the like can be performed by forming a film containing the silylating agent, a film containing the silane coupling agent, or the like over the pixel electrode or the like by a gas phase method, for example. In a gas phase method, first, a material containing a silylating agent, a material containing a silane coupling agent, or the like is evaporated so that the silylating agent, the silane coupling agent, or the like is contained in an atmosphere. Next, a substrate where the pixel electrode and the like are formed is put in the atmosphere. Accordingly, a film containing the silylating agent, the silane coupling agent, or the like can be formed over the pixel electrode, so that the surface of the pixel electrode can have a hydrophobic property.

Next, the common layer 114a is formed over the pixel electrode 111a, the pixel electrode 111b, the pixel electrode 111c, and the insulating layer 255c (FIG. 13C). The common layer 114b can be formed by an evaporation method, specifically a vacuum evaporation method, for example. The common layer 114b may be formed by a transfer method, a printing method, an inkjet method, or a coating method.

As illustrated in FIG. 13C, the common layer 114a is not formed over the conductive layer 123. For example, a mask for specifying a film formation area (also referred to as an area mask, a rough metal mask, or the like to be distinguished from a fine metal mask) is used, so that the common layer 114a can be formed only in a desired region. FIG. 13C schematically illustrates a state where the common layer 114a is formed using an area mask 156a. In forming the common layer 114a, the area mask 156a may be provided to be in contact with the top surface of the insulating layer 170. Accordingly, the area mask 156a is not in contact with any of the pixel electrode 111a, the pixel electrode 111b, the pixel electrode 111c, and the conductive layer 123, so that damage to these layers can be inhibited. Note that as illustrated in FIG. 4A, the common layer 114a may be formed over the conductive layer 123.

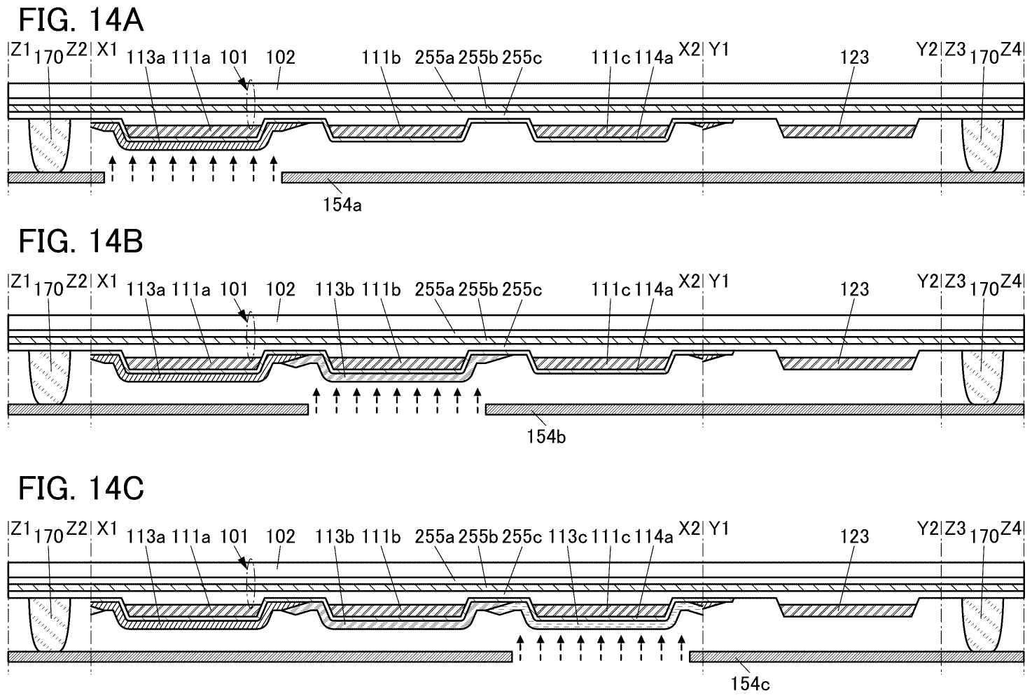

Next, the first layer 113a is formed over the pixel electrode 111a (FIG. 14A). The first layer 113a can be formed by an evaporation method, specifically, a vacuum evaporation method, using a fine metal mask, for example. The first layer 113a may be formed by a transfer method, a printing method, an inkjet method, or a coating method.

FIG. 14A schematically illustrates a state where the first layer 113a is formed using a fine metal mask 154a. FIG. 14A illustrates a state of forming the first layer 113a by a so-called face-down method, in which deposition is performed with the substrate turned upside down so that the formation surface of the first layer 113a faces downward.

The fine metal mask 154a is preferably provided to be in contact with the top surface of the insulating layer 170. Accordingly, the fine metal mask 154a is not in contact with the common layer 114a, so that damage to the common layer 114a can be inhibited. In a similar manner, the fine metal mask 154a is not in contact with the conductive layer 123, so that damage to the conductive layer 123 can be inhibited.

The fine metal mask 154a has an opening in a region to be the subpixel 110a. Accordingly, as illustrated in FIG. 14A, the first layer 113a can be selectively formed in a region overlapping with the pixel electrode 111a and the vicinity thereof. Note that in the vacuum evaporation method using a fine metal mask, deposition is performed in an area wider than an opening of the fine metal mask in many cases. The side surface of the first layer 113a has a tapered shape.

The end portion of the first layer 113a is preferably positioned outward from the end portion of the pixel electrode 111a. Such a structure can increase the aperture ratio of the pixel. Covering the top surface and the side surface of the pixel electrode 111a with the common layer 114a and the first layer 113a inhibits contact between the pixel electrode 111a and the common electrode 115, thereby inhibiting a short circuit in the light-emitting device. Furthermore, the distance between the light-emitting region of the light-emitting device (the region where the first layer 113a and the pixel electrode 111a overlap with each other) and the end portion of the first layer 113a can be increased. Using a region that is away from the end portion of the first layer 113a as the light-emitting region can reduce variation in characteristics of the light-emitting device 130a.

Next, the second layer 113b is formed over the pixel electrode 111b (FIG. 14B). For the formation of the second layer 113b, a method that can be used for the formation of the first layer 113a can be used.

FIG. 14B schematically illustrates a state where the second layer 113b is formed using a fine metal mask 154b. The fine metal mask 154b is preferably provided to be in contact with the top surface of the insulating layer 170. Accordingly, the fine metal mask 154b is in contact with neither the first layer 113a nor the common layer 114a, so that damage to these layers can be inhibited. In a similar manner, the fine metal mask 154b is not in contact with the conductive layer 123, so that damage to the conductive layer 123 can be inhibited.

The fine metal mask 154b has an opening in a region to be the subpixel 110b. Accordingly, as illustrated in FIG. 14B, the second layer 113b can be selectively formed in a region overlapping with the pixel electrode 111b and the vicinity thereof. In FIG. 14B, an example in which the end portion of the second layer 113b overlap with the adjacent first layer 113a is illustrated. Note that the second layer 113b may be separated from the first layer 113a without overlapping with the first layer 113a. The side surface of the second layer 113b has a tapered shape.

The end portion of the second layer 113b is preferably positioned outward from the end portion of the pixel electrode 111b. Such a structure can increase the aperture ratio of the pixel. Covering the top surface and the side surface of the pixel electrode 111b with the common layer 114a and the second layer 113b inhibits contact between the pixel electrode 111b and the common electrode 115, thereby inhibiting a short circuit in the light-emitting device. Furthermore, the distance between the light-emitting region of the light-emitting device (a region where the second layer 113b and the pixel electrode 111b overlap with each other) and the end portion of the second layer 113b can be increased. Using a region that is away from the end portion of the second layer 113b as the light-emitting region can reduce variation in characteristics of the light-emitting device 130b.

Next, the third layer 113c is formed over the pixel electrode 111c (FIG. 14C). For the formation of the third layer 113c, a method that can be used for the formation of the first layer 113a can be used.

FIG. 14C schematically illustrates a state where the third layer 113c is formed using a fine metal mask 154c. The fine metal mask 154c is preferably provided to be in contact with the top surface of the insulating layer 170. Accordingly, the fine metal mask 154c is not in contact with any of the first layer 113a, the second layer 113b, and the common layer 114a, so that damage to these layers can be inhibited. In a similar manner, the fine metal mask 154c is not in contact with the conductive layer 123, so that damage to the conductive layer 123 can be inhibited.

The fine metal mask 154c has an opening in a region to be the subpixel 110c. Accordingly, as illustrated in FIG. 14C, the third layer 113c can be selectively formed in a region overlapping with the pixel electrode 111c and the vicinity thereof. In FIG. 14C, an example in which the end portion of the third layer 113c overlap with the adjacent second layer 113b is illustrated. Note that the third layer 113c may be separated from the second layer 113b without overlapping with the second layer 113b. In a similar manner, the end portion of the third layer 113c may overlap with the adjacent first layer 113a or may be separated from each other without overlapping with the first layer 113a. The side surface of the third layer 113c has a tapered shape.

The end portion of the third layer 113c is preferably positioned outward from the end portion of the pixel electrode 111c. Such a structure can increase the aperture ratio of the pixel. Covering the top surface and the side surface of the pixel electrode 111c with the common layer 114a and the third layer 113c inhibits contact between the pixel electrode 111c and the common electrode 115, thereby inhibiting a short circuit in the light-emitting device. Furthermore, the distance between the light-emitting region of the light-emitting device (a region where the third layer 113c and the pixel electrode 111c overlap with each other) and the end portion of the third layer 113c can be increased. Using a region that is away from the end portion of the third layer 113c as the light-emitting region can reduce variation in characteristics of the light-emitting device 130c.

In the case of manufacturing a display apparatus including both the light-emitting device and the light-receiving device as illustrated in FIG. 8A and FIG. 8B, the fourth layer 113d included in the light-receiving device is formed in a manner similar to those for the first layer 113a to the third layer 113c. There is no particular limitation on the formation order of the first layer 113a to the fourth layer 113d. For example, when a layer with high adhesion to the common layer 114a is formed earlier, film separation in the process can be inhibited. For example, in the case where the first layer 113a to the third layer 113c have higher adhesion to the common layer 114a than the fourth layer 113d, the first layer 113a to the third layer 113c are preferably formed earlier.

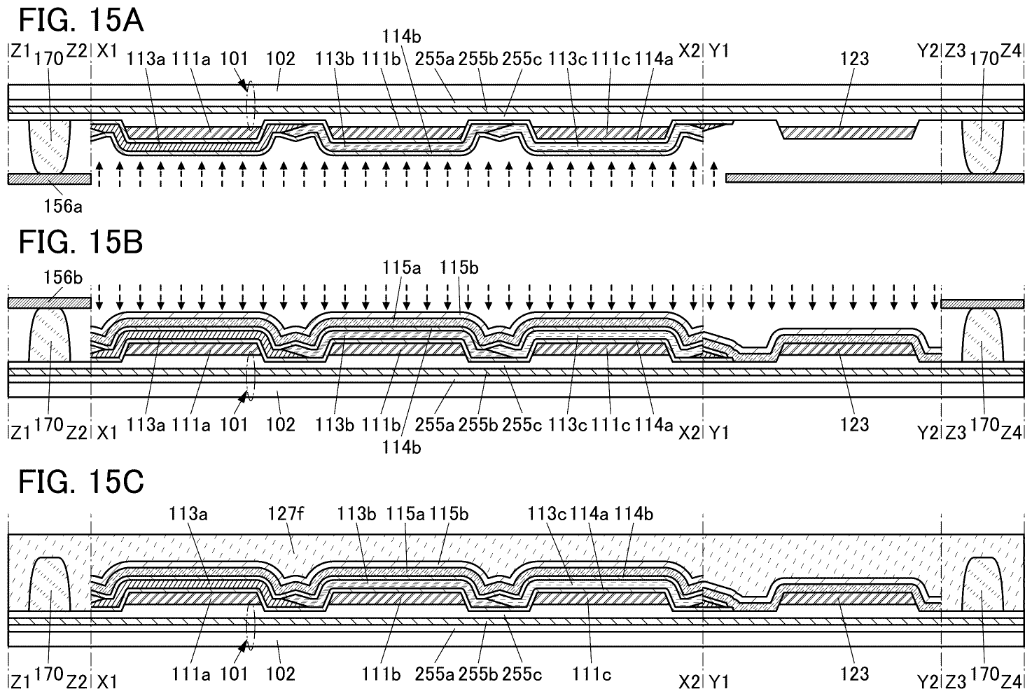

Next, the common layer 114b is formed over the first layer 113a, the second layer 113b, and the third layer 113c (FIG. 15A). The common layer 114b can be formed by a method similar to that for the common layer 114a. FIG. 15A schematically illustrates a state where the common layer 114b is formed using the area mask 156a. In forming the common layer 114b, the area mask 156a may be provided to be in contact with the top surface of the insulating layer 170. Accordingly, the area mask 156a is not in contact with any of the first layer 113a, the second layer 113b, the third layer 113c, and the conductive layer 123, so that damage to these layers can be inhibited.

As illustrated in FIG. 15A, the common layer 114b is not formed over the conductive layer 123. Here, an example in which the same area mask 156a is used for the formation of the common layer 114a and the formation of the common layer 114b is illustrated. Note that in the case where a region where the common layer 114a and the common layer 114b are formed in different regions, different area masks may be used.

Next, the conductive layer 115a and the conductive layer 115b are formed in this order over the common layer 114b and the conductive layer 123 (FIG. 15B). Each of the conductive layer 115a and the conductive layer 115b can be formed by a sputtering method or a vacuum evaporation method, for example. Alternatively, as each of the conductive layer 115a and the conductive layer 115b, a film formed by an evaporation method and a film formed by a sputtering method may be stacked.

After the formation of the conductive layer 115a, the conductive layer 115b is preferably formed successively without exposure to the air. For example, with use of a multi-chamber sputtering apparatus, the conductive layer 115a and the conductive layer 115b are preferably formed in different chambers successively in a vacuum. Accordingly, the conductive layer 115a can be covered with the conductive layer 115b without exposure to the air, whereby the conductive layer 115a can be inhibited from being oxidized even when a material that is easily oxidized is used for the conductive layer 115a.

The conductive layer 115a and the conductive layer 115b are provided in each of the pixel portion 105 and the connection portion 140. The conductive layer 115a and the conductive layer 115b are not necessarily provided over the insulating layer 170. FIG. 15B schematically illustrates a state where the conductive layer 115a and the conductive layer 115b are formed using an area mask 156b. In forming the conductive layer 115a and the conductive layer 115b, the area mask 156b may be provided to be in contact with the top surface of the insulating layer 170. Accordingly, the area mask 156b is in contact with neither the common layer 114b nor the conductive layer 123, so that damage to these layers can be inhibited.

Next, a film 127f to be the layer 127 is formed over the conductive layer 115b (FIG. 15C). The film 127f may also be provided over the insulating layer 170.

The film 127f is preferably formed by a formation method that causes less damage to the first layer 113a, the second layer 113b, the third layer 113c, the common layer 114a, and the common layer 114b.

The film 127f is formed at a temperature lower than the upper temperature limits of the first layer 113a, the second layer 113b, the third layer 113c, the common layer 114a, and the common layer 114b. For example, the film 127f is preferably formed at a substrate temperature higher than or equal to room temperature, higher than or equal to 60° C., higher than or equal to 80° C., higher than or equal to 100° C., or higher than or equal to 120° C. and lower than or equal to 200° C., lower than or equal to 180° C., lower than or equal to 160° C., lower than or equal to 150° C., or lower than or equal to 140° C.

As described above, a material with high heat resistance is used for the light-emitting device of the display apparatus of one embodiment of the present invention. Accordingly, the upper temperature limit of a heat application step in the manufacturing process of the display apparatus can be increased. Therefore, the range of choices of the materials and the formation method of the display apparatus can be widened, thereby improving the manufacturing yield and the reliability. For example, the substrate temperature in forming the film 127f can be higher than or equal to 100° C., higher than or equal to 120° C., or higher than or equal to 140° C.

The film 127f is preferably formed by the aforementioned wet film formation method. For example, the film 127f is preferably formed by spin coating using a photosensitive resin, specifically, a photosensitive resin composite containing an acrylic resin.

Heat treatment (also referred to as prebaking) is preferably performed after the film 127f is formed. The substrate temperature in the heat treatment is lower than the upper temperature limits of the first layer 113a, the second layer 113b, the third layer 113c, the common layer 114a, and the common layer 114b. The substrate temperature in the heat treatment is preferably higher than or equal to 50° C. and lower than or equal to 200° C., further preferably higher than or equal to 60° C. and lower than or equal to 200° C., still further preferably higher than or equal to 70° C. and lower than or equal to 200° C., yet still further preferably higher than or equal to 80° C. and lower than or equal to 200° C., yet still further preferably higher than or equal to 80° C. and lower than or equal to 150° C., yet still further preferably higher than or equal to 80° C. and lower than or equal to 120° C., yet still further preferably higher than or equal to 90° C. and lower than or equal to 120° C. Accordingly, a solvent contained in the film 127f can be removed.

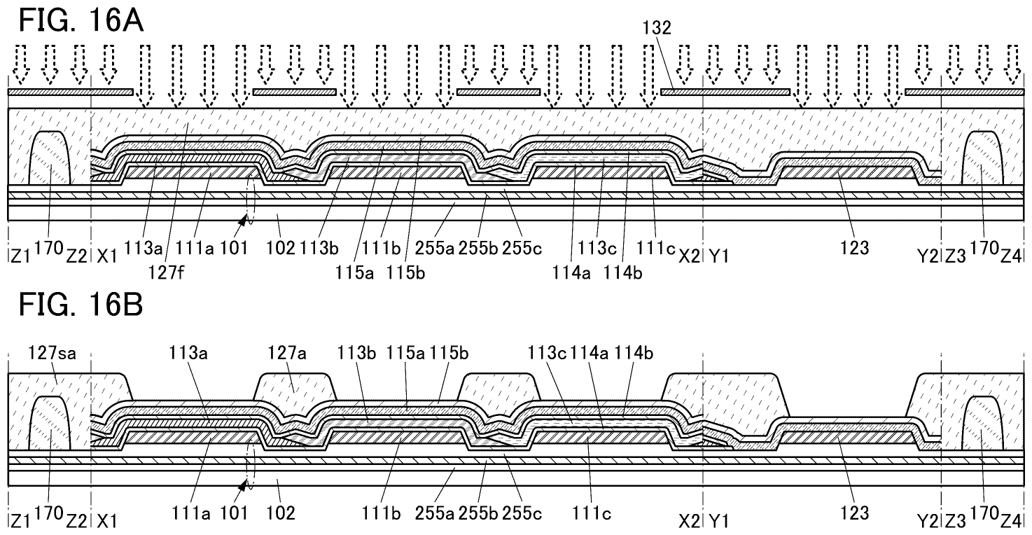

Next, part of the film 127f is exposed to visible light or ultraviolet rays (FIG. 16A). In FIG. 16A, light is indicated by a dashed arrow. In the case where a positive photosensitive resin composite containing an acrylic resin is used for the film 127f, a region where neither the layer 127 nor the layer 127s is formed is exposed to light and a region where either the layer 127 or the layer 127s is formed is shielded from light by a mask 132. The layer 127 is formed in regions sandwiched between two of the pixel electrode 111a, the pixel electrode 111b, and the pixel electrode 111c, and around the conductive layer 123. The layer 127s is formed over and around the insulating layer 170. That is, the film 127f over the pixel electrode 111a, the pixel electrode 111b, the pixel electrode 111c, and the conductive layer 123 is irradiated with visible light or ultraviolet rays.

Note that the width of the layer 127 to be formed later can be controlled by the region exposed to light here. In this embodiment, the layer 127 is processed so as to include a portion overlapping with the top surface of the pixel electrode (see FIG. 2A, FIG. 2B, and FIG. 3A). As illustrated in FIG. 3B, the layer 127 does not necessarily include a portion overlapping with the top surface of the pixel electrode.

Light used for light exposure preferably includes the i-line (wavelength: 365 nm). The light used for light exposure may include at least one of the g-line (wavelength: 436 nm) and the h-line (wavelength: 405 nm).

Although FIG. 16A illustrates an example in which the positive photosensitive resin is used for the film 127f, one embodiment of the present invention is not limited thereto. For example, a structure may be employed in which a negative photosensitive resin is used for the film 127f. In this case, a region where the layer 127 is formed is irradiated with visible light or ultraviolet rays.

Next, development is performed to remove a region of the film 127f exposed to light, so that a layer 127a and a layer 127sa are formed (FIG. 16B). In the case where an acrylic resin is used for the film 127f, an alkaline solution is preferably used as a developer, and for example, an aqueous solution of tetramethyl ammonium hydroxide (TMAH) can be used. There is no particular limitation on the development method, and a dip method, a spin method, a puddle method, a vibration method, or the like can be employed.

Then, a residue (what is called scum) due to the development may be removed. For example, the residue can be removed by ashing using oxygen plasma.

Etching may be performed so that the surface levels of the layer 127a and the layer 127sa are adjusted. The layer 127a and the layer 127sa may be processed by ashing using oxygen plasma, for example. In the case where a non-photosensitive material is used for the film 127f, the surface levels of the layer 127a and the layer 127sa can be adjusted by the ashing, for example.

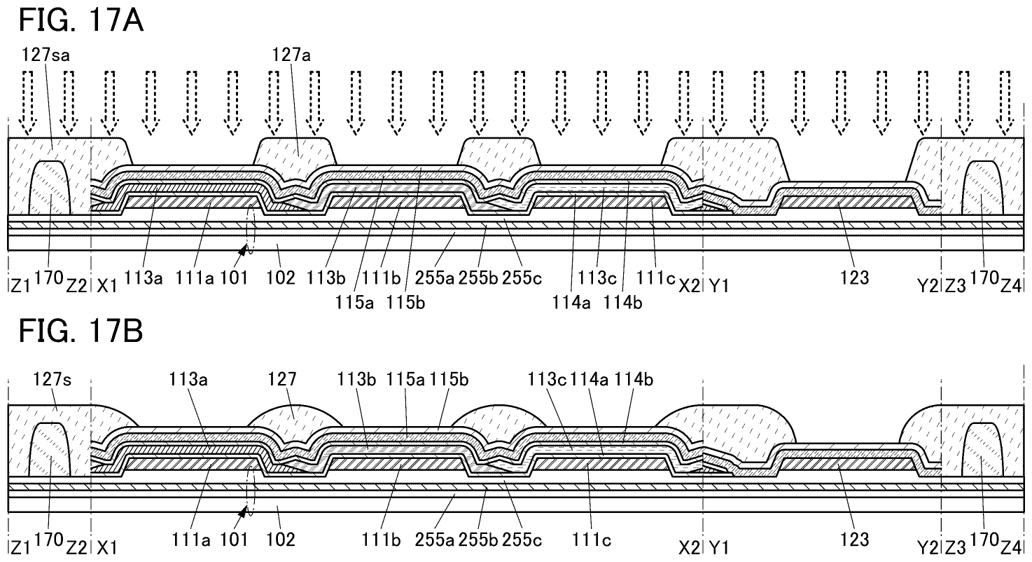

Next, light exposure is preferably performed on the entire substrate so that the layer 127a is irradiated with visible light or ultraviolet rays (FIG. 17A). The layer 127sa may be irradiated with visible light or ultraviolet rays. The energy density for the light exposure is preferably greater than 0 mJ/cm² and less than or equal to 800 mJ/cm², further preferably greater than 0 mJ/cm² and less than or equal to 500 mJ/cm². Performing such light exposure after the development can sometimes increase the degree of transparency of the layer 127a. In addition, it is sometimes possible to lower the substrate temperature required for subsequent heat treatment for changing the shape of the layer 127a into a tapered shape. Note that in the case where a material absorbing visible light is used for the layer 127, the light exposure is not necessarily performed. When the layer 127 absorbs light emitted from the light-emitting device, leakage of light (stray light) to the adjacent light-emitting device can be inhibited.

On the other hand, when light exposure is not performed on the layer 127a, the shape of the layer 127a can be easily changed in a later step in some cases. Thus, in some cases, it is preferable not to perform light exposure on the layer 127a after the development.

For example, in the case where a photocurable resin is used as a material of the layer 127a and the layer 127sa, performing light exposure on the layer 127a and the layer 127sa causes polymerization, so that the layer 127a and the layer 127sa can be cured. Note that instead of performing light exposure on the layer 127a at this stage, later-described post-baking may be performed while the layer 127a remains in a state where its shape is relatively easily changed. Thus, generation of unevenness in the formation surface of the conductive layer 115c can be inhibited and step disconnection of the conductive layer 115c can be inhibited. After the later-described post-baking, light exposure may be performed on the layer 127a (or the layer 127).

After that, heat treatment (also referred to as post-baking) is performed. Performing heat treatment can change the layer 127a into the layer 127 having a tapered side surface as illustrated in FIG. 17B. The heat treatment is performed at a temperature lower than the upper temperature limit of the EL layer. The heat treatment can be performed at a substrate temperature higher than or equal to 50° C. and lower than or equal to 200° C., preferably higher than or equal to 60° C. and lower than or equal to 150° C., further preferably higher than or equal to 70° C. and lower than or equal to 130° C. The heating atmosphere may be an air atmosphere or an inert gas atmosphere. Moreover, the heating atmosphere may be an atmospheric-pressure atmosphere or a reduced-pressure atmosphere. The heat treatment is preferably performed in a reduced-pressure atmosphere, in which case drying at a lower temperature is possible. The heat treatment in this step is preferably performed at a higher substrate temperature than the heat treatment (pre-baking) after the formation of the film 127f. Accordingly, adhesion between the layer 127 and the conductive layer 115b can be improved. Furthermore, corrosion resistance of the layer 127 can be increased.

As described above, a material with high heat resistance is used for the light-emitting device of the display apparatus of one embodiment of the present invention. Therefore, the temperature of the pre-baking and the temperature of the post-baking can each be higher than or equal to 100° C., higher than or equal to 120° C., or higher than or equal to 140° C. Accordingly, adhesion between the layer 127 and the conductive layer 115b can be further improved. Furthermore, corrosion resistance of the layer 127 and the layer 127s can be further increased. In addition, the range of choices for materials that can be used for the layer 127 and the layer 127s can be widened. By adequately removing the solvent and the like included in the layer 127, entry of impurities such as water and oxygen into the EL layer can be inhibited.

As illustrated in FIG. 3A, the side surface of the layer 127 might have a concave shape depending on the materials for the layer 127, and the temperature, time, and atmosphere of the post-baking. For example, the layer 127 is more likely to be changed in shape to have a concave shape as the post-baking is performed at a higher temperature or for a longer time. In addition, as described above, in the case where light exposure is not performed on the layer 127a after the development, the shape of the layer 127 is likely to change at the time of the post-baking in some cases.

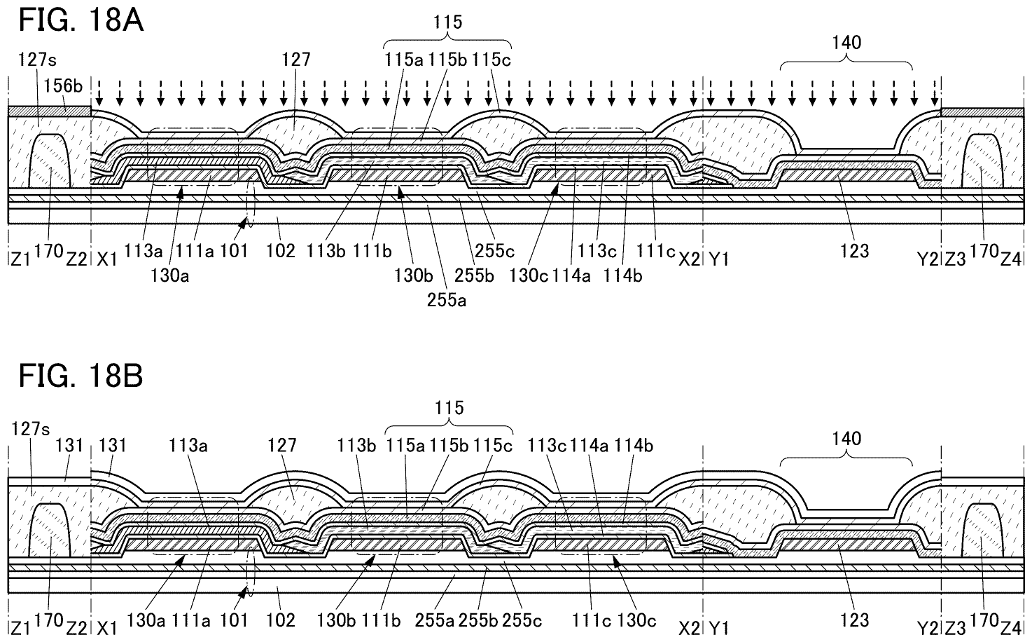

Next, the conductive layer 115c is formed over the layer 127 and the conductive layer 115b (FIG. 18A). The conductive layer 115c can be formed by a sputtering method or a vacuum evaporation method, for example. Alternatively, as the conductive layer 115c, a film formed by an evaporation method and a film formed by a sputtering method may be stacked.

The conductive layer 115c is provided in the pixel portion 105 and the connection portion 140. The conductive layer 115c is not necessarily provided over the layer 127s. FIG. 18A schematically illustrates a state where the conductive layer 115c is formed using the area mask 156b. In forming the conductive layer 115c, the area mask 156b may be provided to be in contact with the top surface of the layer 127s formed over the insulating layer 170. Accordingly, the area mask 156b is in contact with neither the pixel portion 105 nor the connection portion 140, so that damage to these portions can be inhibited.

Next, the protective layer 131 is formed over the conductive layer 115c (FIG. 18B). The protective layer 131 may also be provided over the layer 127s. Furthermore, the substrate 120 is bonded onto the protective layer 131 with the resin layer 122, whereby the display apparatus can be manufactured (FIG. 10A).

Examples of methods for forming the protective layer 131 include a vacuum evaporation method, a sputtering method, a CVD method, and an ALD method.

Note that the insulating layer 170 and the layer 127s may be removed from the display apparatus. For example, regions where the insulating layer 170 and the layer 127s are formed are separated from the pixel portion 105 and the connection portion 140, whereby the regions where the insulating layer 170 and the layer 127s are formed can be removed from the display apparatus. When the regions where the insulating layer 170 and the layer 127s are formed are removed, the display apparatus can be small in size.

As described above, in the method for manufacturing the display apparatus of this embodiment, an insulating layer covering the end portion of the top surface of the pixel electrode 111 is not provided between the pixel electrode 111 and the EL layer. Thus, the distance between adjacent light-emitting devices can be extremely shortened. Accordingly, the display apparatus can have a high resolution or a high definition.

When the layer 127 is provided over the conductive layer 115b to fill a depressed portion generated between adjacent pixel electrodes 111, coverage with the conductive layer 115c can be improved. Consequently, a connection defect due to step disconnection of the common electrode 115 and an increase in electric resistance can be inhibited. When the top surface and the side surface of the pixel electrode 111 are covered with the EL layer, the pixel electrode 111 is not in contact with the common electrode 115, so that a short circuit can be inhibited. Furthermore, the EL layer is covered with the conductive layer 115a and the conductive layer 115b. In the step of forming the layer 127 over the conductive layer 115b, the EL layer is not exposed, so that the EL layer can be inhibited from being damaged. Thus, a display apparatus having high display quality can be provided.

For the formation of the EL layer and the common electrode 115, a mask (e.g., a fine metal mask and an area mask) can be used. In forming the EL layer and the common electrode 115, providing the insulating layer 170 that supports the mask can inhibit these layers from being in contact with the mask and being damaged. The layer 127s may be provided over the insulating layer 170. The stack of the insulating layer 170 and the layer 127s can function as a support layer of the mask in forming the conductive layer 115c.

This embodiment can be combined with the other embodiments as appropriate.

### Embodiment 3

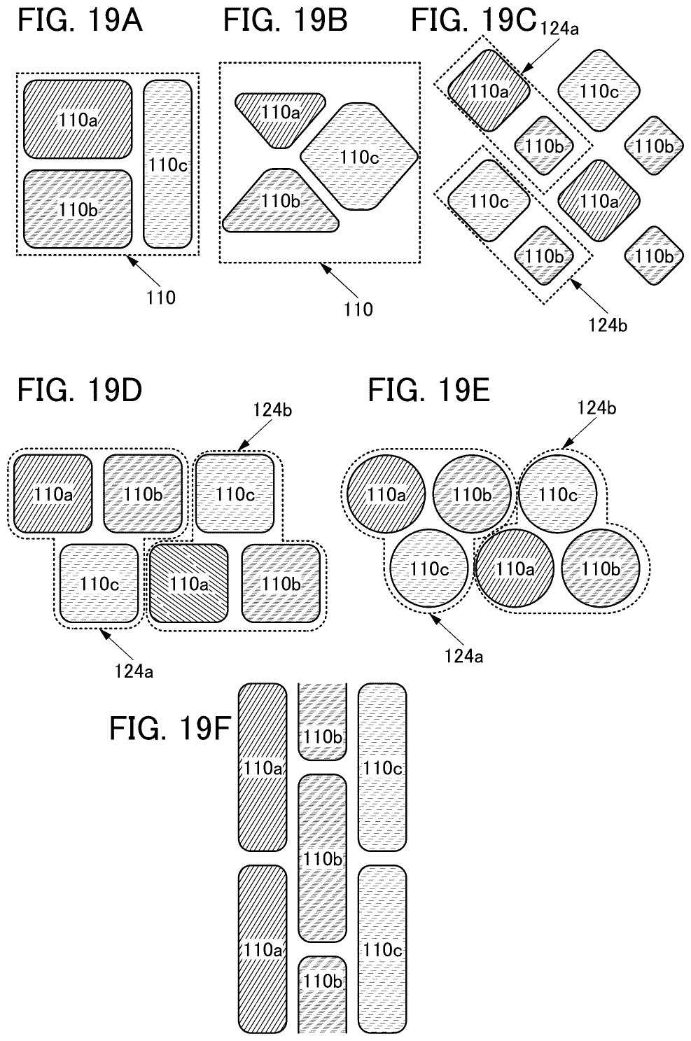

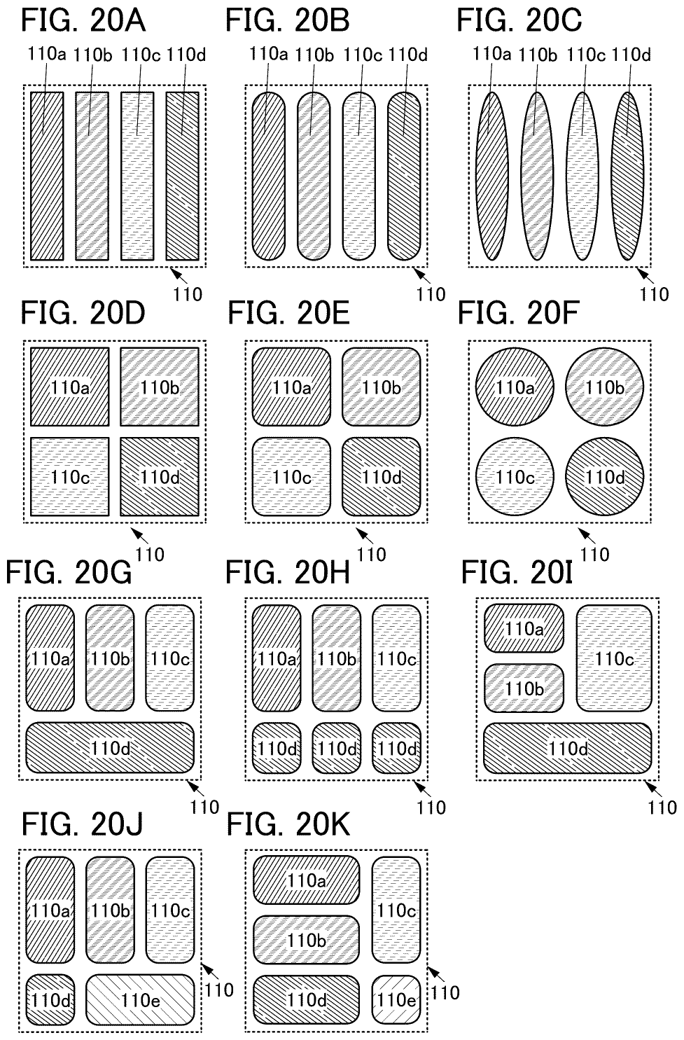

In this embodiment, a display apparatus of one embodiment of the present invention is described with reference to FIG. 19 and FIG. 20.

### [Pixel Layout]

Pixel layouts different from that in FIG. 1A will be mainly described in this embodiment. There is no particular limitation on the arrangement of subpixels, and any of a variety of methods can be employed. Examples of the arrangement of subpixels include stripe arrangement, S-stripe arrangement, matrix arrangement, delta arrangement, Bayer arrangement, and PenTile arrangement.

The top surface shape of the subpixel illustrated in a diagram in this embodiment corresponds to the top surface shape of a light-emitting region (or a light-receiving region).

Examples of a top surface shape of the subpixel include polygons such as a triangle, a tetragon (including a rectangle, a rhombus, and a square), and a pentagon; polygons with rounded corners; an ellipse; and a circle.

The range of the circuit layout for forming the subpixels is not limited to the range of the subpixels illustrated in a diagram and may be placed outside the range of the subpixels.

The pixel 110 illustrated in FIG. 19A employs S-stripe arrangement. The pixel 110 illustrated in FIG. 19A is composed of three subpixels: the subpixel 110a, the subpixel 110b, and the subpixel 110c.

The pixel 110 illustrated in FIG. 19B includes the subpixel 110a whose top surface has a rough trapezoidal shape with rounded corners, the subpixel 110b whose top surface has a rough triangle shape with rounded corners, and the subpixel 110c whose top surface has a rough tetragonal or rough hexagonal shape with rounded corners. The subpixel 110b has a larger light-emitting area than the subpixel 110a. In this manner, the shapes and sizes of the subpixels can be determined independently. For example, the size of a subpixel including a light-emitting device with higher reliability can be smaller.

Pixels 124a and 124b illustrated in FIG. 19C employ PenTile arrangement. FIG. 19C illustrates an example in which the pixels 124a including the subpixel 110a and the subpixel 110b and the pixels 124b including the subpixel 110b and the subpixel 110c are alternately arranged.

The pixels 124a and 124b illustrated in FIG. 19D and FIG. 19E employ delta arrangement. The pixel 124a includes two subpixels (the subpixels 110a and 110b) in the upper row (first row) and one subpixel (the subpixel 110c) in the lower row (second row). The pixel 124b includes one subpixel (the subpixel 110c) in the upper row (first row) and two subpixels (the subpixels 110a and 110b) in the lower row (second row).

FIG. 19D illustrates an example in which the top surface of each subpixel has a rough tetragonal shape with rounded corners, and FIG. 19E illustrates an example in which the top surface of each subpixel has a circular shape.

FIG. 19F illustrates an example in which subpixels of different colors are arranged in a zigzag manner. Specifically, the positions of the top sides of two subpixels arranged in the row direction (e.g., the subpixel 110a and the subpixel 110b or the subpixel 110b and the subpixel 110c) are not aligned in a top view.

For example, in each pixel illustrated in FIG. 19A to FIG. 19F, it is preferable that the subpixel 110a be a subpixel R emitting red light, that the subpixel 110b be a subpixel G emitting green light, and that the subpixel 110c be a subpixel B emitting blue light. Note that the structure of the subpixels is not limited to this, and the colors and arrangement order of the subpixels can be determined as appropriate. For example, the subpixel 110b may be the subpixel R emitting red light and the subpixel 110a may be the subpixel G emitting green light.

In a photolithography method, as a pattern to be processed becomes finer, the influence of light diffraction becomes more difficult to ignore; therefore, the fidelity in transferring a photomask pattern by light exposure is degraded, and it becomes difficult to process a resist mask into a desired shape. Thus, a pattern with rounded corners is likely to be formed even with a rectangular photomask pattern. Consequently, the top surface of a subpixel has a polygonal shape with rounded corners, an elliptical shape, a circular shape, or the like, in some cases.

Furthermore, in the method for manufacturing the display apparatus of one embodiment of the present invention, the EL layer is processed into an island shape using a resist mask. A resist film formed over the EL layer needs to be cured at a temperature lower than the upper temperature limit of the EL layer. Therefore, the resist film is insufficiently cured in some cases depending on the upper temperature limit of the material of the EL layer and the curing temperature of the resist material. An insufficiently cured resist film may have a shape different from a desired shape after being processed. As a result, the top surface of the EL layer may have a polygonal shape with rounded corners, an elliptical shape, a circular shape, or the like. For example, when a resist mask whose top surface has a square shape is intended to be formed, a resist mask whose top surface has a circular shape may be formed, and the top surface of the EL layer may have a circular shape.

Note that to obtain a desired top surface shape of the EL layer, a technique of correcting a mask pattern in advance so that a transferred pattern agrees with a design pattern (OPC (Optical Proximity Correction) technique) may be used. Specifically, with the OPC technique, a pattern for correction is added to a corner portion or the like of a figure on a mask pattern.

As illustrated in FIG. 20A to FIG. 20I, the pixel can include four types of subpixels.

The pixels 110 illustrated in FIG. 20A to FIG. 20C employ stripe arrangement.

FIG. 20A illustrates an example in which each subpixel has a rectangular top surface shape, FIG. 20B illustrates an example in which each subpixel has a top surface shape formed by combining two half circles and a rectangle, and FIG. 20C illustrates an example in which each subpixel has an elliptical top surface shape.

The pixels 110 illustrated in FIG. 20D to FIG. 20F employ matrix arrangement.

FIG. 20D illustrates an example in which each subpixel has a square top surface shape, FIG. 20E illustrates an example in which each subpixel has a rough square top surface shape with rounded corners, and FIG. 20F illustrates an example in which each subpixel has a circular top surface shape.

FIG. 20G and FIG. 20H each illustrate an example in which one pixel 110 is composed of two rows and three columns.

The pixel 110 illustrated in FIG. 20G includes three subpixels (the subpixels 110a, 110b, and 110c) in the upper row (first row) and one subpixel (the subpixel 110d) in the lower row (second row). In other words, the pixel 110 includes the subpixel 110a in the left column (first column), the subpixel 110b in the center column (second column), the subpixel 110c in the right column (third column), and the subpixel 110d across these three columns.

The pixel 110 illustrated in FIG. 20H includes three subpixels (the subpixels 110a, 110b, and 110c) in the upper row (first row) and three subpixels 110d in the lower row (second row). In other words, the pixel 110 includes the subpixel 110a and the subpixel 110d in the left column (first column), the subpixel 110b and the subpixel 110d in the center column (second column), and the subpixel 110c and the subpixel 110d in the right column (third column). Matching the positions of the subpixels in the upper row and the lower row as illustrated in FIG. 20H enables efficient removal of dust and the like that would be produced in the manufacturing process. Thus, a display apparatus with high display quality can be provided.

FIG. 20I illustrates an example in which one pixel 110 is composed of three rows and two columns.

The pixel 110 illustrated in FIG. 20I includes the subpixel 110a in the upper row (first row), the subpixel 110b in the center row (second row), the subpixel 110c across the first and second rows, and one subpixel (the subpixel 110d) in the lower row (third row). In other words, the pixel 110 includes the subpixels 110a and 110b in the left column (first column), the subpixel 110c in the right column (second column), and the subpixel 110d across these two columns.

The pixels 110 illustrated in FIG. 20A to FIG. 20I are each composed of four subpixels: the subpixels 110a, 110b, 110c, and 110d.

The subpixels 110a, 110b, 110c, and 110d can be configured to include light-emitting devices whose emission colors are different. The subpixels 110a, 110b, 110c, and 110d are subpixels of four colors of R, G, B, and white (W), subpixels of four colors of R, G, B, and Y, or subpixels of R, G, B, and infrared light (IR), for example.

In the pixels 110 illustrated in FIG. 20A to FIG. 20I, it is preferable that the subpixel 110a be the subpixel R emitting red light, that the subpixel 110b be the subpixel G emitting green light, that the subpixel 110c be the subpixel B emitting blue light, and that the subpixel 110d be any of a subpixel W emitting white light, a subpixel Y emitting yellow light, and a subpixel IR emitting near-infrared light, for example. In the case of such a structure, stripe arrangement is employed as the layout of R, G, and B in the pixels 110 illustrated in FIG. 20G and FIG. 20H, leading to higher display quality. In addition, what is called S-stripe arrangement is employed as the layout of R, G, and B in the pixel 110 illustrated in FIG. 20I, leading to higher display quality.

The pixel 110 may include a subpixel including a light-receiving device.

In the pixels 110 illustrated in FIG. 20A to FIG. 20I, any one of the subpixel 110a to the subpixel 110d may be a subpixel including a light-receiving device.

In the pixels 110 illustrated in FIG. 20A to FIG. 20I, for example, it is preferable that the subpixel 110a be the subpixel R emitting red light, that the subpixel 110b be the subpixel G emitting green light, that the subpixel 110c be the subpixel B emitting blue light, and that the subpixel 110d be a subpixel S including a light-receiving device. In the case of such a structure, stripe arrangement is employed as the layout of R, G, and B in the pixels 110 illustrated in FIG. 20G and FIG. 20H, leading to higher display quality. In addition, what is called S-stripe arrangement is employed as the layout of R, G, and B in the pixel 110 illustrated in FIG. 20I, leading to higher display quality.

There is no particular limitation on the wavelength of light detected by the subpixel S including a light-receiving device. The subpixel S can have a structure in which one or both of visible light and infrared light are detected.

As illustrated in FIG. 20J and FIG. 20K, the pixel can include five types of subpixels.

FIG. 20J illustrates an example in which one pixel 110 is composed of two rows and three columns.

The pixel 110 illustrated in FIG. 20J includes three subpixels (the subpixels 110a, 110b, and 110c) in the upper row (first row) and two subpixels (the subpixel 110d and a subpixel 110e) in the lower row (second row). In other words, the pixel 110 includes the subpixels 110a and 110d in the left column (first column), the subpixel 110b in the center column (second column), the subpixel 110c in the right column (third column), and the subpixel 110e across the second and third columns.

FIG. 20K illustrates an example in which one pixel 110 is composed of three rows and two columns.

The pixel 110 illustrated in FIG. 20K includes the subpixel 110a in the upper row (first row), the subpixel 110b in the center row (second row), the subpixel 110c across the first and second rows, and two subpixels (the subpixels 110d and 110e) in the lower row (third row). In other words, the pixel 110 includes the subpixels 110a, 110b, and 110d in the left column (first column), and the subpixels 110c and 110e in the right column (second column).

In the pixels 110 illustrated in FIG. 20J and FIG. 20K, for example, it is preferable that the subpixel 110a be the subpixel R emitting red light, that the subpixel 110b be the subpixel G emitting green light, and that the subpixel 110c be the subpixel B emitting blue light. In the case of such a structure, stripe arrangement is employed as the layout of R, G, and B in the pixel 110 illustrated in FIG. 20J, leading to higher display quality. In addition, what is called S-stripe arrangement is employed as the layout of R, G, and B in the pixel 110 illustrated in FIG. 20K, leading to higher display quality.

In the pixels 110 illustrated in FIG. 20J and FIG. 20K, for example, it is preferable to use the subpixel S including a light-receiving device as at least one of the subpixel 110d and the subpixel 110e. In the case where light-receiving devices are used in both the subpixel 110d and the subpixel 110e, the light-receiving devices may have different structures. For example, the wavelength ranges of detected light may be different at least partly. Specifically, one of the subpixel 110d and the subpixel 110e may include a light-receiving device mainly detecting visible light and the other may include a light-receiving device mainly detecting infrared light.

In the pixels 110 illustrated in FIG. 20J and FIG. 20K, for example, the subpixel S including a light-receiving device is used as one of the subpixel 110d and the subpixel 110e and a subpixel including a light-emitting device that can be used as a light source is used as the other. For example, it is preferable that one of the subpixel 110d and the subpixel 110e be the subpixel IR emitting infrared light and that the other be the subpixel S including a light-receiving device detecting infrared light.

In a pixel including the subpixels R, G, B, IR, and S, while an image is displayed using the subpixels R, G, and B, reflected light of infrared light emitted by the subpixel IR that is used as a light source can be detected by the subpixel S.

As described above, the pixel composed of the subpixels each including the light-emitting device can employ any of a variety of layouts in the display apparatus of one embodiment of the present invention. The display apparatus of one embodiment of the present invention can have a structure in which the pixel includes both a light-emitting device and a light-receiving device. Also in this case, any of a variety of layouts can be employed.

This embodiment can be combined with the other embodiments as appropriate.

### Embodiment 4

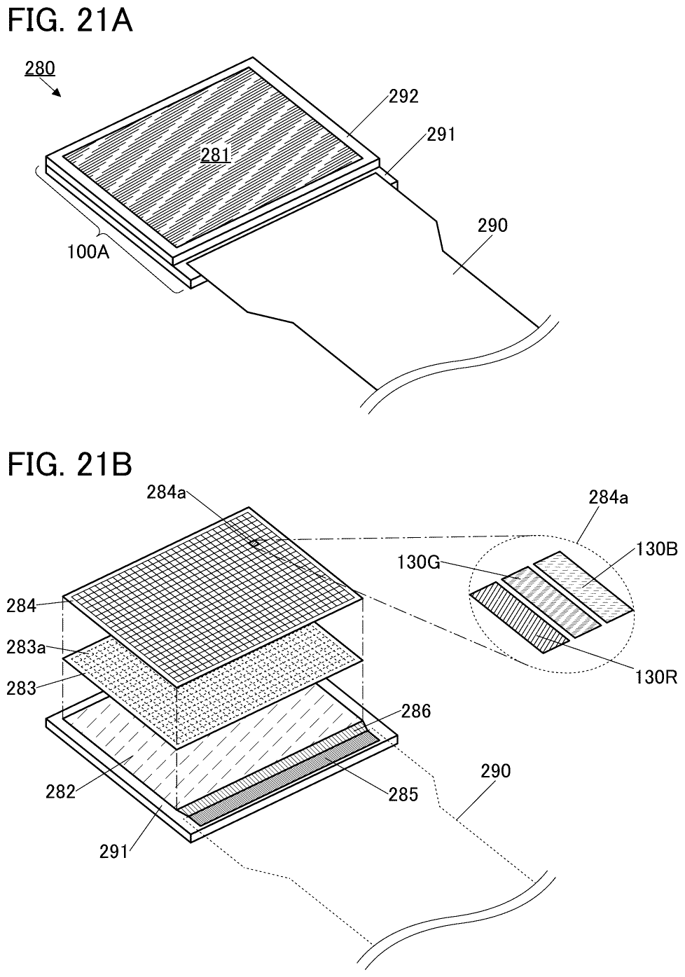

In this embodiment, display apparatuses of embodiments of the present invention will be described with reference to FIG. 21 to FIG. 27.

The display apparatus of this embodiment can be a high-resolution display apparatus. Accordingly, the display apparatus of this embodiment can be used for display portions of information terminals (wearable devices) such as watch-type and bracelet-type information terminals and display portions of wearable devices capable of being worn on the head, such as a VR device like a head-mounted display (HMD) and a glasses-type AR device.

The display apparatus of this embodiment can be a high-definition display apparatus or a large-sized display apparatus. Accordingly, the display apparatus of this embodiment can be used for display portions of electronic devices such as a digital camera, a digital video camera, a digital photo frame, a mobile phone, a portable game console, a portable information terminal, and an audio reproducing device, in addition to display portions of electronic devices with a relatively large screen, such as a television device, a desktop or notebook personal computer, a monitor of a computer or the like, digital signage, and a large game machine such as a pachinko machine.

### [Display Module]

FIG. 21A illustrates a perspective view of a display module 280. The display module 280 includes a display apparatus 100A and an FPC 290. Note that the display apparatus included in the display module 280 is not limited to the display apparatus 100A and may be any of a display apparatus 100B to a display apparatus 100F described later.

The display module 280 includes a substrate 291 and a substrate 292. The display module 280 includes a display portion 281. The display portion 281 is a region of the display module 280 where an image is displayed, and is a region where light emitted from pixels provided in a pixel portion 284 described later can be seen.

FIG. 21B illustrates a perspective view schematically illustrating a structure on the substrate 291 side. Over the substrate 291, a circuit portion 282, a pixel circuit portion 283 over the circuit portion 282, and the pixel portion 284 over the pixel circuit portion 283 are stacked. A terminal portion 285 to be connected to the FPC 290 is provided in a portion over the substrate 291 that does not overlap with the pixel portion 284. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is illustrated on the right side of FIG. 21B. The pixel 284a can employ any of the structures described in the above embodiments. FIG. 21B illustrates an example in which a structure similar to that of the pixel 110 illustrated in FIG. 1A is employed.

The pixel circuit portion 283 includes a plurality of pixel circuits 283a arranged periodically.

One pixel circuit 283a is a circuit that controls driving of a plurality of elements included in one pixel 284a. One pixel circuit 283a can be provided with three circuits each controlling light emission of one light-emitting device. For example, the pixel circuit 283a can include at least one selection transistor, one current control transistor (driving transistor), and a capacitor for one light-emitting device. In this case, a gate signal is input to a gate of the selection transistor, and a source signal is input to a source of the selection transistor. Thus, an active-matrix display apparatus is achieved.

The circuit portion 282 includes a circuit for driving the pixel circuits 283a in the pixel circuit portion 283. For example, the circuit portion 282 preferably includes one or both of a gate line driver circuit and a source line driver circuit. The circuit portion 282 may also include at least one of an arithmetic circuit, a memory circuit, a power supply circuit, and the like.

The FPC 290 functions as a wiring for supplying a video signal, a power supply potential, or the like to the circuit portion 282 from the outside. An IC may be mounted on the FPC 290.

The display module 280 can have a structure in which one or both of the pixel circuit portion 283 and the circuit portion 282 are stacked below the pixel portion 284; hence, the aperture ratio (the effective display area ratio) of the display portion 281 can be significantly high. For example, the aperture ratio of the display portion 281 can be greater than or equal to 40% and less than 100%, preferably greater than or equal to 50% and less than or equal to 95%, further preferably greater than or equal to 60% and less than or equal to 95%. Furthermore, the pixels 284a can be arranged extremely densely and thus the display portion 281 can have extremely high resolution. For example, the pixels 284a are preferably arranged in the display portion 281 with a resolution higher than or equal to 2000 ppi, preferably higher than or equal to 3000 ppi, further preferably higher than or equal to 5000 ppi, still further preferably higher than or equal to 6000 ppi, and lower than or equal to 20000 ppi or lower than or equal to 30000 ppi.

Such a display module 280 has extremely high resolution, and thus can be suitably used for a VR device such as an HMD or a glasses-type AR device. For example, even with a structure in which the display portion of the display module 280 is seen through a lens, pixels of the extremely-high-resolution display portion 281 included in the display module 280 are prevented from being perceived when the display portion is enlarged by the lens, so that display providing a high sense of immersion can be performed. Without being limited thereto, the display module 280 can be suitably used for electronic devices including a relatively small display portion. For example, the display module 280 can be suitably used for a display portion of a wearable electronic device, such as a wrist watch.

### [Display Apparatus 100A]

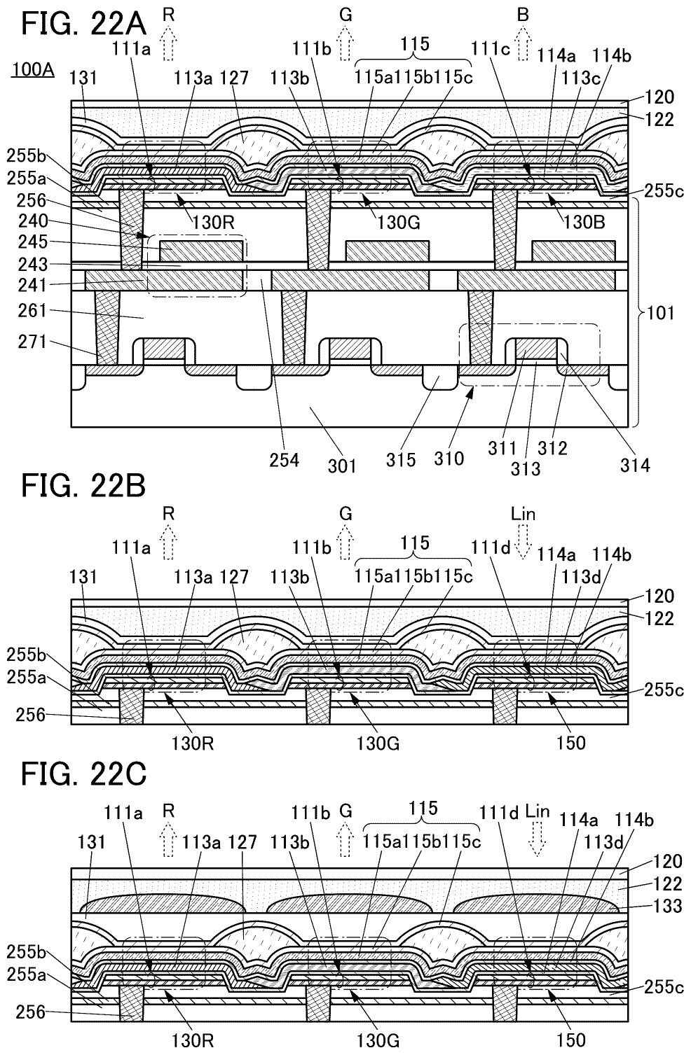

The display apparatus 100A illustrated in FIG. 22A includes a substrate 301, a light-emitting device 130R, a light-emitting device 130G, a light-emitting device 130B, a capacitor 240, and a transistor 310.

The substrate 301 corresponds to the substrate 291 in FIG. 21A and FIG. 21B. A stacked-layer structure from the substrate 301 to the insulating layer 255c corresponds to the layer 101 in Embodiment 1.

The transistor 310 is a transistor including a channel formation region in the substrate 301. As the substrate 301, a semiconductor substrate such as a single crystal silicon substrate can be used, for example. The transistor 310 includes part of the substrate 301, a conductive layer 311, low-resistance regions 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance region 312 is a region where the substrate 301 is doped with an impurity, and functions as one of a source and a drain. The insulating layer 314 is provided to cover the side surface of the conductive layer 311.

An element isolation layer 315 is provided between two adjacent transistors 310 to be embedded in the substrate 301.

An insulating layer 261 is provided to cover the transistor 310, and the capacitor 240 is provided over the insulating layer 261.

The capacitor 240 includes a conductive layer 241, a conductive layer 245, and an insulating layer 243 positioned between these conductive layers. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of the source and the drain of the transistor 310 through a plug 271 embedded in the insulating layer 261. The insulating layer 243 is provided to cover the conductive layer 241. The conductive layer 245 is provided in a region overlapping with the conductive layer 241 with the insulating layer 243 therebetween.

Note that a conductive layer surrounding the outer surface of the display portion 281 (or the pixel portion 284) is preferably provided in at least one layer of the conductive layers included in the layer 101. The conductive layer can be referred to as a guard ring. By providing the conductive layer, elements such as a transistor and a light-emitting device can be inhibited from being broken by high voltage application due to electrostatic discharge (ESD) or charging caused by a step using plasma.

The insulating layer 255a is provided to cover the capacitor 240, the insulating layer 255b is provided over the insulating layer 255a, and the insulating layer 255c is provided over the insulating layer 255b. The light-emitting device 130R, the light-emitting device 130G, and the light-emitting device 130B are provided over the insulating layer 255c. FIG. 22A illustrates an example in which the light-emitting device 130R, the light-emitting device 130G, and the light-emitting device 130B each have a structure similar to the stacked-layer structure illustrated in FIG. 1B. An insulator is provided in a region between adjacent light-emitting devices. In FIG. 22A and the like, the upper layer 127 is provided in the region.

“a” is positioned over the first layer 113a included in the light-emitting device 130R, “b” is positioned over the second layer 113b included in the light-emitting device 130G, and “c” is positioned over the third layer 113c included in the light-emitting device 130B.

The pixel electrode 111a, the pixel electrode 111b, and the pixel electrode 111c are each electrically connected to one of the source and the drain of the transistor 310 through a plug 256 embedded in the insulating layer 243, the insulating layer 255a, the insulating layer 255b, and the insulating layer 255c, the conductive layer 241 embedded in the insulating layer 254, and the plug 271 embedded in the insulating layer 261. The top surface of the insulating layer 255c and the top surface of the plug 256 are level or substantially level with each other. A variety of conductive materials can be used for the plugs. FIG. 22A and the like illustrate an example in which the pixel electrode has a two-layer structure of a reflective electrode and a transparent electrode over the reflective electrode.

The substrate 120 is bonded onto the light-emitting device 130R, the light-emitting device 130G, and the light-emitting device 130B with the resin layer 122. The protective layer 131 is provided to cover the light-emitting device 130R, the light-emitting device 130G, and the light-emitting device 130B, and the substrate 120 may be bonded onto the protective layer 131 with the resin layer 122. Embodiment 1 can be referred to for the details of the light-emitting devices and the components thereover up to the substrate 120. The substrate 120 corresponds to the substrate 292 in FIG. 21A.

The display apparatuses illustrated in FIG. 22B and FIG. 22C are each an example in which the light-emitting devices 130R and 130G and the light-receiving device 150 are included. Although not illustrated, the display apparatus also includes the light-emitting device 130B. In FIG. 22B and FIG. 22C, the layers below the insulating layer 255a are omitted. The display apparatuses illustrated in FIG. 22B and FIG. 22C can each employ any of the structures of the layer 101, which are illustrated in FIG. 22A and FIG. 23 to FIG. 27, for example.

The light-receiving device 150 includes the pixel electrode 111d, the fourth layer 113d, the common layer 114b, and the common electrode 115 which are stacked. Embodiment 1 and Embodiment 6 can be referred to for the details of the display apparatus including the light-receiving device.

As illustrated in FIG. 22C, a lens array 133 may be provided in the display apparatus. The lens array 133 can be provided to overlap with one or both of a light-emitting device and a light-receiving device.

FIG. 22C illustrates an example in which the lens array 133 is provided over the light-emitting devices 130R and 130G and the light-receiving device 150 with the protective layer 131 therebetween. The lens array 133 is directly formed over the substrate provided with the light-emitting device (and the light-receiving device), whereby the accuracy of positional alignment of the light-emitting device or the light-receiving device and the lens array can be enhanced.

In FIG. 22C, light emitted by the light-emitting device passes through the lens array 133, resulting in being extracted to the outside of the display apparatus.

Alternatively, the lens array 133 may be provided for the substrate 120 and may be bonded onto the protective layer 131 with the resin layer 122. By providing the lens array 133 for the substrate 120, the heat treatment temperature in the formation step of the lens array 133 can be increased.

The lens array 133 may include a convex surface facing the substrate 120 side or a convex surface facing the light-emitting device side.

The lens array 133 can be formed using at least one of an inorganic material and an organic material. For example, a material containing a resin can be used for the lens. Moreover, a material containing at least one of an oxide and a sulfide can be used for the lens. As the lens array 133, a microlens array can be used, for example. The lens array 133 may be directly formed over the substrate or the light-emitting device. Alternatively, a lens array separately formed may be bonded thereto.

### [Display Apparatus 100B]

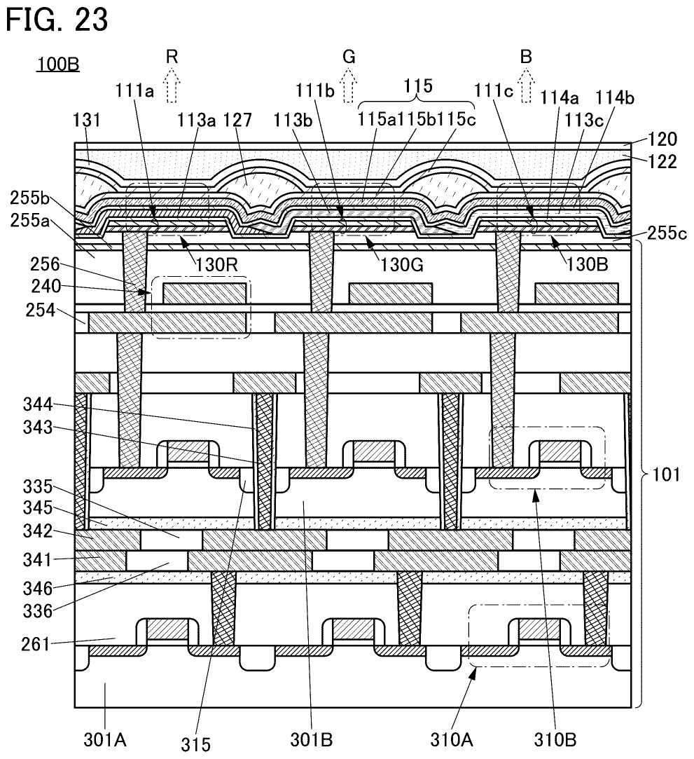

The display apparatus 100B illustrated in FIG. 23 has a structure in which a transistor 310A and a transistor 310B whose channels are formed in a semiconductor substrate are stacked. Note that in the description of the display apparatus below, portions similar to those of the above-described display apparatus are not described in some cases.

In the display apparatus 100B, a substrate 301B provided with the transistor 310B, the capacitor 240, and the light-emitting devices is bonded to a substrate 301A provided with the transistor 310A.

Here, an insulating layer 345 is preferably provided on the bottom surface of the substrate 301B. An insulating layer 346 is preferably provided over the insulating layer 261 provided over the substrate 301A. The insulating layers 345 and 346 are insulating layers functioning as protective layers and can inhibit diffusion of impurities into the substrate 301B and the substrate 301A. For each of the insulating layer 345 and the insulating layer 346, an inorganic insulating film that can be used as the protective layer 131 or an insulating layer 332 can be used.

The substrate 301B is provided with a plug 343 that penetrates the substrate 301B and the insulating layer 345. An insulating layer 344 is preferably provided to cover the side surface of the plug 343. The insulating layer 344 is an insulating layer functioning as a protective layer and can inhibit diffusion of impurities into the substrate 301B. As the insulating layer 344, an inorganic insulating film that can be used as the protective layer 131 can be used.

A conductive layer 342 is provided under the insulating layer 345 on the rear surface of the substrate 301B (the surface opposite to the substrate 120). The conductive layer 342 is preferably provided to be embedded in an insulating layer 335. The bottom surfaces of the conductive layer 342 and the insulating layer 335 are preferably planarized. Here, the conductive layer 342 is electrically connected to the plug 343.

Meanwhile, a conductive layer 341 is provided over the insulating layer 346 over the substrate 301A. The conductive layer 341 is preferably provided to be embedded in the insulating layer 336. The top surfaces of the conductive layer 341 and the insulating layer 336 are preferably planarized.

The conductive layer 341 and the conductive layer 342 are bonded to each other, whereby the substrate 301A and the substrate 301B are electrically connected to each other. Here, improving the flatness of a plane formed by the conductive layer 342 and the insulating layer 335 and a plane formed by the conductive layer 341 and the insulating layer 336 allows the conductive layer 341 and the conductive layer 342 to be bonded to each other favorably.

The conductive layer 341 and the conductive layer 342 are preferably formed using the same conductive material. For example, it is possible to use a metal film containing an element selected from Al, Cr, Cu, Ta, Ti, Mo, and W, or a metal nitride film containing any of the above elements as a component (a titanium nitride film, a molybdenum nitride film, or a tungsten nitride film). Copper is particularly preferably used for the conductive layer 341 and the conductive layer 342. In that case, it is possible to employ Cu—Cu (copper-to-copper) direct bonding (a technique for achieving electrical continuity by connecting Cu (copper) pads).

### [Display Apparatus 100C]

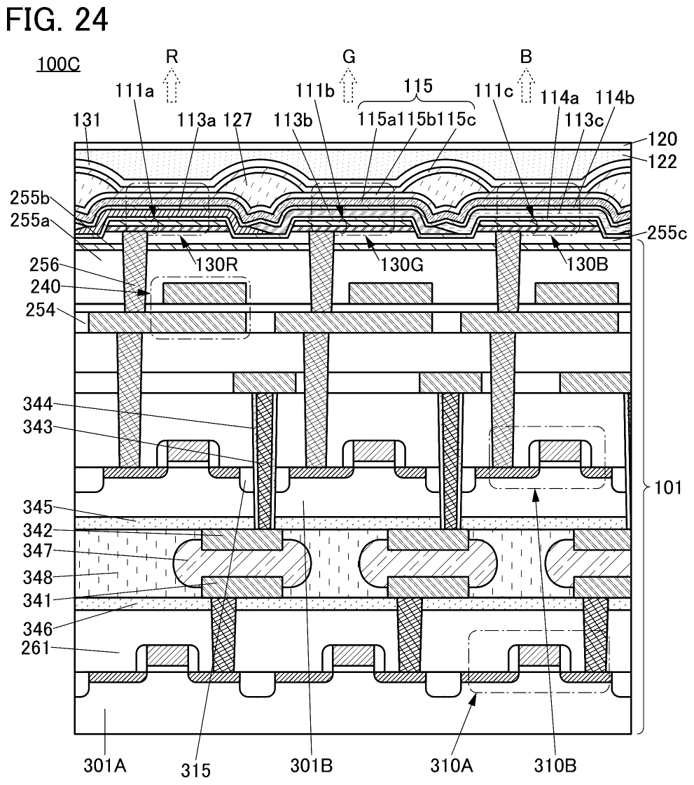

The display apparatus 100C illustrated in FIG. 24 has a structure in which the conductive layer 341 and the conductive layer 342 are bonded to each other through a bump 347.

As illustrated in FIG. 24, providing the bump 347 between the conductive layer 341 and the conductive layer 342 enables the conductive layer 341 and the conductive layer 342 to be electrically connected to each other. The bump 347 can be formed using a conductive material containing gold (Au), nickel (Ni), indium (In), tin (Sn), or the like, for example. For another example, solder may be used for the bump 347. An adhesive layer 348 may be provided between the insulating layer 345 and the insulating layer 346. In the case where the bump 347 is provided, the insulating layer 335 and the insulating layer 336 may be omitted.

### [Display Apparatus 100D]

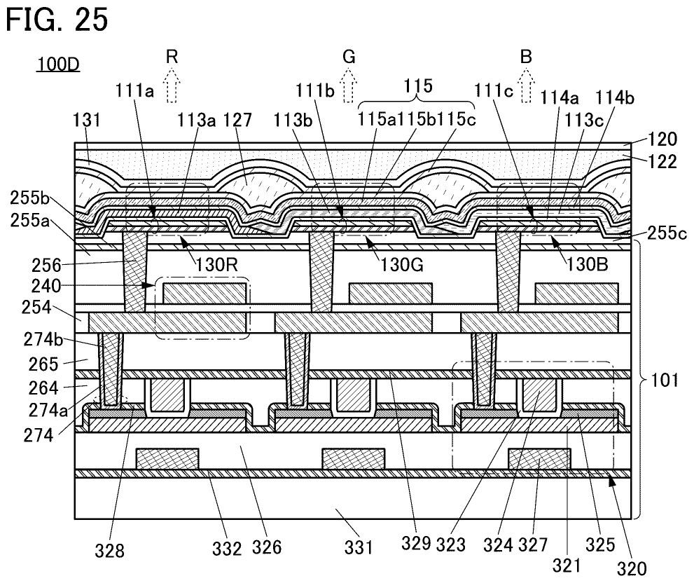

The display apparatus 100D illustrated in FIG. 25 differs from the display apparatus 100A mainly in a structure of a transistor.

A transistor 320 is a transistor (OS transistor) that includes a metal oxide exhibiting semiconductor characteristics (also referred to as an oxide semiconductor) in its semiconductor layer where a channel is formed.

The transistor 320 includes a semiconductor layer 321, an insulating layer 323, a conductive layer 324, a pair of conductive layers 325, an insulating layer 326, and a conductive layer 327.

A substrate 331 corresponds to the substrate 291 in FIG. 21A and FIG. 21B. A stacked-layer structure from the substrate 331 to the insulating layer 255c corresponds to the layer 101 in Embodiment 1. As the substrate 331, an insulating substrate or a semiconductor substrate can be used.

The insulating layer 332 is provided over the substrate 331. The insulating layer 332 functions as a barrier layer that prevents diffusion of impurities such as water and hydrogen from the substrate 331 into the transistor 320 and release of oxygen from the semiconductor layer 321 to the insulating layer 332 side. As the insulating layer 332, for example, a film in which hydrogen or oxygen is less likely to diffuse than in a silicon oxide film, such as an aluminum oxide film, a hafnium oxide film, or a silicon nitride film, can be used.

Note that in this specification and the like, a barrier layer refers to a layer having a barrier property. A barrier property in this specification and the like refers to a function of inhibiting diffusion of a particular substance (also referred to as having low permeability). Alternatively, a barrier property refers to a function of capturing or fixing (also referred to as gettering) a particular substance.

The conductive layer 327 is provided over the insulating layer 332, and the insulating layer 326 is provided to cover the conductive layer 327. The conductive layer 327 functions as a first gate electrode of the transistor 320, and part of the insulating layer 326 functions as a first gate insulating layer. An oxide insulating film such as a silicon oxide film is preferably used as at least part of the insulating layer 326 that is in contact with the semiconductor layer 321. The top surface of the insulating layer 326 is preferably planarized.

The semiconductor layer 321 is provided over the insulating layer 326. The semiconductor layer 321 preferably includes a metal oxide film having semiconductor characteristics (an oxide semiconductor). The pair of conductive layers 325 is provided over and in contact with the semiconductor layer 321 and functions as a source electrode and a drain electrode.

An insulating layer 328 is provided to cover the top surfaces and the side surfaces of the pair of conductive layers 325, the side surface of the semiconductor layer 321, and the like, and an insulating layer 264 is provided over the insulating layer 328. The insulating layer 328 functions as a barrier layer that prevents diffusion of impurities such as water and hydrogen from the insulating layer 264 and the like into the semiconductor layer 321 and release of oxygen from the semiconductor layer 321. As the insulating layer 328, an insulating film similar to the insulating layer 332 can be used.

An opening reaching the semiconductor layer 321 is provided in the insulating layer 328 and the insulating layer 264. The insulating layer 323 that is in contact with the side surfaces of the insulating layer 264, the insulating layer 328, and the conductive layer 325 and the top surface of the semiconductor layer 321, and the conductive layer 324 are embedded in the opening. The conductive layer 324 functions as a second gate electrode, and the insulating layer 323 functions as a second gate insulating layer.

The top surface of the conductive layer 324, the top surface of the insulating layer 323, and the top surface of the insulating layer 264 are planarized so as to be level or substantially level with each other, and an insulating layer 329 and an insulating layer 265 are provided to cover these layers.

The insulating layer 264 and the insulating layer 265 function as interlayer insulating layers. The insulating layer 329 functions as a barrier layer that prevents diffusion of impurities such as water and hydrogen from the insulating layer 265 or the like into the transistor 320. For the insulating layer 329, an insulating film similar to the insulating layer 328 and the insulating layer 332 can be used.

A plug 274 electrically connected to one of the pair of conductive layers 325 is provided to be embedded in the insulating layer 265, the insulating layer 329, and the insulating layer 264. Here, the plug 274 preferably includes a conductive layer 274a covering the side surface of an opening formed in the insulating layer 265, the insulating layer 329, the insulating layer 264, and the insulating layer 328 and part of the top surface of the conductive layer 325, and a conductive layer 274b in contact with the top surface of the conductive layer 274a. For the conductive layer 274a, a conductive material that does not easily allow diffusion of hydrogen and oxygen is preferably used.

### [Display Apparatus 100E]

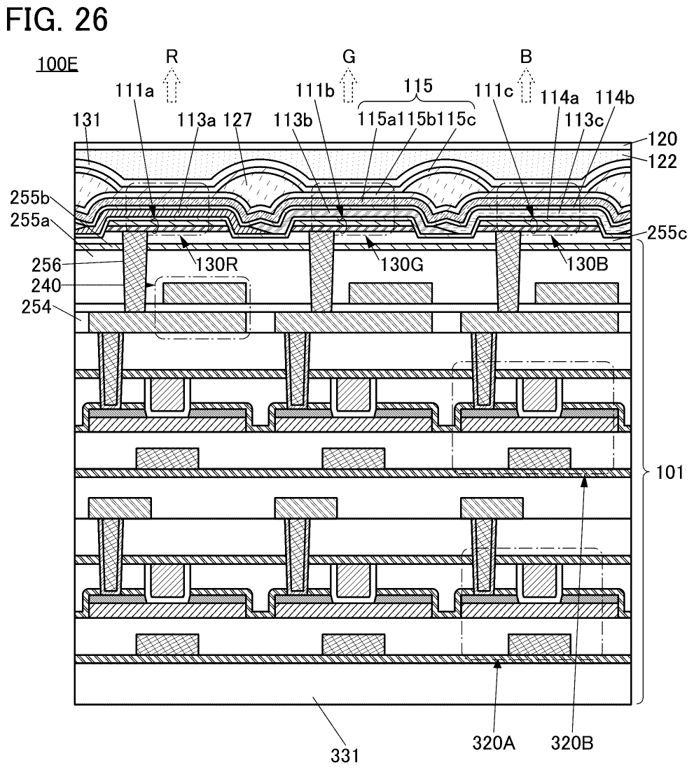

The display apparatus 100E illustrated in FIG. 26 has a structure in which a transistor 320A and a transistor 320B each including an oxide semiconductor in a semiconductor where a channel is formed are stacked.

The display apparatus 100D can be referred to for the transistor 320A, the transistor 320B, and the components around them.

Although the structure in which two transistors including an oxide semiconductor are stacked is described, the present invention is not limited thereto. For example, three or more transistors may be stacked.

### [Display Apparatus 100F]

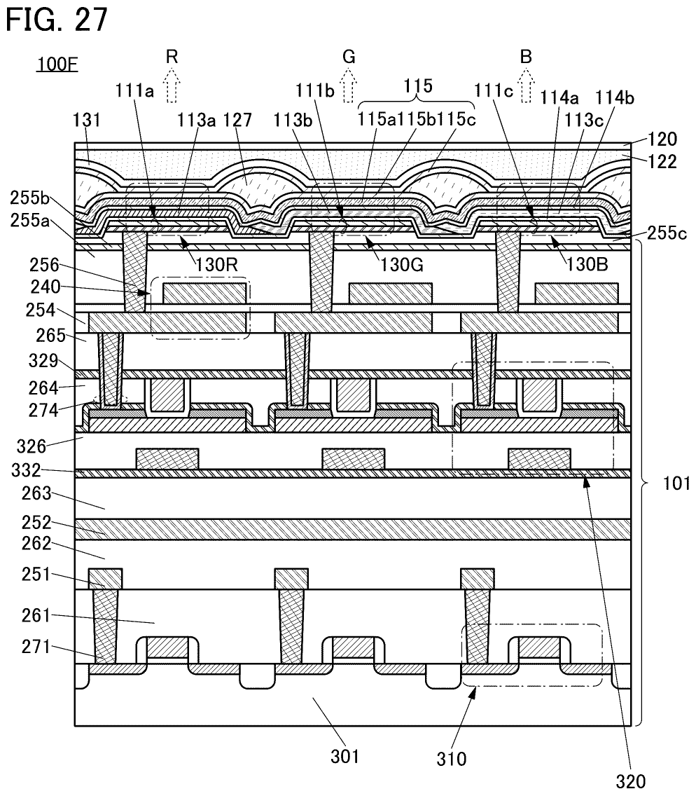

The display apparatus 100F illustrated in FIG. 27 has a structure in which the transistor 310 having a channel formed in the substrate 301 and the transistor 320 including a metal oxide in a semiconductor layer where a channel is formed are stacked.

The insulating layer 261 is provided to cover the transistor 310, and a conductive layer 251 is provided over the insulating layer 261. An insulating layer 262 is provided to cover the conductive layer 251, and a conductive layer 252 is provided over the insulating layer 262. The conductive layer 251 and the conductive layer 252 each function as a wiring. An insulating layer 263 and the insulating layer 332 are provided to cover the conductive layer 252, and the transistor 320 is provided over the insulating layer 332. The insulating layer 265 is provided to cover the transistor 320, and the capacitor 240 is provided over the insulating layer 265. The capacitor 240 and the transistor 320 are electrically connected to each other through the plug 274.

The transistor 320 can be used as a transistor included in the pixel circuit. The transistor 310 can be used as a transistor included in the pixel circuit or a transistor included in a driver circuit for driving the pixel circuit (a gate line driver circuit or a source line driver circuit). The transistor 310 and the transistor 320 can also be used as transistors included in a variety of circuits such as an arithmetic circuit and a memory circuit.

With such a structure, not only the pixel circuit but also the driver circuit or the like can be formed directly under the light-emitting device; thus, the display apparatus can be downsized as compared to the case where the driver circuit is provided around a display region.

There is no particular limitation on the crystallinity of a semiconductor material used for the transistors, and any of an amorphous semiconductor, a single crystalline semiconductor, and a semiconductor having crystallinity other than single crystal (a microcrystalline semiconductor, a polycrystalline semiconductor, or a semiconductor partly including crystal regions) may be used. A single crystal semiconductor or a semiconductor having crystallinity is preferably used, in which case degradation of the transistor characteristics can be inhibited.

The semiconductor layer of the transistor preferably includes a metal oxide exhibiting semiconductor characteristics (an oxide semiconductor). That is, a transistor including a metal oxide in its channel formation region (hereinafter also referred to as an OS transistor) is preferably used for the display apparatus of this embodiment.

Examples of the metal oxide that can be used for the semiconductor layer include indium oxide, gallium oxide, and zinc oxide. The metal oxide preferably contains two or three selected from indium, an element M, and zinc. The element M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, cobalt, and magnesium. Specifically, the element M is preferably one or more kinds selected from aluminum, gallium, yttrium, and tin.

It is particularly preferable that an oxide containing indium (In), gallium (Ga), and zinc (Zn) (also referred to as IGZO) be used as the metal oxide used for the semiconductor layer. Alternatively, it is preferable to use an oxide containing indium, tin, and zinc (also referred to as ITZO (registered trademark)). Further alternatively, it is preferable to use an oxide containing indium, gallium, tin, and zinc. Alternatively, it is preferable to use an oxide containing indium (In), aluminum (Al), and zinc (Zn) (also referred to as IAZO). Further alternatively, it is preferable to use an oxide containing indium (In), aluminum (Al), gallium (Ga), and zinc (Zn) (also referred to as IAGZO).

When the metal oxide used for the semiconductor layer is an In-M-Zn oxide, the atomic ratio of In is preferably higher than or equal to the atomic ratio of M in the In-M-Zn oxide. Examples of the atomic ratio of the metal elements in such an In-M-Zn oxide include In:M:Zn=1:1:1 or a composition in the neighborhood thereof, In:M:Zn=1:1:1.2 or a composition in the neighborhood thereof, In:M:Zn=1:3:2 or a composition in the neighborhood thereof, In:M:Zn=1:3:4 or a composition in the neighborhood thereof, In:M:Zn=2:1:3 or a composition in the neighborhood thereof, In:M:Zn=3:1:2 or a composition in the neighborhood thereof, In:M:Zn=4:2:3 or a composition in the neighborhood thereof, In:M:Zn=4:2:4.1 or a composition in the neighborhood thereof, In:M:Zn=5:1:3 or a composition in the neighborhood thereof, In:M:Zn=5:1:6 or a composition in the neighborhood thereof, In:M:Zn=5:1:7 or a composition in the neighborhood thereof, In:M:Zn=5:1:8 or a composition in the neighborhood thereof, In:M:Zn=6:1:6 or a composition in the neighborhood thereof, and In:M:Zn=5:2:5 or a composition in the neighborhood thereof. Note that a composition in the neighborhood includes the range of +30% of an intended atomic ratio.

For example, in the case where the atomic ratio is described as In:Ga:Zn=4:2:3 or a composition in the neighborhood thereof, the case is included where Ga is greater than or equal to 1 and less than or equal to 3 and Zn is greater than or equal to 2 and less than or equal to 4 with In being 4. In addition, in the case where the atomic ratio is described as In:Ga:Zn=5:1:6 or a composition in the neighborhood thereof, the case is included where Ga is greater than 0.1 and less than or equal to 2 and Zn is greater than or equal to 5 and less than or equal to 7 with In being 5. Furthermore, in the case where the atomic ratio is described as In:Ga:Zn=1:1:1 or a composition in the neighborhood thereof, the case is included where Ga is greater than 0.1 and less than or equal to 2 and Zn is greater than 0.1 and less than or equal to 2 with In being 1.

The semiconductor layer may include two or more metal oxide layers with different compositions. For example, a stacked-layer structure of a first metal oxide layer having In:M:Zn=1:3:4 [atomic ratio] or a composition in the neighborhood thereof and a second metal oxide layer having In:M:Zn=1:1:1 [atomic ratio] or a composition in the neighborhood thereof and being formed over the first metal oxide layer can be suitably employed. Gallium or aluminum is particularly preferably used as the element M.

For example, a stacked structure or the like of one selected from indium oxide, indium gallium oxide, and IGZO, and one selected from IAZO, IAGZO, and ITZO (registered trademark) may be used.

As the oxide semiconductor having crystallinity, a CAAC (c-axis aligned crystalline)-OS, an nc (nanocrystalline)-OS, and the like are given.

Alternatively, a transistor using silicon in a channel formation region (a Si transistor) may be used. Examples of silicon include single crystal silicon, polycrystalline silicon, and amorphous silicon. In particular, a transistor containing low-temperature polysilicon (LTPS) in its semiconductor layer (hereinafter also referred to as an LTPS transistor) can be used. The LTPS transistor has high field-effect mobility and favorable frequency characteristics.

With the use of a Si transistor such as an LTPS transistor, a circuit required to be driven at a high frequency (e.g., a source driver circuit) can be formed on the same substrate as the display portion. This allows simplification of an external circuit mounted on the display apparatus and a reduction in component cost and mounting cost.

An OS transistor has much higher field-effect mobility than a transistor using amorphous silicon. In addition, an OS transistor has an extremely low leakage current between a source and a drain in an off state (hereinafter also referred to as off-state current), and charge accumulated in a capacitor that is connected in series to the transistor can be retained for a long period. Furthermore, the power consumption of the display apparatus can be reduced with the OS transistor.

To increase the emission luminance of the light-emitting device included in a pixel circuit, it is necessary to increase the amount of current flowing through the light-emitting device. For that purpose, the source-drain voltage of the driving transistor included in the pixel circuit needs to be increased. Since an OS transistor has a higher withstand voltage between the source and the drain than a Si transistor, a high voltage can be applied between the source and the drain of the OS transistor. Thus, with use of an OS transistor as a driving transistor included in the pixel circuit, the amount of current flowing through the light-emitting device can be increased, resulting in an increase in emission luminance of the light-emitting device.

When a transistor operates in a saturation region, a change in source-drain current relative to a change in gate-source voltage can be smaller in an OS transistor than in a Si transistor. Accordingly, when an OS transistor is used as the driving transistor included in the pixel circuit, current flowing between the source and the drain can be set minutely by a change in gate-source voltage; hence, the amount of current flowing through the light-emitting device can be controlled. Accordingly, the number of gray levels in the pixel circuit can be increased.

Regarding saturation characteristics of current flowing when a transistor operates in a saturation region, even in the case where the source-drain voltage of an OS transistor increases gradually, more stable current (saturation current) can be made flow through an OS transistor than through a Si transistor. Thus, with use of an OS transistor as a driving transistor, current can be made flow stably through the light-emitting device, for example, even when a variation in current-voltage characteristics of the EL device occurs. In other words, when the OS transistor operates in the saturation region, the source-drain current hardly changes with an increase in the source-drain voltage; hence, the emission luminance of the light-emitting device can be stable.

As described above, with use of an OS transistor as the driving transistor included in the pixel circuit, it is possible to achieve “inhibition of black floating”, “increase in emission luminance”, “increase in the number of gray levels”, “inhibition of variation in light-emitting devices”, and the like.

### Embodiment 5

In this embodiment, a light-emitting device that can be used for a display apparatus of one embodiment of the present invention will be described.

In this specification and the like, a structure in which light-emitting devices of different emission colors (e.g., blue (B), green (G), and red (R)) are separately formed is referred to as an SBS (Side By Side) structure in some cases.

The emission color of the light-emitting device can be red, green, blue, cyan, magenta, yellow, or white, for example. When the light-emitting device has a microcavity structure, the color purity can be increased.

### [Light-Emitting Device]

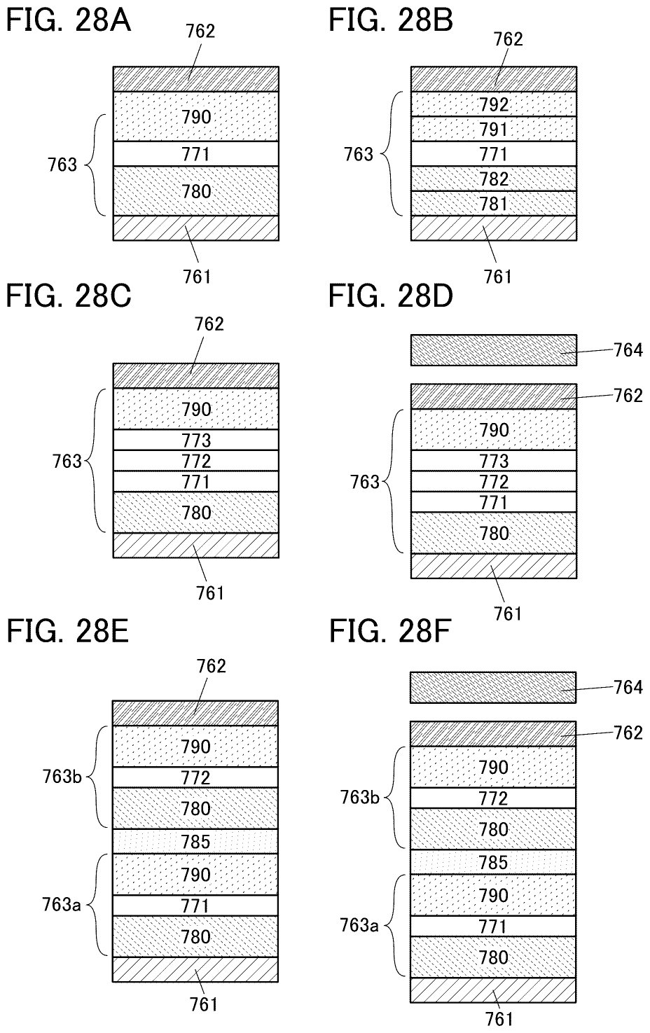

As illustrated in FIG. 28A, the light-emitting device includes an EL layer 763 between a pair of electrodes (a lower electrode 761 and an upper electrode 762). The EL layer 763 can be formed of a plurality of layers such as a layer 780, a light-emitting layer 771, and a layer 790.

The light-emitting layer 771 contains at least a light-emitting substance (also referred to as a light-emitting material).

In the case where the lower electrode 761 is an anode and the upper electrode 762 is a cathode, the layer 780 includes one or more of a layer containing a substance having a high hole-injection property (a hole-injection layer), a layer containing a substance having a high hole-transport property (a hole-transport layer), and a layer containing a substance having a high electron-blocking property (an electron-blocking layer). Furthermore, the layer 790 includes one or more of a layer containing a substance having a high electron-injection property (an electron-injection layer), a layer containing a substance having a high electron-transport property (an electron-transport layer), and a layer containing a substance having a high hole-blocking property (a hole-blocking layer). In the case where the lower electrode 761 is a cathode and the upper electrode 762 is an anode, the structures of the layer 780 and the layer 790 are replaced with each other.

The structure including the layer 780, the light-emitting layer 771, and the layer 790, which is provided between the pair of electrodes, can function as a single light-emitting unit, and the structure in FIG. 28A is referred to as a single structure in this specification.

FIG. 28B is a variation example of the EL layer 763 included in the light-emitting device illustrated in FIG. 28A. Specifically, the light-emitting device illustrated in FIG. 28B includes a layer 781 over the lower electrode 761, a layer 782 over the layer 781, the light-emitting layer 771 over the layer 782, a layer 791 over the light-emitting layer 771, a layer 792 over the layer 791, and the upper electrode 762 over the layer 792.

In the case where the lower electrode 761 is an anode and the upper electrode 762 is a cathode, the layer 781 can be a hole-injection layer, the layer 782 can be a hole-transport layer, the layer 791 can be an electron-transport layer, and the layer 792 can be an electron-injection layer, for example. In the case where the lower electrode 761 is a cathode and the upper electrode 762 is an anode, the layer 781 can be an electron-injection layer, the layer 782 can be an electron-transport layer, the layer 791 can be a hole-transport layer, and the layer 792 can be a hole-injection layer. With such a layer structure, carriers can be efficiently injected into the light-emitting layer 771, and the efficiency of the recombination of carriers in the light-emitting layer 771 can be increased.

Note that structures in which a plurality of light-emitting layers (the light-emitting layer 771, a light-emitting layer 772, and a light-emitting layer 773) are provided between the layer 780 and the layer 790 as illustrated in FIG. 28C and FIG. 28D are other variations of the single structure.

Structures in which a plurality of light-emitting units (an EL layer 763a and an EL layer 763b) are connected in series with a charge-generation layer 785 therebetween as illustrated in FIG. 28E and FIG. 28F are referred to as a tandem structure in this specification. Note that the tandem structure may be referred to as a stack structure. The tandem structure enables a light-emitting device capable of high-luminance light emission.

In FIG. 28C and FIG. 28D, light-emitting substances that emit light of the same color, or moreover, the same light-emitting substance may be used for the light-emitting layer 771, the light-emitting layer 772, and the light-emitting layer 773. For example, a light-emitting substance that emits blue light may be used for the light-emitting layer 771, the light-emitting layer 772, and the light-emitting layer 773. A color conversion layer may be provided as a layer 764 illustrated in FIG. 28D.

Light-emitting substances emitting light of different colors may be used for the light-emitting layer 771, the light-emitting layer 772, and the light-emitting layer 773. White light emission can be obtained by mixing light emitted from the light-emitting layer 771, the light-emitting layer 772, and the light-emitting layer 773. A color filter (also referred to as a coloring layer) may be provided as the layer 764 illustrated in FIG. 28D. When white light passes through the color filter, light of a desired color can be obtained.

The light-emitting device emitting white light preferably contains two or more kinds of light-emitting substances. To obtain white light emission, two kinds of light-emitting substances are selected such that they emit light of complementary colors. For example, when an emission color of the first light-emitting layer and an emission color of the second light-emitting layer are complementary colors, the light-emitting device can be configured to emit white light as a whole. In the case of a light-emitting device including three or more light-emitting layers, white light emission can be obtained by mixing light emitted from the light-emitting layers.

In FIG. 28E and FIG. 28F, light-emitting substances that emit light of the same color, or moreover, the same light-emitting substance may be used for the light-emitting layer 771 and the light-emitting layer 772. Alternatively, light-emitting substances emitting light of different colors may be used for the light-emitting layer 771 and the light-emitting layer 772. White light emission can be obtained when the emission color of the light-emitting layer 771 and the emission color of the light-emitting layer 772 are complementary colors. FIG. 28F illustrates an example in which the layer 764 is further provided. One or both of a color conversion layer and a color filter (a coloring layer) can be used as the layer 764.

Also in FIG. 28C, FIG. 28D, FIG. 28E, and FIG. 28F, the layer 780 and the layer 790 may each independently have a stacked-layer structure of two or more layers as illustrated in FIG. 28B.

Note that in FIG. 28D and FIG. 28F, a conductive film transmitting visible light is used for the upper electrode 762 to extract light from the upper electrode 762 side.

Next, materials that can be used for the light-emitting device will be described.

Either a low molecular compound or a high molecular compound can be used for the light-emitting device, and an inorganic compound may also be included. Each layer included in the light-emitting device can be formed by a method such as an evaporation method (including a vacuum evaporation method), a transfer method, a printing method, an inkjet method, or a coating method.

The light-emitting layer can contain one or more kinds of light-emitting substances. As the light-emitting substance, a substance whose emission color is blue, violet, bluish violet, green, yellowish green, yellow, orange, red, or the like is appropriately used. Alternatively, as the light-emitting substance, a substance that emits near-infrared light can be used.

Examples of the light-emitting substance include a fluorescent material, a phosphorescent material, a TADF material, and a quantum dot material.

Examples of a fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of a phosphorescent material include an organometallic complex (particularly an iridium complex) having a 4H-triazole skeleton, a 1H-triazole skeleton, an imidazole skeleton, a pyrimidine skeleton, a pyrazine skeleton, or a pyridine skeleton; an organometallic complex (particularly an iridium complex) having a phenylpyridine derivative including an electron-withdrawing group as a ligand; a platinum complex; and a rare earth metal complex.

The light-emitting layer may contain one or more kinds of organic compounds (e.g., a host material or an assist material) in addition to the light-emitting substance (a guest material). As one or more kinds of organic compounds, one or both of a substance having a high hole-transport property (a hole-transport material) and a substance having a high electron-transport property (an electron-transport material) can be used. Alternatively, as one or more kinds of organic compounds, a bipolar material or a TADF material may be used.

The light-emitting layer preferably includes a phosphorescent material and a combination of a hole-transport material and an electron-transport material that easily forms an exciplex, for example. With such a structure, light emission can be efficiently obtained by ExTET (Exciplex-Triplet Energy Transfer), which is energy transfer from the exciplex to the light-emitting substance (a phosphorescent material). When a combination of materials is selected so as to form an exciplex that emits light whose wavelength overlaps with the wavelength of a lowest-energy-side absorption band of the light-emitting substance, energy can be transferred smoothly and light emission can be obtained efficiently. With the above structure, high efficiency, low-voltage driving, and a long lifetime of a light-emitting device can be achieved at the same time.

In addition to the light-emitting layer, the EL layer 763 may further include a layer containing any of a substance having a high hole-injection property, a substance having a high hole-transport property, a hole-blocking material, a substance having a high electron-transport property, a substance having a high electron-injection property, an electron-blocking material, a substance having a bipolar property (a substance having a high electron-transport property and a high hole-transport property), and the like.

The hole-injection layer is a layer that injects holes from the anode to the hole-transport layer, and is a layer that contains a substance having a high hole-injection property. Examples of a substance having a high hole-injection property include an aromatic amine compound and a composite material containing a hole-transport material and an acceptor material (an electron-accepting material).

As the hole-transport material, it is possible to use a substance having a high hole-transport property which can be used for the hole-transport layer and will be described later.

As the acceptor material, an oxide of a metal belonging to any of Group 4 to Group 8 of the periodic table can be used, for example. Specifically, molybdenum oxide, vanadium oxide, niobium oxide, tantalum oxide, chromium oxide, tungsten oxide, manganese oxide, and rhenium oxide are given. Among these, molybdenum oxide is particularly preferable since it is stable in the air, has a low hygroscopic property, and is easy to handle. Alternatively, an organic acceptor material containing fluorine can be used. Alternatively, organic acceptor materials such as a quinodimethane derivative, a chloranil derivative, and a hexaazatriphenylene derivative can be used.

As the substance with a high hole-injection property, a material that contains a hole-transport material and the above-described oxide of a metal belonging to Group 4 to Group 8 of the periodic table (typically, molybdenum oxide) may be used, for example.

The hole-transport layer is a layer that transports holes injected from the anode by the hole-injection layer, into the light-emitting layer. The hole-transport layer is a layer that contains a hole-transport material. As the hole-transport material, a substance having a hole mobility of 1×10⁻⁶ cm²/Vs or higher is preferable. Note that other substances can also be used as long as the substances have a hole-transport property higher than an electron-transport property. As the hole-transport material, substances with a high hole-transport property, such as a π-electron rich heteroaromatic compound (e.g., a carbazole derivative, a thiophene derivative, and a furan derivative) and an aromatic amine (a compound having an aromatic amine skeleton), are preferred.

The electron-blocking layer is provided in contact with the light-emitting layer. The electron-blocking layer is a layer that has a hole-transport property and contains a material capable of blocking electrons. Any of the materials having an electron-blocking property among the above hole-transport materials can be used for the electron-blocking layer.

The electron-blocking layer has a hole-transport property, and thus can also be referred to as a hole-transport layer. A layer having an electron-blocking property among the hole-transport layers can also be referred to as an electron-blocking layer.

The electron-transport layer is a layer that transports electrons injected from the cathode by the electron-injection layer, into the light-emitting layer. The electron-transport layer is a layer that contains an electron-transport material. As the electron-transport material, a substance having an electron mobility of 1×10⁻⁶ cm²/Vs or higher is preferable. Note that other substances can also be used as long as the substances have an electron-transport property higher than a hole-transport property. As the electron-transport material, any of the following substances with a high electron-transport property can be used, for example: a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, and a π-electron deficient heteroaromatic compound such as a nitrogen-containing heteroaromatic compound.

The hole-blocking layer is provided in contact with the light-emitting layer. The hole-blocking layer is a layer that has an electron-transport property and contains a material capable of blocking holes. Any of the materials having a hole-blocking property among the above electron-transport materials can be used for the hole-blocking layer.

The hole-blocking layer has an electron-transport property, and thus can also be referred to as an electron-transport layer. A layer having a hole-blocking property among the electron-transport layers can also be referred to as a hole-blocking layer.

The electron-injection layer is a layer that injects electrons from the cathode to the electron-transport layer, and is a layer that contains a substance having a high electron-injection property. As the substance having a high electron-injection property, an alkali metal, an alkaline earth metal, or a compound thereof can be used. As the substance having a high electron-injection property, a composite material containing an electron-transport material and a donor material (electron-donating material) can also be used.

The difference between the LUMO level of the substance having a high electron-injection property and the work function value of the material used for the cathode is preferably small (specifically, smaller than or equal to 0.5 eV).

For the electron-injection layer, it is possible to use an alkali metal, an alkaline earth metal, or a compound thereof, such as lithium, cesium, ytterbium, lithium fluoride (LiF), cesium fluoride (CsF), calcium fluoride (CaFx, where X is a given number), 8-(quinolinolato) lithium (abbreviation: Liq), 2-(2-pyridyl) phenolatolithium (abbreviation: LiPP), 2-(2-pyridyl)-3-pyridinolato lithium (abbreviation: LiPPy), 4-phenyl-2-(2-pyridyl) phenolatolithium (abbreviation: LiPPP), lithium oxide (LiOₓ), or cesium carbonate, for example. The electron-injection layer may have a stacked-layer structure of two or more layers. As the stacked-layer structure, for example, a structure in which lithium fluoride is used for the first layer and ytterbium is provided for the second layer is given.

The electron-injection layer may contain an electron-transport material. For example, a compound having an unshared electron pair and an electron deficient heteroaromatic ring can be used as the electron-transport material. Specifically, it is possible to use a compound having at least one of a pyridine ring, a diazine ring (a pyrimidine ring, a pyrazine ring, and a pyridazine ring), and a triazine ring.

Note that the lowest unoccupied molecular orbital (LUMO) level of the organic compound having an unshared electron pair is preferably greater than or equal to −3.6 eV and less than or equal to −2.3 eV. In general, the highest occupied molecular orbital (HOMO) level and the LUMO level of an organic compound can be estimated by CV (cyclic voltammetry), photoelectron spectroscopy, optical absorption spectroscopy, inverse photoelectron spectroscopy, or the like.

For example, 4,7-diphenyl-1,10-phenanthroline (abbreviation: BPhen), 2,9-di(naphthalen-2-yl)-4,7-diphenyl-1,10-phenanthroline (abbreviation: NBPhen), diquinoxalino[2,3-a: 2′,3′-c] phenazine (abbreviation: HATNA), 2,4,6-tris[3′-(pyridin-3-yl) biphenyl-3-yl]-1,3,5-triazine (abbreviation: TmPPPyTz), or the like can be used as the organic compound having an unshared electron pair. Note that NBPhen has a higher glass transition temperature (Tg) than BPhen and thus has high heat resistance.

In the case of manufacturing a light-emitting device having a tandem structure, a charge-generation layer (also referred to as an intermediate layer) is provided between two light-emitting units. The intermediate layer has a function of injecting electrons into one of the two light-emitting units and injecting holes to the other when voltage is applied between the pair of electrodes.

For the charge-generation layer, for example, a material that can be used for the electron-injection layer, such as lithium, can be suitably used. For the charge-generation layer, for example, a material that can be used for the hole-injection layer can be suitably used. For the charge-generation layer, a layer containing a hole-transport material and an acceptor material (an electron-accepting material) can be used. For the charge-generation layer, a layer containing an electron-transport material and a donor material can be used. Forming such a charge-generation layer can inhibit an increase in the driving voltage that would be caused by stacking light-emitting units.

The charge-generation layer includes at least a charge-generation region. The charge-generation region preferably contains an acceptor material, and for example, preferably contains a hole-transport material and an acceptor material which can be used for the above-described hole-injection layer.

The charge-generation layer preferably includes a layer containing a substance having a high electron-injection property. The layer can also be referred to as an electron-injection buffer layer. The electron-injection buffer layer is preferably provided between the charge-generation region and the electron-transport layer. By provision of the electron-injection buffer layer, an injection barrier between the charge-generation region and the electron-transport layer can be lowered; thus, electrons generated in the charge-generation region can be easily injected into the electron-transport layer.

The electron-injection buffer layer preferably contains an alkali metal or an alkaline earth metal, and for example, can be configured to contain an alkali metal compound or an alkaline earth metal compound. Specifically, the electron-injection buffer layer preferably contains an inorganic compound containing an alkali metal and oxygen or an inorganic compound containing an alkaline earth metal and oxygen, further preferably contains an inorganic compound containing lithium and oxygen (e.g., lithium oxide (Li₂O)). Alternatively, a material that can be used for the electron-injection layer can be favorably used for the electron-injection buffer layer.

The charge-generation layer preferably includes a layer containing a substance having a high electron-transport property. The layer can also be referred to as an electron-relay layer. The electron-relay layer is preferably provided between the charge-generation region and the electron-injection buffer layer. In the case where the charge-generation layer does not include an electron-injection buffer layer, the electron-relay layer is preferably provided between the charge-generation region and the electron-transport layer. The electron-relay layer has a function of preventing interaction between the charge-generation region and the electron-injection buffer layer (or the electron-transport layer) and smoothly transferring electrons.

A phthalocyanine-based material such as copper (II) phthalocyanine (abbreviation: CuPc) or a metal complex having a metal-oxygen bond and an aromatic ligand is preferably used for the electron-relay layer.

Note that the charge-generation region, the electron-injection buffer layer, and the electron-relay layer cannot be clearly distinguished from each other in some cases on the basis of the cross-sectional shapes, the characteristics, or the like.

Note that the charge-generation layer may contain a donor material instead of an acceptor material. For example, the charge-generation layer may include a layer containing an electron-transport material and a donor material, which can be used for the electron-injection layer.

When the light-emitting units are stacked, provision of a charge-generation layer between two light-emitting units can inhibit an increase in driving voltage.

This embodiment can be combined with the other embodiments as appropriate.

### Embodiment 6

In this embodiment, a light-receiving device that can be used for the display apparatus of one embodiment of the present invention and a display apparatus having a light-emitting and light-receiving function will be described.

For example, a pn or pin photodiode can be used as the light-receiving device. The light-receiving device functions as a photoelectric conversion device (also referred to as a photoelectric conversion element) that detects light entering the light-receiving device and generates electric charge. The amount of electric charge generated from the light-receiving device depends on the amount of light entering the light-receiving device.

It is particularly preferable to use an organic photodiode including a layer containing an organic compound, as the light-receiving device. An organic photodiode, which is easily made thin, lightweight, and large in area and has a high degree of freedom for shape and design, can be used for a variety of display apparatuses.

### [Light-Receiving Device]

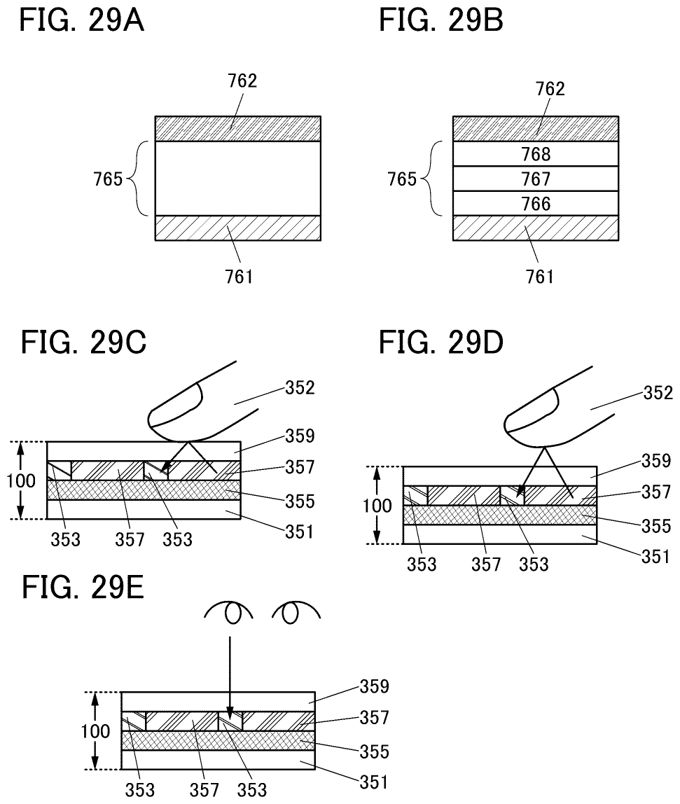

As illustrated in FIG. 29A, the light-receiving device includes a layer 765 between a pair of electrodes (the lower electrode 761 and the upper electrode 762). The layer 765 includes at least one active layer, and may further include another layer.

FIG. 29B is a variation example of the layer 765 included in the light-receiving device illustrated in FIG. 29A. Specifically, the light-receiving device illustrated in FIG. 29B includes a layer 766 over the lower electrode 761, an active layer 767 over the layer 766, a layer 768 over the active layer 767, and the upper electrode 762 over the layer 768.

The active layer 767 functions as a photoelectric conversion layer.

In the case where the lower electrode 761 is an anode and the upper electrode 762 is a cathode, the layer 766 includes one or both of a hole-transport layer and an electron-blocking layer. The layer 768 includes one or both of an electron-transport layer and a hole-blocking layer. In the case where the lower electrode 761 is a cathode and the upper electrode 762 is an anode, the structures of the layers 766 and 768 are replaced with each other.

Next, materials that can be used for the light-receiving device will be described.

Either a low molecular compound or a high molecular compound can be used for the light-receiving device, and an inorganic compound may also be included. Each layer included in the light-receiving device can be formed by a method such as an evaporation method (including a vacuum evaporation method), a transfer method, a printing method, an inkjet method, or a coating method.

The active layer included in the light-receiving device includes a semiconductor. Examples of the semiconductor include an inorganic semiconductor such as silicon and an organic semiconductor including an organic compound. This embodiment describes an example in which an organic semiconductor is used as the semiconductor included in the active layer. The use of an organic semiconductor is preferable because the light-emitting layer and the active layer can be formed by the same method (e.g., a vacuum evaporation method) and thus the same manufacturing apparatus can be used.

Examples of an n-type semiconductor material included in the active layer include electron-accepting organic semiconductor materials such as fullerene (e.g., C₆₀ and C₇₀) and fullerene derivatives. Examples of the fullerene derivative include [6,6]-Phenyl-C₇₁-butyric acid methyl ester (abbreviation: PC70BM), [6,6]-Phenyl-C₆₁-butyric acid methyl ester (abbreviation: PC60BM), and 1′,1″,4′,4″-Tetrahydro-di[1,4]methanonaphthaleno[1,2:2′,3′,56,60:2″,3″][5,6]fullerene-C₆₀ (abbreviation: ICBA).

Other examples of an n-type semiconductor material include perylenetetracarboxylic acid derivatives such as N,N′-dimethyl-3,4,9,10-perylenetetracarboxylic diimide (abbreviation: Me-PTCDI) and 2,2′-(5,5′-(thieno[3,2-b]thiophene-2,5-diyl)bis(thiophene-5,2-diyl))bis(methan-1-yl-1-ylidene)dimalononitrile (abbreviation: FT2TDMN).

Other examples of an n-type semiconductor material include a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative, a benzoquinoline derivative, a quinoxaline derivative, a dibenzoquinoxaline derivative, a pyridine derivative, a bipyridine derivative, a pyrimidine derivative, a naphthalene derivative, an anthracene derivative, a coumarin derivative, a rhodamine derivative, a triazine derivative, and a quinone derivative.

Examples of a p-type semiconductor material contained in the active layer include electron-donating organic semiconductor materials such as copper (II) phthalocyanine (CuPc), tetraphenyldibenzoperiflanthene (DBP), zinc phthalocyanine (ZnPc), tin(II) phthalocyanine (SnPc), quinacridone, and rubrene.

Other examples of a p-type semiconductor material include a carbazole derivative, a thiophene derivative, a furan derivative, and a compound having an aromatic amine skeleton. Other examples of a p-type semiconductor material include a naphthalene derivative, an anthracene derivative, a pyrene derivative, a triphenylene derivative, a fluorene derivative, a pyrrole derivative, a benzofuran derivative, a benzothiophene derivative, an indole derivative, a dibenzofuran derivative, a dibenzothiophene derivative, an indolocarbazole derivative, a porphyrin derivative, a phthalocyanine derivative, a naphthalocyanine derivative, a quinacridone derivative, a rubrene derivative, a tetracene derivative, a polyphenylene vinylene derivative, a polyparaphenylene derivative, a polyfluorene derivative, a polyvinylcarbazole derivative, and a polythiophene derivative.

The HOMO level of the electron-donating organic semiconductor material is preferably shallower (higher) than the HOMO level of the electron-accepting organic semiconductor material. The LUMO level of the electron-donating organic semiconductor material is preferably shallower (higher) than the LUMO level of the electron-accepting organic semiconductor material.

Fullerene having a spherical shape is preferably used as the electron-accepting organic semiconductor material, and an organic semiconductor material having a substantially planar shape is preferably used as the electron-donating organic semiconductor material. Molecules of similar shapes tend to aggregate, and aggregated molecules of similar kinds, which have molecular orbital energy levels close to each other, can increase the carrier-transport property.

For the active layer, a high molecular compound such as Poly[[4,8-bis[5-(2-ethylhexyl)-2-thienyl]benzo[1,2-b: 4,5-b′]dithiophene-2,6-diyl]-2,5-thiophenediyl[5,7-bis(2-ethylhexyl)-4,8-dioxo-4H,8H-benzo[1,2-c: 4,5-c′]dithiophene-1,3-diyl]] polymer (abbreviation: PBDB-T) or a PBDB-T derivative, which functions as a donor, can be used. For example, a method in which an acceptor material is dispersed to PBDB-T or a PBDB-T derivative can be used.

For example, the active layer is preferably formed by co-evaporation of an n-type semiconductor and a p-type semiconductor. Alternatively, the active layer may be formed by stacking an n-type semiconductor and a p-type semiconductor.

The active layer may contain a mixture of three or more kinds of materials. For example, a third material may be mixed with an n-type semiconductor material and a p-type semiconductor material in order to extend a wavelength range. In that case, the third material may be either a low molecular compound or a high molecular compound.

In addition to the active layer, the light-receiving device may further include a layer containing a substance with a high hole-transport property, a substance with a high electron-transport property, a substance with a bipolar property (a substance with a high electron-transport property and a high hole-transport property), or the like. Without limitation to the above, the light-receiving device may further include a layer containing a substance with a high hole-injection property, a hole-blocking material, a substance with a high electron-injection property, an electron-blocking material, or the like. Layers other than the active layer included in the light-receiving device can be formed using a material that can be used for the light-emitting device.

As the hole-transport material or the electron-blocking material, a high molecular compound such as poly(3,4-ethylenedioxythiophene)/polystyrenesulfonic acid (abbreviation: PEDOT/PSS), or an inorganic compound such as molybdenum oxide or copper iodide (Cul) can be used, for example. As the electron-transport material or the hole-blocking material, an inorganic compound such as zinc oxide (ZnO), or an organic compound such as polyethylenimine ethoxylate (abbreviation: PEIE) can be used. The light-receiving device may include a mixed film of PEIE and ZnO, for example.

### [Display Apparatus Having Light Detection Function]

In the display apparatus of one embodiment of the present invention, the light-emitting devices are arranged in a matrix in a display portion, and an image can be displayed on the display portion. Furthermore, the light-receiving devices are arranged in a matrix in the display portion, and the display portion has one or both of an image capturing function and a sensing function in addition to an image displaying function. The display portion can be used as an image sensor or a touch sensor. That is, by detecting light with the display portion, an image can be captured or the approach or contact of a target (e.g., a finger, a hand, or a pen) can be detected.

Furthermore, in the display apparatus of one embodiment of the present invention, the light-emitting devices can be used as a light source of the sensor. In the display apparatus of one embodiment of the present invention, when an object reflects (or scatters) light emitted by the light-emitting device included in the display portion, the light-receiving device can detect reflected light (or scattered light); thus, image capturing or touch detection is possible even in a dark place.

Accordingly, a light-receiving portion and a light source do not need to be provided separately from the display apparatus; hence, the number of components of an electronic device can be reduced. For example, a biometric authentication device, a capacitive touch panel for scroll operation, or the like is not necessarily provided separately from the electronic device. Thus, with the use of the display apparatus of one embodiment of the present invention, the electronic device can be provided with reduced manufacturing cost.

Specifically, the display apparatus of one embodiment of the present invention includes a light-emitting device and a light-receiving device in a pixel. In the display apparatus of one embodiment of the present invention, an organic EL device is used as the light-emitting device, and an organic photodiode is used as the light-receiving device. The organic EL device and the organic photodiode can be formed over the same substrate. Thus, the organic photodiode can be incorporated in the display apparatus including the organic EL device.

In the display apparatus including light-emitting devices and a light-receiving device in each pixel, the pixel has a light-receiving function; thus, the display apparatus can detect a contact or approach of an object while displaying an image. For example, all the subpixels included in the display apparatus can display an image; alternatively, some of the subpixels can emit light as a light source and the other subpixels can display an image.

In the case where the light-receiving device is used as an image sensor, the display apparatus can capture an image with the use of the light-receiving device. For example, the display apparatus of this embodiment can be used as a scanner.

For example, image capturing for personal authentication with the use of a fingerprint, a palm print, the iris, the shape of a blood vessel (including the shape of a vein and the shape of an artery), a face, or the like can be performed using the image sensor.

For example, an image of the periphery, surface, or inside (e.g., fundus) of an eye of a user of a wearable device can be captured using the image sensor. Therefore, the wearable device can have a function of detecting any one or more selected from blinking, movement of an iris, and movement of an eyelid of the user.

The light-receiving device can be used for a touch sensor (also referred to as a direct touch sensor), a near touch sensor (also referred to as a hover sensor, a hover touch sensor, a contactless sensor, or a touchless sensor), or the like.

Here, the touch sensor or the near touch sensor can detect the approach or contact of an object (e.g., a finger, a hand, or a pen).

The touch sensor can detect an object when the display apparatus and the object come in direct contact with each other. The near touch sensor can detect an object even when the object is not in contact with the display apparatus. For example, the display apparatus is preferably capable of detecting an object when the distance between the display apparatus and the object is greater than or equal to 0.1 mm and less than or equal to 300 mm, preferably greater than or equal to 3 mm and less than or equal to 50 mm. With this structure, the display apparatus can be operated without direct contact of an object. In other words, the display apparatus can be operated in a contactless (touchless) manner. With the above structure, the display apparatus can have a reduced risk of being dirty or damaged, or can be operated without the object directly touching a dirt (e.g., dust or a virus) attached to the display apparatus.

The refresh rate can be variable in the display apparatus of one embodiment of the present invention. For example, the refresh rate is adjusted (adjusted in the range from 1 Hz to 240 Hz, for example) in accordance with contents displayed on the display apparatus, whereby power consumption can be reduced. The driving frequency of the touch sensor or the near touch sensor may be changed in accordance with the refresh rate. For example, when the refresh rate of the display apparatus is 120 Hz, the driving frequency of the touch sensor or the near touch sensor can be higher than 120 Hz (can typically be 240 Hz). With this structure, low power consumption can be achieved, and the response speed of the touch sensor or the near touch sensor can be increased.

The display apparatus 100 illustrated in FIG. 29C to FIG. 29E includes a layer 353 including a light-receiving device, a functional layer 355, and a layer 357 including a light-emitting device, between a substrate 351 and a substrate 359.

The functional layer 355 includes a circuit for driving a light-receiving device and a circuit for driving a light-emitting device. One or more of a switch, a transistor, a capacitor, a resistor, a wiring, a terminal, and the like can be provided in the functional layer 355. Note that in the case where the light-emitting device and the light-receiving device are driven by a passive-matrix method, a structure including neither a switch nor a transistor may be employed.

For example, after light emitted by the light-emitting device in the layer 357 including the light-emitting device is reflected by a finger 352 in contact with the display apparatus 100 as illustrated in FIG. 29C, the light-receiving device in the layer 353 including the light-receiving device detects the reflected light. Thus, the contact of the finger 352 with the display apparatus 100 can be detected.

Alternatively, the display apparatus may have a function of detecting an object that is approaching (not in contact with) the display apparatus as illustrated in FIG. 29D and FIG. 29E or capturing an image of such an object. FIG. 29D illustrates an example in which a human finger is detected, and FIG. 29E illustrates an example in which information on the periphery, surface, or inside of the human eye (e.g., the number of blinks, movement of an eyeball, and movement of an eyelid) is detected.

This embodiment can be combined with the other embodiments as appropriate.

### Embodiment 7

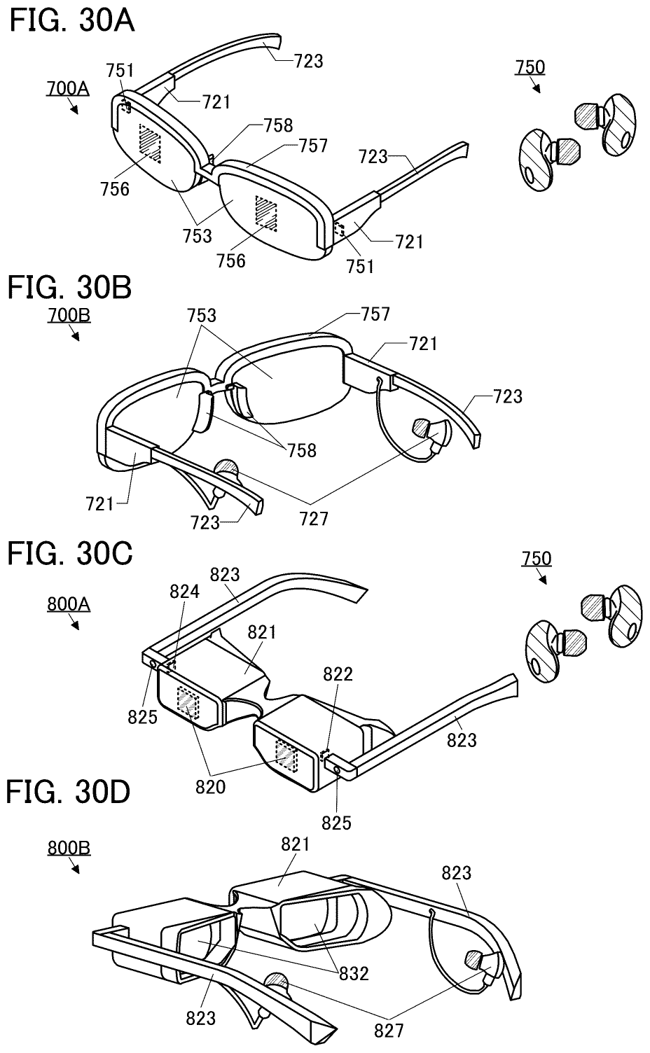

In this embodiment, electronic devices of embodiments of the present invention will be described with reference to FIG. 30 to FIG. 32.

Electronic devices of this embodiment each include the display apparatus of one embodiment of the present invention in a display portion. The display apparatus of one embodiment of the present invention can be easily increased in resolution and definition. Thus, the display apparatus of one embodiment of the present invention can be used for a display portion of a variety of electronic devices.

Examples of the electronic devices include a digital camera, a digital video camera, a digital photo frame, a mobile phone, a portable game console, a portable information terminal, and an audio reproducing device, in addition to electronic devices with a relatively large screen, such as a television device, a desktop or notebook personal computer, a monitor of a computer or the like, digital signage, and a large game machine such as a pachinko machine.

In particular, the display apparatus of one embodiment of the present invention can have high resolution, and thus can be suitably used for an electronic device including a relatively small display portion. Examples of such an electronic device include watch-type and bracelet-type information terminals (wearable devices) and wearable devices capable of being worn on a head, such as a VR device like a head-mounted display, a glasses-type AR device, and an MR device.

The definition of the display apparatus of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840× 2160), or 8K (number of pixels: 7680×4320). In particular, the definition is preferably 4K, 8K, or higher. The pixel density (resolution) of the display apparatus of one embodiment of the present invention is preferably higher than or equal to 100 ppi, further preferably higher than or equal to 300 ppi, further preferably higher than or equal to 500 ppi, further preferably higher than or equal to 1000 ppi, still further preferably higher than or equal to 2000 ppi, still further preferably higher than or equal to 3000 ppi, still further preferably higher than or equal to 5000 ppi, yet further preferably higher than or equal to 7000 ppi. The use of the display apparatus having one or both of such high definition and high resolution can further increase realistic sensation, sense of depth, and the like. There is no particular limitation on the screen ratio (aspect ratio) of the display apparatus of one embodiment of the present invention. For example, the display apparatus is compatible with a variety of screen ratios such as 1:1 (a square), 4:3, 16:9, and 16:10.

The electronic device in this embodiment may include a sensor (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic device in this embodiment can have a variety of functions. For example, the electronic device can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

Examples of a wearable device capable of being worn on a head are described with reference to FIG. 30A to FIG. 30D. These wearable devices have at least one of a function of displaying AR contents, a function of displaying VR contents, a function of displaying SR contents, and a function of displaying MR contents. The electronic device having a function of displaying contents of at least one of AR, VR, SR, MR, and the like enables a user to feel a higher sense of immersion.

An electronic device 700A illustrated in FIG. 30A and an electronic device 700B illustrated in FIG. 30B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display apparatus of one embodiment of the present invention can be used for the display panels 751. Thus, the electronic device can perform display with extremely high resolution.

The electronic device 700A and the electronic device 700B can each project images displayed on the display panels 751 onto display regions 756 of the optical members 753. Since the optical members 753 have a light-transmitting property, a user can see images displayed on the display regions, which are superimposed on transmission images seen through the optical members 753. Accordingly, the electronic device 700A and the electronic device 700B are electronic devices capable of AR display.

In each of the electronic device 700A and the electronic device 700B, a camera capable of capturing images of the front side may be provided as the image capturing portion. Furthermore, when the electronic device 700A and the electronic device 700B are each provided with an acceleration sensor such as a gyroscope sensor, the orientation of the user's head can be sensed and an image corresponding to the orientation can be displayed on the display regions 756.

The communication portion includes a wireless communication device, and a video signal and the like can be supplied by the wireless communication device. Note that instead of the wireless communication device or in addition to the wireless communication device, a connector to which a cable for supplying a video signal and a power supply potential can be connected may be provided.

The electronic device 700A and the electronic device 700B are each provided with a battery so that they can be charged wirelessly and/or by wire.

A touch sensor module may be provided in the housing 721. The touch sensor module has a function of detecting touch on the outer surface of the housing 721. A tap operation or a slide operation, for example, by the user can be detected with the touch sensor module, whereby a variety of processing can be executed. For example, processing such as a pause or a restart of a moving image can be executed by a tap operation, and processing such as fast forward and fast rewind can be executed by a slide operation. The touch sensor module is provided in each of the two housings 721, whereby the range of the operation can be increased.

A variety of touch sensors can be used for the touch sensor module. For example, any of touch sensors of various types such as a capacitive type, a resistive type, an infrared type, an electromagnetic induction type, a surface acoustic wave type, and an optical type can be employed. In particular, a capacitive sensor or an optical sensor is preferably used for the touch sensor module.

In the case of using an optical touch sensor, a photoelectric conversion device (also referred to as a photoelectric conversion element) can be used as a light-receiving device. One or both of an inorganic semiconductor and an organic semiconductor can be used for an active layer of the photoelectric conversion device.

An electronic device 800A illustrated in FIG. 30C and an electronic device 800B illustrated in FIG. 30D each include a pair of display portions 820, a housing 821, a communication portion 822, a pair of wearing portions 823, a control portion 824, a pair of image capturing portions 825, and a pair of lenses 832.

The display apparatus of one embodiment of the present invention can be used for the display portions 820. Thus, the electronic device can perform display with extremely high resolution. This enables a user to feel high sense of immersion.

The display portions 820 are provided at a position inside the housing 821 so as to be seen through the lenses 832. When the pair of display portions 820 display different images, three-dimensional display using parallax can be performed.

The electronic device 800A and the electronic device 800B can be regarded as electronic devices for VR. The user who wears the electronic device 800A or the electronic device 800B can see images displayed on the display portions 820 through the lenses 832.

The electronic device 800A and the electronic device 800B each preferably include a mechanism for adjusting the lateral positions of the lenses 832 and the display portions 820 so that the lenses 832 and the display portions 820 are positioned optimally in accordance with the positions of the user's eyes. Moreover, the electronic device 800A and the electronic device 800B each preferably include a mechanism for adjusting focus by changing the distance between the lenses 832 and the display portions 820.

The electronic device 800A or the electronic device 800B can be mounted on the user's head with the wearing portions 823. FIG. 30C and the like illustrate examples where the wearing portion 823 has a shape like a temple of glasses; however, one embodiment of the present invention is not limited thereto. The wearing portion 823 can have any shape with which the user can wear the electronic device, for example, a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to cover a plurality of fields of view, such as a telescope field of view and a wide field of view.

Although an example of including the image capturing portion 825 is described here, a range sensor (hereinafter also referred to as a sensing portion) that is capable of measuring a distance from an object may be provided. That is, the image capturing portion 825 is one embodiment of the sensing portion. As the sensing portion, an image sensor or a distance image sensor such as LIDAR (Light Detection and Ranging) can be used, for example. With the use of images obtained by the camera and images obtained by the distance image sensor, more pieces of information can be obtained and a gesture operation with higher accuracy is possible.

The electronic device 800A may include a vibration mechanism that functions as bone-conduction earphones. For example, a structure including the vibration mechanism can be employed for any one or more of the display portion 820, the housing 821, and the wearing portion 823. Thus, without additionally requiring an audio device such as headphones, earphones, or a speaker, the user can enjoy video and sound only by wearing the electronic device 800A.

The electronic device 800A and the electronic device 800B may each include an input terminal. To the input terminal, a cable for supplying a video signal from a video output device or the like, electric power for charging a battery provided in the electronic device, and the like can be connected.

The electronic device of one embodiment of the present invention may have a function of performing wireless communication with earphones 750. The earphones 750 include a communication portion (not illustrated) and have a wireless communication function. The earphones 750 can receive information (e.g., audio data) from the electronic device with the wireless communication function. For example, the electronic device 700A illustrated in FIG. 30A has a function of transmitting information to the earphones 750 with the wireless communication function. As another example, the electronic device 800A illustrated in FIG. 30C has a function of transmitting information to the earphones 750 with the wireless communication function.

The electronic device may include an earphone portion. The electronic device 700B illustrated in FIG. 30B includes earphone portions 727. For example, the earphone portion 727 and the control portion can be connected to each other by wire. Part of a wiring that connects the earphone portion 727 and the control portion may be positioned inside the housing 721 or the wearing portion 723.

Similarly, the electronic device 800B illustrated in FIG. 30D includes earphone portions 827. For example, the earphone portion 827 and the control portion 824 can be connected to each other by wire. Part of a wiring that connects the earphone portion 827 and the control portion 824 may be positioned inside the housing 821 or the wearing portion 823. Alternatively, the earphone portions 827 and the wearing portions 823 may include magnets. This is preferred because the earphone portions 827 can be fixed to the wearing portions 823 with magnetic force and thus can be easily housed.

The electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of what is called a headset by including the audio input mechanism.

As described above, both the glasses-type device (e.g., the electronic device 700A and the electronic device 700B) and the goggles-type device (e.g., the electronic device 800A and the electronic device 800B) are preferable as the electronic device of one embodiment of the present invention.

The electronic device of one embodiment of the present invention can transmit information to earphones by wire or wirelessly.

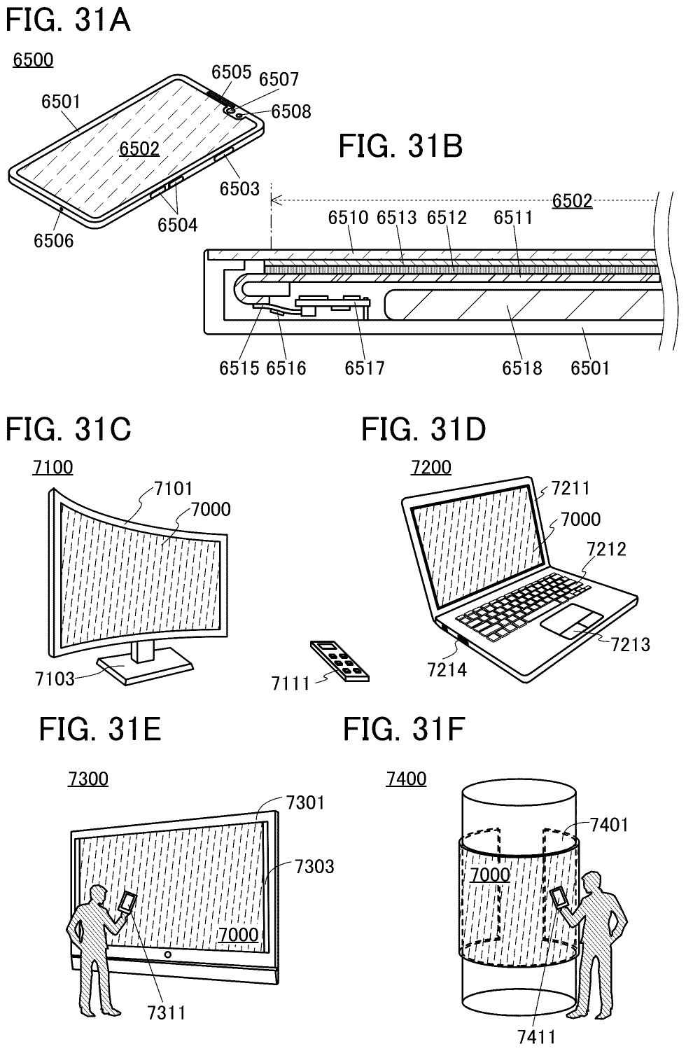

An electronic device 6500 illustrated in FIG. 31A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display apparatus of one embodiment of the present invention can be used for the display portion 6502.

FIG. 31B is a schematic cross-sectional view including an end portion of the housing 6501 on the microphone 6506 side.

A protection member 6510 having a light-transmitting property is provided on a display surface side of the housing 6501, and a display panel 6511, an optical member 6512, a touch sensor panel 6513, a printed circuit board 6517, a battery 6518, and the like are placed in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display of one embodiment of the present invention can be used as the display panel 6511. Thus, an extremely lightweight electronic device can be obtained. Since the display panel 6511 is extremely thin, the battery 6518 with high capacity can be mounted while an increase in thickness of the electronic device is reduced. Moreover, part of the display panel 6511 is folded back so that a connection portion with the FPC 6515 is provided on the back side of the pixel portion, whereby an electronic device with a narrow bezel can be obtained.

FIG. 31C illustrates an example of a television device. In a television device 7100, a display portion 7000 is incorporated in a housing 7101. Here, a structure in which the housing 7101 is supported by a stand 7103 is illustrated.

The display apparatus of one embodiment of the present invention can be used for the display portion 7000.

Operation of the television device 7100 illustrated in FIG. 31C can be performed with an operation switch provided in the housing 7101 and a separate remote control 7111. Alternatively, the display portion 7000 may include a touch sensor, and the television device 7100 may be operated by touch on the display portion 7000 with a finger or the like. The remote control 7111 may include a display portion for displaying information output from the remote control 7111. With operation keys or a touch panel provided in the remote control 7111, channels and volume can be controlled and videos displayed on the display portion 7000 can be controlled.

Note that the television device 7100 has a structure in which a receiver, a modem, and the like are provided. A general television broadcast can be received with the receiver. When the television device is connected to a communication network by wire or wirelessly via the modem, one-way (from a transmitter to a receiver) or two-way (between a transmitter and a receiver or between receivers, for example) data communication can be performed.

FIG. 31D illustrates an example of a notebook personal computer. A notebook personal computer 7200 includes a housing 7211, a keyboard 7212, a pointing device 7213, an external connection port 7214, and the like. In the housing 7211, the display portion 7000 is incorporated.

The display apparatus of one embodiment of the present invention can be used for the display portion 7000.

FIG. 31E and FIG. 31F illustrate examples of digital signage.

Digital signage 7300 illustrated in FIG. 31E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 31F is digital signage 7400 attached to a cylindrical pillar 7401. The digital signage 7400 includes the display portion 7000 provided along a curved surface of the pillar 7401.

The display apparatus of one embodiment of the present invention can be used for the display portion 7000 in each of FIG. 31E and FIG. 31F.

A larger area of the display portion 7000 can increase the amount of information that can be provided at a time. The larger the display portion 7000 attracts more attention, so that the effectiveness of the advertisement can be increased, for example.

A touch panel is preferably used in the display portion 7000, in which case intuitive operation by a user is possible in addition to display of an image or a moving image on the display portion 7000. Moreover, for an application for providing information such as route information or traffic information, usability can be enhanced by intuitive operation.

As illustrated in FIG. 31E and FIG. 31F, it is preferable that the digital signage 7300 or the digital signage 7400 can work with an information terminal 7311 or an information terminal 7411 such as a smartphone a user has through wireless communication. For example, information of an advertisement displayed on the display portion 7000 can be displayed on a screen of the information terminal 7311 or the information terminal 7411. By operating the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

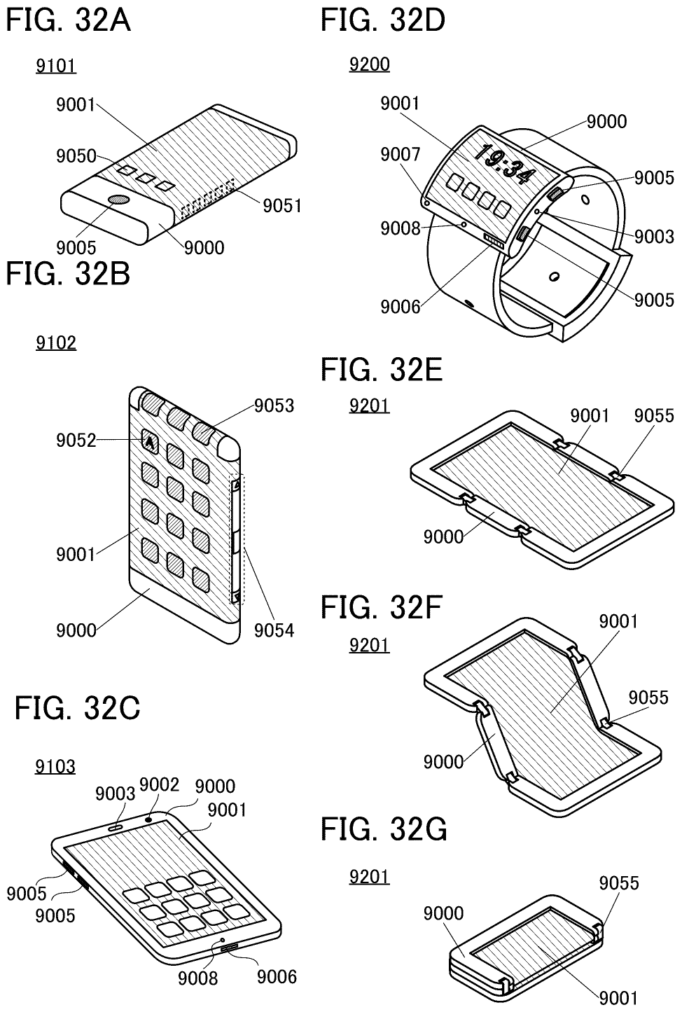

Electronic devices illustrated in FIG. 32A to FIG. 32G each include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays), a microphone 9008, and the like.

The electronic devices illustrated in FIG. 32A to FIG. 32G have a variety of functions. For example, the electronic devices can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic devices are not limited thereto, and the electronic devices can have a variety of functions. The electronic devices may each include a plurality of display portions. The electronic devices may each be provided with a camera or the like and have a function of taking a still image or a moving image and storing the taken image in a storage medium (an external storage medium or a storage medium incorporated in the camera), a function of displaying the taken image on the display portion, or the like.

The electronic devices illustrated in FIG. 32A to FIG. 32G are described in detail below.

FIG. 32A is a perspective view illustrating a portable information terminal 9101. For example, the portable information terminal 9101 can be used as a smartphone. Note that the portable information terminal 9101 may be provided with the speaker 9003, the connection terminal 9006, the sensor 9007, or the like. The portable information terminal 9101 can display characters and image information on its plurality of surfaces. FIG. 32A illustrates an example in which three icons 9050 are displayed. Furthermore, information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, the date, the time, remaining battery, and the radio field intensity. Alternatively, the icon 9050 or the like may be displayed at the position where the information 9051 is displayed.

FIG. 32B is a perspective view illustrating a portable information terminal 9102. The portable information terminal 9102 has a function of displaying information on three or more surfaces of the display portion 9001. Shown here is an example in which information 9052, information 9053, and information 9054 are displayed on different surfaces. For example, a user can check the information 9053 displayed such that it can be seen from above the portable information terminal 9102, with the portable information terminal 9102 put in a breast pocket of his/her clothes. The user can see the display without taking out the portable information terminal 9102 from the pocket and decide whether to answer the call, for example.

FIG. 32C is a perspective view illustrating a tablet terminal 9103. The tablet terminal 9103 is capable of executing a variety of applications such as mobile phone calls, e-mailing, viewing and editing texts, music reproduction, Internet communication, and a computer game. The tablet terminal 9103 includes the display portion 9001, a camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 32D is a perspective view illustrating a watch-type portable information terminal 9200. For example, the portable information terminal 9200 can be used as a Smartwatch (registered trademark). The display surface of the display portion 9001 is curved, and an image can be displayed on the curved display surface. Furthermore, intercommunication between the portable information terminal 9200 and, for example, a headset capable of wireless communication enables hands-free calling. With the connection terminal 9006, the portable information terminal 9200 can perform mutual data transmission with another information terminal and charging. Note that the charging operation may be performed by wireless power feeding.

FIG. 32E to FIG. 32G are perspective views illustrating a foldable portable information terminal 9201. FIG. 32E is a perspective view of an opened state of the portable information terminal 9201, FIG. 32G is a perspective view of a folded state thereof, and FIG. 32F is a perspective view of a state in the middle of change from one of FIG. 32E and FIG. 32G to the other. The portable information terminal 9201 is highly portable in the folded state and is highly browsable in the opened state because of a seamless large display region. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

This embodiment can be combined with the other embodiments as appropriate.

### REFERENCE NUMERALS

100A: display apparatus, 100B: display apparatus, 100C: display apparatus, 100D: display apparatus, 100E: display apparatus, 100F: display apparatus, 100: display apparatus, 101: layer, 102: substrate, 105: pixel portion, 110a: subpixel, 110b: subpixel, 110c: subpixel, 110d: subpixel, 110e: subpixel, 110: pixel, 111a: pixel electrode, 111b: pixel electrode, 111c: pixel electrode, 111d: pixel electrode, 111: pixel electrode, 113a: first layer, 113b: second layer, 113c: third layer, 113d: fourth layer, 114a: common layer, 114b: common layer, 115a: conductive layer, 115b: conductive layer, 115c: conductive layer, 115: common electrode, 120: substrate, 122: resin layer, 123: conductive layer, 124a: pixel, 124b: pixel, 127a: layer, 127f: film, 127s: layer, 127sa: layer, 127: layer, 130a: light-emitting device, 130B: light-emitting device, 130b: light-emitting device, 130c: light-emitting device, 130G: light-emitting device, 130R: light-emitting device, 130: light-emitting device, 131: protective layer, 132: mask, 133: lens array, 140: connection portion, 150: light-receiving device, 154a: fine metal mask, 154b: fine metal mask, 154c: fine metal mask, 156a: area mask, 156b: area mask, 170: insulating layer, 240: capacitor, 241: conductive layer, 243: insulating layer, 245: conductive layer, 251: conductive layer, 252: conductive layer, 254: insulating layer, 255a: insulating layer, 255b: insulating layer, 255c: insulating layer, 256: plug, 261: insulating layer, 262: insulating layer, 263: insulating layer, 264: insulating layer, 265: insulating layer, 271: plug, 274a: conductive layer, 274b: conductive layer, 274: plug, 280: display module, 281: display portion, 282: circuit portion, 283a: pixel circuit, 283: pixel circuit portion, 284a: pixel, 284: pixel portion, 285: terminal portion, 286: wiring portion, 290: FPC, 291: substrate, 292: substrate, 301A: substrate, 301B: substrate, 301: substrate, 310A: transistor, 310B: transistor, 310: transistor, 311: conductive layer, 312: low-resistance region, 313: insulating layer, 314: insulating layer, 315: element isolation layer, 320A: transistor, 320B: transistor, 320: transistor, 321: semiconductor layer, 323: insulating layer, 324: conductive layer, 325: conductive layer, 326: insulating layer, 327: conductive layer, 328: insulating layer, 329: insulating layer, 331: substrate, 332: insulating layer, 335: insulating layer, 336: insulating layer, 341: conductive layer, 342: conductive layer, 343: plug, 344: insulating layer, 345: insulating layer, 346: insulating layer, 347: bump, 348: adhesive layer, 351: substrate, 352: finger, 353: layer, 355: functional layer, 357: layer, 359: substrate, 700A: electronic device, 700B: electronic device, 721: housing, 723: wearing portion, 727: earphone portion, 750: earphone, 751: display panel, 753: optical member, 756: display region, 757: frame, 758: nose pad, 761: lower electrode, 762: upper electrode, 763a: EL layer, 763b: EL layer, 763: EL layer, 764: layer, 765: layer, 766: layer, 767: active layer, 768: layer, 771: light-emitting layer, 772: light-emitting layer, 773: light-emitting layer, 780: layer, 781: layer, 782: layer, 785: charge-generation layer, 790: layer, 791: layer, 792: layer, 800A: electronic device, 800B: electronic device, 820: display portion, 821: housing, 822: communication portion, 823: wearing portion, 824: control portion, 825: image capturing portion, 827: earphone portion, 832: lens, 6500: electronic device, 6501: housing, 6502: display portion, 6503: power button, 6504: button, 6505: speaker, 6506: microphone, 6507: camera, 6508: light source, 6510: protection member, 6511: display panel, 6512: optical member, 6513: touch sensor panel, 6515: FPC, 6516: IC, 6517: printed circuit board, 6518: battery, 7000: display portion, 7100: television device, 7101: housing, 7103: stand, 7111: remote control, 7200: notebook personal computer, 7211: housing, 7212: keyboard, 7213: pointing device, 7214: external connection port, 7300: digital signage, 7301: housing, 7303: speaker, 7311: information terminal, 7400: digital signage, 7401: pillar, 7411: information terminal, 9000: housing, 9001: display portion, 9002: camera, 9003: speaker, 9005: operation key, 9006: connection terminal, 9007: sensor, 9008: microphone, 9050: icon, 9051: information, 9052: information, 9053: information, 9054: information, 9055: hinge, 9101: portable information terminal, 9102: portable information terminal, 9103: tablet terminal, 9200: portable information terminal, 9201: portable information terminal

1. A display apparatus comprising:
a first light-emitting device, a second light-emitting device, and a layer,
wherein the first light-emitting device comprises a first pixel electrode, a first light-emitting layer over the first pixel electrode, a first common electrode over the first light-emitting layer, and a second common electrode over the first common electrode,
wherein the second light-emitting device comprises a second pixel electrode, a second light-emitting layer over the second pixel electrode, the first common electrode over the second light-emitting layer, and the second common electrode over the first common electrode,
wherein the layer is provided between the first light-emitting device and the second light-emitting device, and
wherein the second common electrode is provided over the layer.

2. The display apparatus according to claim 1,
wherein the layer is an insulating layer.

3. The display apparatus according to claim 1,
wherein the layer is a conductive layer.

4. The display apparatus according to claim 1, further comprising:
a first insulating layer and a second insulating layer,
wherein the first pixel electrode, the second pixel electrode, and the second insulating layer are provided over the first insulating layer, and
wherein in a cross-sectional view, a level of a top surface of the second insulating layer is higher than a level of a top surface of the first common electrode.

5. The display apparatus according to claim 4, further comprising:
a third insulating layer,
wherein the third insulating layer is provided over the second insulating layer, and
wherein in a cross-sectional view, a level of a top surface of the third insulating layer is higher than a level of a top surface of the second common electrode in a region in contact with the first common electrode.

6. The display apparatus according to claim 5,
wherein the layer is an insulating layer, and
wherein the third insulating layer comprises the same material as the layer.

7. The display apparatus according to claim 1,
wherein an end portion of the first light-emitting layer is positioned outward from an end portion of the first pixel electrode, and
wherein an end portion of the second light-emitting layer is positioned outward from an end portion of the second pixel electrode.

8. The display apparatus according to claim 1,
wherein the first light-emitting layer comprises a region overlapping with the second light-emitting layer.

9. The display apparatus according to claim 1, further comprising:
a first common layer,
wherein the first common layer is sandwiched between the first pixel electrode and the first light-emitting layer, and
wherein the first common layer is sandwiched between the second pixel electrode and the second light-emitting layer.

10. The display apparatus according to claim 9,
wherein the first common layer comprises a carrier-injection layer.

11. The display apparatus according to claim 1, further comprising:
a second common layer,
wherein the second common layer is sandwiched between the first light-emitting layer and the first common electrode, and
wherein the second common layer is sandwiched between the second light-emitting layer and the first common electrode.

12. The display apparatus according to claim 11,
wherein the second common layer comprises a carrier-injection layer.

13. A method for manufacturing a display apparatus, comprising:
forming a first pixel electrode and a second pixel electrode;
forming a first light-emitting layer using a first mask over the first pixel electrode;
forming a second light-emitting layer using a second mask over the second pixel electrode;
forming a first common electrode using a third mask over the first light-emitting layer and the second light-emitting layer;
forming a layer over part of the first common electrode; and
forming a second common electrode using a fourth mask in a region overlapping with the first common electrode,
wherein the layer is provided between the first pixel electrode and the second pixel electrode, and
wherein the second common electrode is provided over the layer.

14. A method for manufacturing a display apparatus, comprising:
forming a first pixel electrode and a second pixel electrode over a first insulating layer;
forming a second insulating layer over the first insulating layer;
forming a first light-emitting layer using a first mask over the first pixel electrode;
forming a second light-emitting layer using a second mask over the second pixel electrode;
forming a first common electrode using a third mask over the first light-emitting layer and the second light-emitting layer;
forming a third insulating layer over part of the first common electrode and forming a fourth insulating layer over the second insulating layer; and
forming a second common electrode using a fourth mask in a region overlapping with the first common electrode,
wherein the third insulating layer is provided between the first pixel electrode and the second pixel electrode, and
wherein the second common electrode is provided over the first common electrode and the third insulating layer.

15. The method for manufacturing a display apparatus, according to claim 14,
wherein in a cross-sectional view, a level of a top surface of the second insulating layer is higher than a level of a top surface of the first common electrode,
wherein in forming the first light-emitting layer, the first mask is in contact with the top surface of the second insulating layer,
wherein in forming the second light-emitting layer, the second mask is in contact with the top surface of the second insulating layer, and
wherein in forming the first common electrode, the third mask is in contact with the top surface of the second insulating layer.

16. The method for manufacturing a display apparatus, according to claim 14,
wherein in a cross-sectional view, a level of a top surface of the fourth insulating layer is higher than a level of a top surface of the second common electrode in a region in contact with the first common electrode, and
wherein in forming the second common electrode, the fourth mask is in contact with the top surface of the fourth insulating layer.
